(19) United States
(12) Patent Application Publication
(10) Pub. No.: US 2022/0138983 A1
(43) Pub. Date: May 5, 2022

(54) INSPECTION DEVICE AND INSPECTION METHOD

(71) Applicant: Semiconductor Energy Laboratory Co., Ltd., Atsugi-shi, Kanagawa-ken (JP)

(72) Inventors: Hiromichi GODO, Isehara (JP); Kentaro HAYASHI, Atsugi (JP)

(21) Appl. No.: 17/434,033

(22) PCT Filed: Mar. 20, 2020
(86) PCT No.: PCT/IB2020/052564

§ 371 Date: Aug. 26, 2021

(30) Foreign Application Priority Data
Apr. 2, 2019 (JP) 2019-070529

(51) Int. Cl. G06T 7/73; G06N 3/063; G06T 5/50

(52) U.S. Cl. CPC G06T 7/73; G06N 3/063; G06T 2207/30148; G06T 2207/10061; G06T 5/50

(57) ABSTRACT

An inspection device capable of sensing an abnormality included in an image with high accuracy is provided. The inspection device includes an electron microscope, an image processing device, and a calculator. The electron microscope has a function of generating a signal corresponding to a surface shape of a sample over a stage. The image processing device has a function of generating a first image corresponding to the signal. The calculator includes a circuit in which a neural network is formed, and has a function of obtaining a second image on the basis of the first image using the neural network. The calculator has a function of obtaining a third image by performing smoothing processing on the first image and a function of obtaining a fourth image by performing smoothing processing on the second image. The calculator has a function of obtaining a fifth image by obtaining a difference between the third image and the fourth image.

### TECHNICAL FIELD

One embodiment of the present invention relates to an inspection device and an inspection method.

Another embodiment of the present invention relates to a semiconductor apparatus. Note that one embodiment of the present invention is not limited to the above technical field. The technical field of the invention disclosed in this specification and the like relates to an object, a method, or a manufacturing method. Alternatively, one embodiment of the present invention relates to a process, a machine, manufacture, or a composition of matter.

In this specification and the like, a semiconductor apparatus generally means a device that can function by utilizing semiconductor characteristics. A display device, a light-emitting device, a memory device, an electro-optical device, a power storage device, a semiconductor circuit, and an electronic device include a semiconductor apparatus in some cases.

### BACKGROUND ART

In recent years, artificial intelligence (AI) using an artificial neural network (hereinafter referred to as a neural network) has been actively developed, and successful examples have been reported mainly in the field of image recognition.

Furthermore, a case of utilizing artificial intelligence for appearance inspection in a manufacturing process has been reported. In particular, a system that automatically determines an abnormality by analyzing a difference between an inspection image and an image generated by a neural network has been reported (Patent Document 1).

In recent years, transistors using oxide semiconductors or metal oxides in their channel formation regions (Oxide Semiconductor transistors, hereinafter referred to as OS transistors) have attracted attention. By utilizing an extremely low off-state current of an OS transistor, applications using OS transistors have been proposed.

For example, Patent Document 2 discloses an example in which an OS transistor is used in a DRAM (Dynamic Random Access Memory). Patent Document 3 discloses a nonvolatile memory using an OS transistor. In this specification and the like, memories using OS transistors are referred to as OS memories. The OS memories have an unlimited rewriting number of times of rewriting and consume low power.

Furthermore, a multi-bit memory using an OS memory has been proposed (Non-Patent Document 1). The multi-bit memory can store analog data as it is without converting the analog data into digital data. That is, the multi-bit memory can function as an analog memory. An analog neural network provided with the multi-bit memory has been proposed (Non-Patent Document 2). The analog neural network can store obtained analog data as it is and calculate it. Thus, the amount of consumed power is small compared with the case of calculating a neural network with a conventional digital circuit.

### REFERENCE

### Patent Document

[Patent Document 1] PCT International Publication No. 2018/105028
[Patent Document 2] Japanese Published Patent Application No. 2013-168631
[Patent Document 3] Japanese Published Patent Application No. 2012-069932

### Non-Patent Document

[Non-Patent Document 1] T. Onuki, et al., Symp. VLSI Circuit Dig. Tech. Papers, pp. 124-125. 2016
[Non-Patent Document 2] T. Aoki, et al., International Conference on Solid State Devices and Materials (SSDM), Dig. Tech. Papers, pp. 191-192, 2017

### SUMMARY OF THE INVENTION

### Problems to be Solved by the Invention

In the manufacturing site of semiconductor devices, for example, a scanning electron microscope (SEM) is used for appearance inspection of minute portions such as wirings and contact holes. However, an image obtained by an electron microscope such as a SEM includes a larger amount of noise than an image obtained by an optical microscope due to the influence of charge up of a sample, variation in acceleration voltage, and the like. Such noise hinders building of a system for automatically analyzing a SEM image.

In addition, in the case of building a system using a neural network, a GPU (Graphics Processing Unit) is generally used for a calculator; however, a calculator using a GPU consumes a large amount of power and requires maintenance costs.

An object of one embodiment of the present invention is to provide an inspection device capable of sensing an abnormality included in an image with high accuracy. Another object of one embodiment of the present invention is to provide an inspection method capable of sensing an abnormality included in an image with high accuracy. Another object of one embodiment of the present invention is to provide an inspection device capable of sensing an abnormality included in an image with low power consumption. Another object of one embodiment of the present invention is to provide an inspection method capable of sensing an abnormality included in an image with low power consumption. Another object of one embodiment of the present invention is to provide a novel inspection device. Another object of one embodiment of the present invention is to provide a novel inspection method.

Note that the objects of one embodiment of the present invention are not limited to the objects listed above. The objects listed above do not preclude the existence of other objects. Note that the other objects are objects that are not described in this section and will be described below. The objects that are not described in this section will be derived from the descriptions of the specification, the drawings, and the like and can be extracted from these descriptions by those skilled in the art. Note that one embodiment of the present invention solves at least one of the objects listed above and the other objects. Note that one embodiment of the present invention does not necessarily solve all the objects listed above and the other objects.

### Means for Solving the Problems

One embodiment of the present invention is an inspection device including an electron microscope, an image processing device, and a calculator; the electron microscope has a function of generating a signal corresponding to a surface shape of a sample; the image processing device has a function of generating a first image corresponding to the signal; the calculator has a function of obtaining a second image on the basis of the first image; the calculator has a function of obtaining a third image by performing smoothing processing on the first image; the calculator has a function of obtaining a fourth image by performing smoothing processing on the second image; and the calculator has a function of obtaining a fifth image by obtaining a difference between the third image and the fourth image.

Alternatively, in the above embodiment, the calculator may include a circuit in which a neural network is formed, and the calculator may have a function of obtaining the second image on the basis of the first image using the neural network.

Alternatively, in the above embodiment, the third image may be expressed by a first pixel value; the fourth image may be expressed by a second pixel value; the fifth image may be expressed by a third pixel value; the calculator may have a function of obtaining the third pixel value by obtaining a difference between the first pixel value and the second pixel value; the calculator may have a function of obtaining a fourth pixel value on the basis of the third pixel value; the fourth pixel value may be a first value when the third pixel value is greater than or equal to a threshold; and the fourth pixel value may be a second value when the third pixel value is less than the threshold.

Alternatively, in the above embodiment, the calculator may have a function of performing outlier detection on a sixth image expressed by the fourth pixel value to classify the sixth image as abnormal data or normal data.

Alternatively, in the above embodiment, the calculator may include an input/output device; the calculator may have a function of calculating the degree of abnormality of the sixth image by performing the outlier detection; the calculator may have a function of obtaining the sixth images corresponding to a plurality of first images and calculating the degrees of abnormality of the obtained sixth images; and the input/output device may have a function of displaying the first images corresponding to the sixth images in order of the degree of abnormality.

Alternatively, in the above embodiment, the input/output device may have a function of displaying a seventh image obtained by combining the first image and the sixth image.

Alternatively, in the above embodiment, when the first image includes an abnormal portion, it is possible that the second image obtained by the calculator on the basis of the first image does not include the abnormal portion.

Alternatively, in the above embodiment, the circuit in which the neural network is formed may include a transistor using a metal oxide in a channel formation region.

Alternatively, one embodiment of the present invention is an inspection method using an inspection device including a calculator and an electron microscope; a first image taken by the electron microscope is obtained by the calculator; the calculator obtains a second image on the basis of the first image; the calculator obtains a third image by performing smoothing processing on the first image and obtains a fourth image by performing smoothing processing on the second image; and the calculator obtains a fifth image by obtaining a difference between the third image and the fourth image.

Alternatively, in the above embodiment, the calculator may include a circuit in which a neural network is formed, and the calculator may have a function of obtaining the second image on the basis of the first image using the neural network.

Alternatively, in the above embodiment, the calculator may obtain a third pixel value expressing the fifth image by obtaining the third pixel value that is a difference between a first pixel value expressing the third image and a second pixel value expressing the fourth image, and the calculator may obtain a fourth pixel value that is a first value when the third pixel value is higher than or equal to a threshold and is a second value when the third pixel value is lower than the threshold.

Alternatively, in the above embodiment, the calculator may perform outlier detection on a sixth image expressed by the fourth pixel value to classify the sixth image as abnormal data or normal data.

Alternatively, in the above embodiment, the calculator may include an input/output device; the calculator may obtain the sixth images of a plurality of first images and calculate the degrees of abnormality of the sixth images by performing the outlier detection on the obtained sixth images; and the input/output device may display the first images corresponding to the sixth images in order of the degree of abnormality.

Alternatively, in the above embodiment, the input/output device may display a seventh image obtained by combining the first image and the sixth image.

Alternatively, in the above embodiment, when the first image includes an abnormal portion, it is possible that the second image obtained by the calculator on the basis of the first image does not include the abnormal portion.

Alternatively, in the above embodiment, the circuit in which the neural network is formed may include a transistor using a metal oxide in a channel formation region.

### Effect of the Invention

According to one embodiment of the present invention, an inspection device capable of sensing an abnormality included in an image with high accuracy can be provided. According to another embodiment of the present invention, an inspection method capable of sensing an abnormality included in an image with high accuracy can be provided. According to another embodiment of the present invention, an inspection device capable of sensing an abnormality included in an image with low power consumption can be provided. According to another embodiment of the present invention, an inspection method capable of sensing an abnormality included in an image with low power consumption can be provided. According to another embodiment of the present invention, a novel inspection device can be provided. According to another embodiment of the present invention, a novel inspection method can be provided.

Note that the effects of one embodiment of the present invention are not limited to the effects listed above. The effects listed above do not preclude the existence of other effects. Note that the other effects are effects that are not described in this section and will be described below. The effects that are not described in this section will be derived from the descriptions of the specification, the drawings, and the like and can be extracted from these descriptions by those skilled in the art. Note that one embodiment of the present invention has at least one of the effects listed above and the other effects. Accordingly, depending on the case, one embodiment of the present invention does not have the effects listed above in some cases.

### BRIEF DESCRIPTION OF THE DRAWINGS

FIG. 1 is a block diagram showing a structure example of an inspection device.

FIG. 2 is a flow chart showing an example of an inspection method.

FIG. 3A to FIG. 3C are schematic diagrams showing an example of an inspection method.

FIG. 4 is a flow chart showing an example of an inspection method.

FIG. 5A to FIG. 5C are schematic diagrams showing an example of an inspection method.

FIG. 6A and FIG. 6B are schematic diagrams showing an example of an inspection method.

FIG. 7A and FIG. 7B are schematic diagrams showing an example of an inspection method.

FIG. 8 is a block diagram showing a structure example of an inspection device.

FIG. 9 is a block diagram showing a structure example of an inspection device.

FIG. 10A and FIG. 10B are diagrams showing a hierarchical neural network.

FIG. 11 is a block diagram showing a structure example of an arithmetic circuit.

FIG. 12 is a circuit diagram showing a structure example of a circuit included in an arithmetic circuit.

FIG. 13 is a timing chart showing an operation example of an arithmetic circuit.

FIG. 14 is a block diagram showing a structure example of an arithmetic circuit.

FIG. 15 is a block diagram showing a structure example of an arithmetic circuit.

FIG. 16 is a timing chart showing an operation example of an arithmetic circuit.

FIG. 17A is a block diagram showing a structure example of a memory device. FIG. 17B is a perspective view showing a structure example of the memory device.

FIG. 18A to FIG. 18H are circuit diagrams showing structure examples of a memory device.

FIG. 19 is a schematic cross-sectional view showing a structure example of a semiconductor apparatus.

FIG. 20 is a schematic cross-sectional view showing a structure example of a semiconductor apparatus.

FIG. 21A to FIG. 21C are schematic cross-sectional views showing a structure example of a semiconductor apparatus.

FIG. 22A and FIG. 22B are schematic cross-sectional views showing a structure example of a transistor.

FIG. 23 is a schematic cross-sectional view showing a structure example of a semiconductor apparatus.

FIG. 24A and FIG. 24B are schematic cross-sectional views showing a structure example of a transistor.

FIG. 25 is a schematic cross-sectional view showing a structure example of a semiconductor apparatus.

FIG. 26A is a top view showing a structure example of a capacitor. FIG. 26B and FIG. 26C are cross-sectional perspective views showing the structure example of the capacitor.

FIG. 27A is a top view showing a structure example of a capacitor. FIG. 27B is a cross-sectional view showing the structure example of the capacitor. FIG. 27C is a cross-sectional perspective view showing the structure example of the capacitor.

FIG. 28A is a diagram showing the classification of crystal structures of IGZO. FIG. 28B is a diagram showing an XRD spectrum of quartz glass. FIG. 28C is a diagram showing an XRD spectrum of Crystalline IGZO. FIG. 28D is a diagram showing a nanobeam electron diffraction pattern of Crystalline IGZO.

FIG. 29 shows a structure of a generator used in Example.

FIG. 30 shows images in Example.

FIG. 31A and FIG. 31B show images in Example.

FIG. 32 shows images in Example.

### MODE FOR CARRYING OUT THE INVENTION

### Embodiment 1

In this embodiment, an inspection device of one embodiment of the present invention and an inspection method thereof are described.

Note that in this specification and the like, DOSRAM (registered trademark) is an abbreviation of “Dynamic Oxide Semiconductor RAM”, which refers to a RAM including a 1T (transistor)-1C (capacitor) memory cell.

In this specification and the like, NOSRAM (registered trademark) is an abbreviation of “Nonvolatile Oxide Semiconductor RAM”, which refers to a RAM including a gain cell (2T or 3T) memory cell. The DOSRAM and the NOSRAM are each a memory utilizing a low off-state current of an OS transistor.

Embodiments of the present invention are an inspection device including an electron microscope, a PC (Personal Computer), and a server, and an inspection method using the inspection device. According to one embodiment of the present invention, the shape of a minute sample such as a semiconductor device can be inspected, for example. Specifically, whether a sample includes an abnormal portion can be inspected, for example.

In this specification and the like, the PC and the server are collectively referred to as a calculator.

The electron microscope has a function of taking an image of a sample. The image taken by the electron microscope is transmitted to the calculator as an inspection image. The calculator includes an AI chip that is a circuit in which a neural network is formed, and the neural network has performed learning in advance using only images of samples with no abnormal portion as teacher data, for example.

The inspection image transmitted to the calculator is input to the circuit in which the neural network is formed. Then, the circuit generates an image. Thus, it can be said that the circuit has a function of a generator.

As described above, the learning of the neural network is performed using only images of samples with no abnormal portion as teacher data, for example. Thus, even when an inspection image input to the circuit in which the neural network is formed is an image including an abnormal portion, the abnormal portion disappears from an output image.

The calculator included in the inspection device of one embodiment of the present invention performs smoothing processing on the inspection image and the image output from the neural network. Then, a difference between the inspection image and the image output from the neural network, which have been subjected to the smoothing processing, is obtained, whereby an abnormal portion included in the inspection image is detected.

An inspection image taken by an electron microscope includes noise in many cases. Therefore, when the difference is obtained without performing the smoothing processing, an abnormal portion might not be correctly detected. Thus, the difference is obtained after the smoothing processing is performed, whereby an abnormal portion can be correctly detected particularly in the case where an inspection image is taken by an electron microscope. In the above manner, the inspection device of one embodiment of the present invention can automatically sense an abnormality included in an inspection image with high accuracy.

### <Structure of Inspection Device>

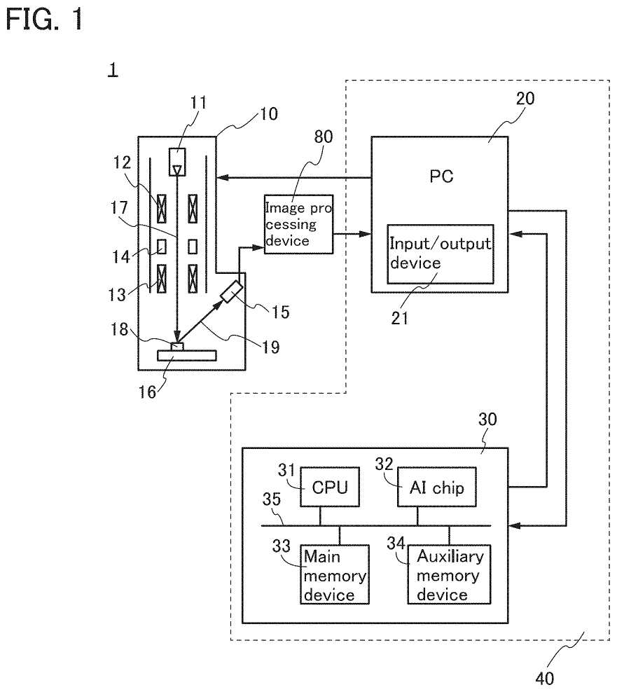

FIG. 1 is a block diagram showing a structure example of an inspection device 1 of one embodiment of the present invention. The inspection device 1 includes an electron microscope 10, an image processing device 80, a PC 20, and a server 30. Here, the PC 20 and the server 30 are collectively referred to as a calculator 40.

The inspection device 1 with the structure illustrated in FIG. 1 is suitable for inspecting the shape of a minute sample such as a semiconductor device. In particular, the inspection device 1 is suitable for inspecting the shape of a sample having a size smaller than or equal to several micrometers.

Although the following description is made on the assumption that the electron microscope 10 is a SEM, one embodiment of the present invention is not limited thereto and can be applied also to a transmission electron microscope (TEM) or a scanning transmission electron microscope (STEM).

The electron microscope 10 includes an electron gun 11, a condenser lens 12, an objective lens 13, a scanning coil 14, a detector 15, and a stage 16. Although not illustrated, the electron microscope 10 includes a vacuum pump and thus a sample chamber can be kept in a vacuum state.

An electron beam 17 released from the electron gun 11 is condensed by the condenser lens 12 and the objective lens 13, and a sample 18 is irradiated with the condensed electron beam. The sample 18 releases a signal electron 19, and the signal electron 19 is detected by the detector 15. The signal electron 19 includes a secondary electron and a reflection electron. Note that the secondary electron and the reflection electron may be detected by different detectors. The inspection device 1 can observe the surface shape of the sample 18 or the like by analyzing the intensity of the signal electron 19.

Accordingly, it can be said that the electron microscope 10 has a function of generating a signal corresponding to the surface shape of the sample 18 or the like.

The image processing device 80 has a function of converting a signal into an image. In the inspection device 1, the image processing device 80 converts a signal sensed by the detector 15 into an image. The image generated by the image processing device 80 is transmitted to the PC 20. The PC 20 includes an input/output device 21. A user of the inspection device 1 can confirm the image generated by the image processing device 80 through the input/output device 21.

In this specification and the like, an image is expressed by a pixel value. The pixel value is a value representing the luminance of light emitted from a pixel, for example. Here, the luminance of light emitted from one pixel is represented by one pixel value, for example. Therefore, an image can be expressed by pixel values whose number is the same as a resolution. For example, an image with a resolution of 1920×1080 can be expressed by 1920×1080 pixel values.

The input/output device 21 is what is called an interface, and includes a display, a keyboard, a mouse, or the like. In the case where the input/output device 21 includes a display, the display may be provided with a touch sensor.

In addition, the PC 20 has a function of controlling the electron microscope 10, and can control the acceleration voltage of the electron beam, the position of the stage, or the like.

The PC 20 is connected to the server 30 through a network and can transmit an image taken by the electron microscope 10 to the server 30.

The server 30 includes a CPU (Central Processing Unit) 31, an AI chip 32, a main memory device 33, an auxiliary memory device 34, and a bus 35.

The server 30 can analyze an image signal transmitted from the PC 20 and transmit the analysis result to the PC 20.

As the main memory device 33, a DRAM can be used. Alternatively, as the main memory device 33, a DOSRAM or a NOSRAM may be used. The use of a DOSRAM or a NOSRAM can reduce the power consumption of the server 30.

As the auxiliary memory device 34, an HDD (Hard Disk Drive) or an SSD (Solid State Drive) can be used. Alternatively, as the auxiliary memory device 34, a NOSRAM may be used. The use of a NOSRAM can reduce the power consumption of the server 30.

The AI chip 32 is a circuit in which a neural network is formed. For the AI chip 32, an OS transistor is preferably used. The use of an OS transistor for the AI chip 32 enables an analog neural network, which can reduce the power consumption of the server 30.

Note that the PC 20 may have a role of the server 30. In that case, the PC 20 preferably includes the AI chip 32.

An image taken by the electron microscope 10 is analyzed by the server 30. The server 30 can automatically sense an abnormal portion included in the image and notify the user of the inspection device 1 via the PC 20 and the input/output device 21.

### <Inspection Method>

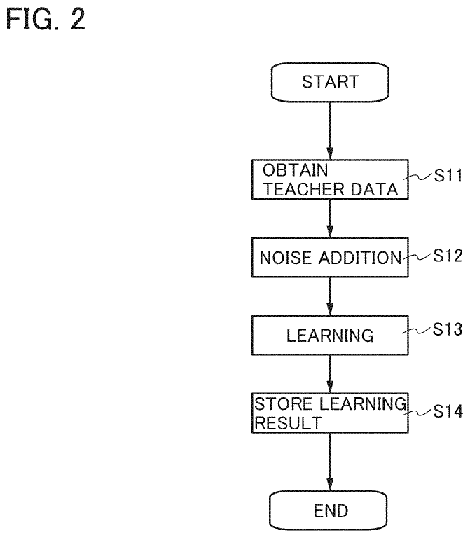

Next, an example of a method for specifying an abnormal portion in a taken image by the inspection device 1 illustrated in FIG. 1 will be described with reference to FIG. 2 to FIG. 7. Note that although the sample 18 is assumed to be a semiconductor device in this embodiment, one embodiment of the present invention is not limited thereto. All samples whose shapes are generally confirmed by an electron microscope are applied to the sample 18.

### <<Learning>>

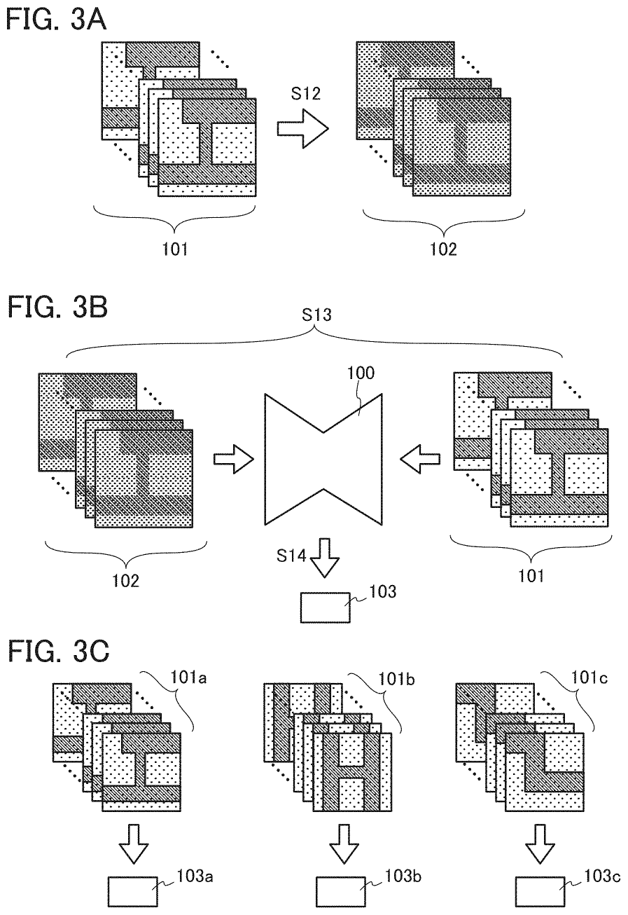

In the inspection method of one embodiment of the present invention, learning is performed in advance using teacher data. FIG. 2 shows a flow chart showing an example of the sequence of learning processing, and FIG. 3A to FIG. 3C are schematic diagrams for describing part of the processing in FIG. 2. This embodiment describes a case where a wiring shape of a semiconductor device is inspected as an example.

The processing shown in FIG. 2 is preferably performed in the server 30, but part or the whole of the processing may be performed in the PC 20 depending on the case.

First, teacher data 101 is obtained in Step S11. The teacher data 101 preferably includes only a plurality of images of non-defective items including no abnormal portion. The number of images of non-defective items is preferably greater than or equal to 1000, further preferably greater than or equal to 5000, still further preferably greater than or equal to 10000. As the number of images of non-defective items increases, the learning can be performed with higher accuracy; however, the number is actually limited by the performance of the server 30 where the learning is performed. Specifically, the number is limited by the processing capacity of the CPU 31 and the AI chip 32 and the storage capacity of the main memory device 33.

In addition, in Step S11, the resolution of the image included in the teacher data 101 is preferably converted into an appropriate value. As the resolution of the image increases, the learning can be performed with higher accuracy; however, the resolution is actually limited by the performance of the server 30 where the learning is performed. Specifically, the resolution is limited by the processing capacity of the CPU 31 and the AI chip 32 and the storage capacity of the main memory device 33.

In Step S11, the number of channels of the image included in the teacher data 101 is preferably converted into 1, i.e., the image is preferably converted into a grayscale image.

Next, in Step S12, noise is added to all of the images in the teacher data 101 to generate data 102 (FIG. 3A). As the noise to be added, Gaussian noise or the like is given.

Next, the learning is performed in Step S13. The learning is performed using the teacher data 101, the data 102, and a generator 100 (FIG. 3B).

The generator 100 is a program using a neural network, and can generate an image corresponding to input data. Examples of the generator 100 include an Autoencoder (AE) and a Convolutional Autoencoder (CAE). Alternatively, as the generator 100, a model utilizing Generative Adversarial Networks (GAN) such as Deep Convolutional Generative Adversarial Networks (DCGAN) may be used. It can be said that the AI chip 32 has a function of the generator 100.

The generator 100 performs the learning (updates the weight of the neural network) using the data 102 as input data so that output data is close to the teacher data 101.

Next, in Step S14, a learning result 103 is stored (FIG. 3B). Specifically, the weight of the generator 100 obtained by the learning is stored. The above-described learning is performed per wiring shape to be inspected. That is, the learning result corresponding to the type of a wiring shape to be inspected is obtained. For example, FIG. 3C illustrates three types of wiring shapes denoted by teacher data 101a, teacher data 101b, and teacher data 101c. As results of the learning using the respective teacher data, a learning result 103a, a learning result 103b, and a learning result 103c are obtained. These learning results are stored in the auxiliary memory device 34 of the server 30.

The learning is thus completed.

### <<Inspection>>

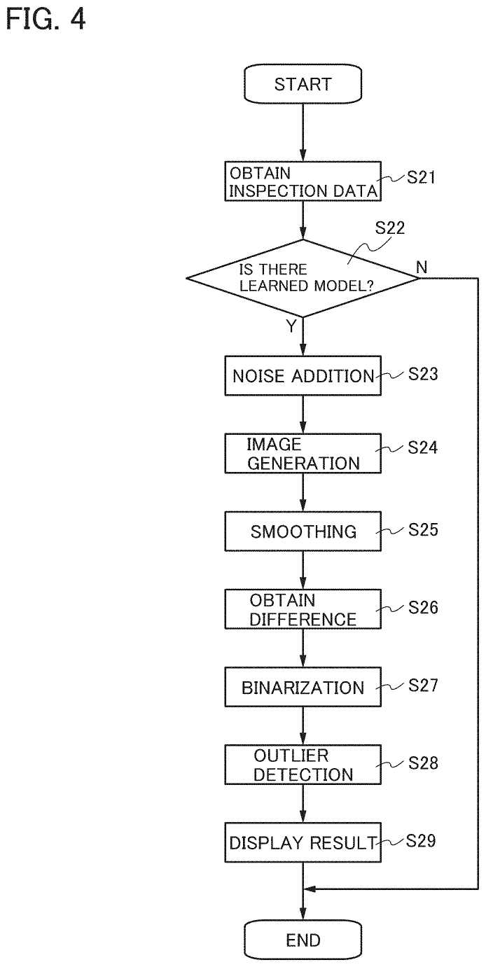

Next, a method for determining an abnormality from an inspection image using the above-described learning result will be described with reference to FIG. 4 to FIG. 7.

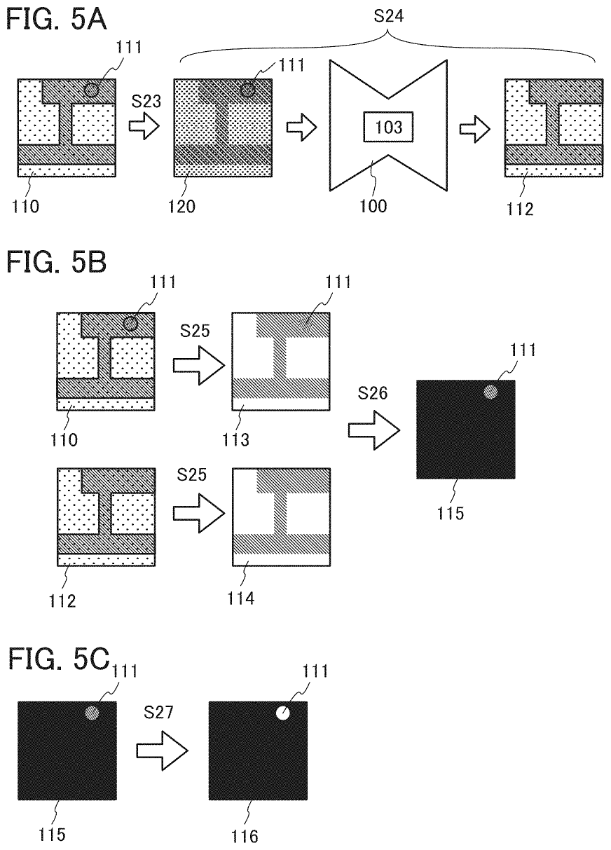

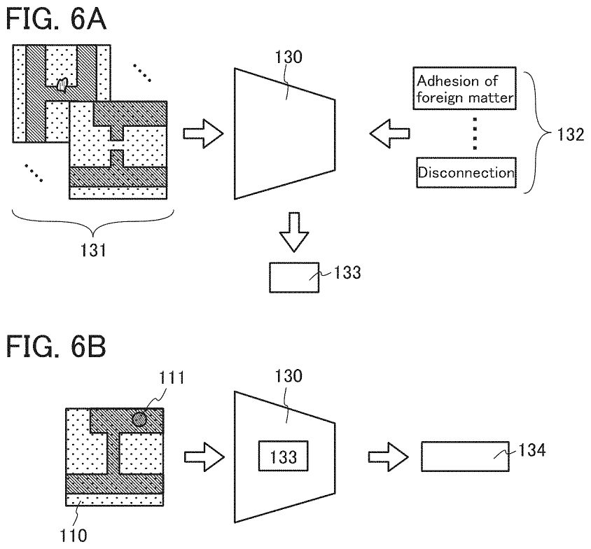

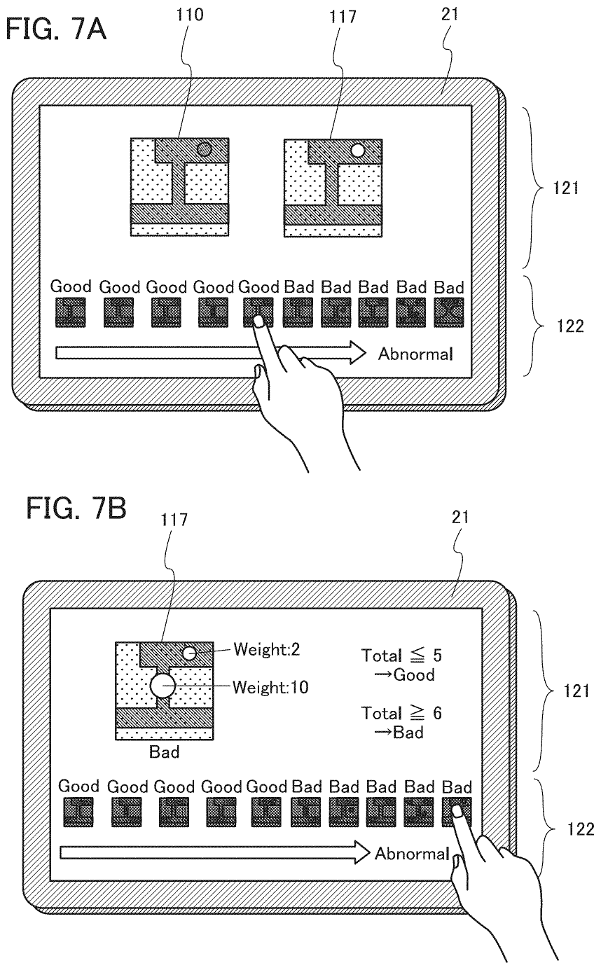

FIG. 4 shows a flow chart showing an example of the sequence of the above-described inspection processing, and FIG. 5A to FIG. 5C, FIG. 6A, FIG. 6B, FIG. 7A, and FIG. 7B are schematic diagrams for describing part of the processing in FIG. 4.

The processing shown in FIG. 4 is preferably performed in the server 30, but part or the whole of the processing may be performed in the PC 20 depending on the case. In particular, in the case where it takes time to transmit data between the PC 20 and the server 30, the processing in FIG. 4 is preferably performed in the PC 20. In that case, the PC 20 preferably includes the AI chip 32.

First, in Step S21, the server 30 obtains an image taken by the electron microscope 10. Next, in Step S22, the server 30 examines whether a learned model corresponding to the obtained image exists in the auxiliary memory device 34. In the case where the learned model exists, the inspection proceeds to Step S23, and in the case where the learned model does not exist, the inspection is terminated. Note that before the inspection is terminated, a message to the effect that learned data does not exist is preferably output to the input/output device 21 in order to notify the user of the inspection device 1.

Furthermore, in Step S21, the resolution and the number of channels of an inspection image 110 are preferably set to be equal to those of the teacher data 101 in Step S13 in FIG. 2.

This embodiment is based on the assumption that the inspection image 110 including an abnormal portion 111 is obtained as illustrated in FIG. 5A.

Next, in Step S23, noise is added to the inspection image 110, whereby an image 120 is generated (FIG. 5A). The noise to be added is preferably the same as that added in Step S12 in FIG. 2.

Next, in Step S24, the image 120 is input to the generator 100 that has performed the learning, whereby an image 112 is obtained (FIG. 5A). The generator 100 is in a state including the learning result 103 obtained by the pre-learning, and its weight has been updated.

The generator 100 has performed the learning using only the teacher data 101 that is a collection of images of non-defective items and thus has not been provided with information related to the abnormal portion 111. Thus, the generator 100 cannot reproduce the abnormal portion 111, and the abnormal portion 111 disappears from the image 112.

Next, in Step S25, smoothing processing is performed on the inspection image 110, whereby an image 113 is obtained. Similarly, smoothing processing is performed on the image 112, whereby an image 114 is obtained (FIG. 5B). The same smoothing processing is preferably performed on the inspection image 110 and the image 112.

As a method of the smoothing processing, a method of calculating the convolution of an image and a filter called a kernel is given. As the filter, two filters, an average filter and a Gaussian filter, are given. As an example of a method of the smoothing processing, the case of using an average filter with a size of 3×3 will be described.

$$\begin{matrix}[ Formula 1 ] & \\ K = \frac{1}{9} [ \begin{matrix}1 & 1 & 1 \\ 1 & 1 & 1 \\ 1 & 1 & 1\end{matrix} ] & ( 1 )\end{matrix}$$

When smoothing processing using an average filter expressed by Formula 1 is performed, a window with a size of 3×3 is selected for each pixel with the pixel used as a center, and the sum of the pixel values of all pixels in the window is divided by 9. That is, the average of the pixel values in the window is obtained. This calculation is applied to all pixels, whereby a smoothed image can be obtained. Note that the size of the filter is not limited to that expressed by Formula 1, and a filter with a size expressed by the square of an odd number, such as 5×5 or 7×7, may be provided as appropriate.

The weights of the average filter (matrix elements of Formula 1) are all 1; meanwhile, a Gaussian filter is a filter in which weights of the filter are provided in accordance with a Gaussian distribution using a target pixel as a center. In the case of using a Gaussian filter, a variance (or a standard deviation) of a Gaussian distribution is specified.

The inspection image 110 includes noise due to the electron microscope 10 in many cases. By performing the above-described smoothing processing, noise can be removed from the inspection image 110.

Next, in Step S26, a difference between the image 113 and the image 114 is obtained. Specifically, differences between pixel values expressing the image 113 and pixel values expressing the image 114 are obtained, whereby an image 115 is obtained (FIG. 5B). The difference is calculated for each pixel values. That is, in the case where the image 113 and the image 114 are each expressed by 1920×1080 pixel values, for example, the difference is calculated for each of the 1920×1080 pixel values. Thus, in the case where the image 113 and the image 114 are each expressed by 1920×1080 pixel values, the image 115 can also be expressed by 1920×1080 pixel values.

A difference between the image 113 and the image 114 is close to 0 in a portion other than the abnormal portion 111. Thus, the luminance of the image 115 is close to 0 in the portion other than the abnormal portion 111.

Next, in Step S27, the luminances of pixels of the image 115 are binarized into 1 and 0 on the basis of a specific threshold. Thus, an image 116 in which the abnormal portion 111 is painted white and a portion other than the abnormal portion 111 is painted black can be obtained (FIG. 5C). The image 116 is an image in which the abnormal portion 111 is emphasized.

Next, in Step S28, outlier detection is performed on the image 116, whereby the image 116 is classified as abnormal data or normal data. That is, the machine performs good or bad determination on the inspection image 110. For the outlier detection, a method such as k-nearest neighbor, k-means clustering, LOF (Local Outlier Factor), or an SVM (Support Vector Machine) method may be employed as appropriate.

At this time, the degree of abnormality of the image 116 is preferably represented by a certain value. For example, in the image 116, the number of pixels whose luminance is represented by 1 (the number of pixels painted white) is used as the degree of abnormality. The larger number of the degree of abnormality means that a difference between an inspection image and teacher data is larger and the degree of abnormality is higher.

Alternatively, a distance from the center of gravity of a collection obtained as normal data by clustering may be used as the degree of abnormality, for example. In this case, a longer distance from the center of gravity means the higher degree of abnormality of data.

Alternatively, a distance from a boundary between a normality and an abnormality, which is determined by the machine, may be used as the degree of abnormality, for example.

In addition, an abnormality may be weighted. The level of a weight can differ between the types of abnormalities, for example. An abnormality that largely affects the quality of an inspection sample can be provided with a large weight, for example. In the case of weighting an abnormality, for example, all abnormal portions 111 detected from the inspection image 110 can be weighted, and the sum of the weights can be used as the degree of abnormality.

FIG. 6A and FIG. 6B are schematic diagrams for describing an example of a method for weighting an abnormality. FIG. 6A is a schematic diagram for describing an example of a method of learning performed in advance. FIG. 6B is a schematic diagram for describing an example of a method for determining the type of an abnormality from an inspection image including the abnormality using a learning result.

Each of the processing shown in FIG. 6A and the processing shown in FIG. 6B is preferably performed in the server 30, but part or the whole of the processing may be performed in the PC 20 depending on the case. In particular, in the case where it takes time to transmit data between the PC 20 and the server 30, the processing in FIG. 6B is preferably performed in the PC 20. In that case, the PC 20 preferably includes the AI chip 32.

An example of a learning method will be described. First, image data 131 is obtained, and a label 132 is linked to each image of the obtained image data 131. The image data 131 preferably includes only a plurality of images of defective items including abnormal portions. The label 132 can show, for example, the type of an abnormality shown in the image data 131. Examples of the type of an abnormality can include disconnection, short circuit, adhesion of a foreign matter, and formation of a void.

The number of images of defective items for one type of an abnormality is, for example, preferably greater than or equal to 1000, further preferably greater than or equal to 5000, still further preferably greater than or equal to 10000. As the number of images of defective items increases, the learning can be performed with higher accuracy; however, the number is actually limited by the performance of the server 30 where the learning is performed. Specifically, the number is limited by the processing capacity of the CPU 31 and the AI chip 32 and the storage capacity of the main memory device 33.

The resolution of the image included in the image data 131 is preferably converted into an appropriate value. As the resolution of the image increases, the learning can be performed with higher accuracy; however, the resolution is actually limited by the performance of the server 30 where the learning is performed. Specifically, the resolution is limited by the processing capacity of the CPU 31 and the AI chip 32 and the storage capacity of the main memory device 33.

The number of channels of the image included in the image data 131 is preferably converted into 1, i.e., the image is preferably converted into a grayscale image.

Next, the learning is performed. The learning is performed using the image data 131, the label 132, and a classifier 130 (FIG. 6A).

The classifier 130 is a program using a neural network, and can extract the feature value of an input image and generate a feature map. As the classifier 130, for example, a convolutional neural network (CNN) is given. It can be said that the AI chip 32 has a function of the classifier 130.

The classifier 130 performs the learning (updates the weight of the neural network) using the image data 131 and the label 132 as teacher data so that desired data is output. For example, the learning is performed so that in the case where the classifier 130 outputs a feature map, the feature value of the image data 131 input to the classifier 130 can be appropriately extracted by the classifier 130 in accordance with the label 132.

Next, a learning result 133 is stored (FIG. 6A). Specifically, the weight of the classifier 130 obtained by the learning is stored. The learning is thus completed.

An example of a method for determining the type of an abnormality will be described. In the case where an abnormality is detected in Step S28 shown in FIG. 4, an inspection image from which the abnormality is detected is input to the classifier 130 that has performed the learning. FIG. 6B shows an example in which the inspection image 110 including the abnormal portion 111 is input to the classifier 130. Here, the classifier 130 is in a state including the learning result 133 obtained by the pre-learning, and its weight has been updated.

By inputting the inspection image 110 to the classifier 130, data 134 representing the type of the abnormality included in the inspection image is output from the classifier 130 on the basis of the learning result 133.

Next, the degree of abnormality of the inspection image 110 including the abnormal portion 111 is calculated on the basis of the data 134. For example, a value obtained by multiplying the number of abnormalities by a weight corresponding to the data 134 can be used as the degree of abnormality.

In the inspection method of one embodiment of the present invention, smoothing processing is performed on the inspection image 110 to obtain the image 113; smoothing processing is performed on the image 112 to obtain the image 114; and then a difference between the image 113 and the image 114 is obtained. As described above, the inspection image 110 includes noise due to the electron microscope 10 in many cases. Therefore, when the difference is obtained without performing the smoothing processing, the abnormal portion 111 might not be correctly detected. Thus, by obtaining the difference after the smoothing processing is performed, the inspection device 1 can automatically sense the abnormal portion 111 included in the inspection image 110 with high accuracy.

Next, in Step S29, an inspection result is displayed on the input/output device 21. FIG. 7A is a schematic diagram showing an example in which the above-described inspection result is displayed on the input/output device 21. FIG. 7A illustrates a terminal provided with a touch panel and a display as an example of the input/output device 21.

In a region 122 on the lower side of a screen, inspection images are displayed in order of the degree of abnormality obtained in Step S28. FIG. 7A shows an example in which the degree of abnormality of the image is lower toward the left side, and the degree of abnormality of the image is higher toward the right side (Abnormal). That is, a less defective item exists on the left side and a more defective item exists on the right side. In addition, the result of the good or bad determination in Step S28 by the machine (Good/Bad) is displayed on each image.

When the user of the inspection device 1 touches an image displayed on the region 122, the touched image is enlarged and displayed on a region 121 on the upper side of the screen. FIG. 7A shows an example in which two images, the inspection image 110 touched by the user of the inspection device 1 and an image 117, are displayed. The image 117 is obtained by combining the inspection image 110 and the image 116 in FIG. 5C. That is, the image 117 is an image in which the abnormal portion of the inspection image 110 is emphasized. The inspection image 110 and the image 117 are displayed on the region 121, whereby the user of the inspection device 1 can easily determine the abnormal portion included in the inspection image. Note that an abnormal portion of the image 117 may be displayed with a gradation of color in accordance with the luminance of the image 115 in FIG. 5B.

By displaying the result as in FIG. 7A, images that are difficult to determine even with the machine can be gathered. The determination by the machine and the determination by visual observation by the user of the inspection device 1 do not necessarily correspond. The user can correct the Good/Bad results determined by the machine via the input/output device 21. Moreover, the result of the correction can be transmitted to the server 30 and reflected in the future good or bad determination.

The determination by the machine and the determination by the user of the inspection device 1 on images existing near left and right ends of the region 122 of FIG. 7A (an image with an extremely low degree of abnormality or an image with an extremely high degree of abnormality) are hardly different from each other. Meanwhile, the determination by the machine and the determination by the user of the inspection device 1 on an image existing around the center of the screen are often different from each other. By arranging the inspection images as in FIG. 7A, the user of the inspection device 1 has only to pay attention to the image around the center of the screen, and the time required for the confirmation by the user of the inspection device 1 can be shortened.

FIG. 7B is a schematic diagram showing a display example of the input/output device 21 in the case where weights (Weight) are given to abnormal portions of the inspection image 110. As described above, the weight can be larger as the influence on the quality of an inspection sample is larger. The weighting can be performed by the method illustrated in FIG. 6A and FIG. 6B. FIG. 7B shows an example in which the image 117 corresponding to the inspection image 110 touched by the user of the inspection device 1 is displayed.

The image 117 illustrated in FIG. 7B includes two abnormal portions. Here, one of the abnormal portions does not cause disconnection, short circuit, or the like and the influence of the abnormality on the quality of an inspection sample is small. The other of the abnormal portions causes disconnection, for example, and the influence of the abnormality on the quality of an inspection sample is large. Therefore, the weight of the other abnormal portion is set larger than the weight of the one abnormal portion. FIG. 7B shows a display example of the input/output device 21 in which the weight of the one abnormal portion is 2 and the weight of the other abnormal portion is 10. As illustrated in FIG. 7B, a weight can be displayed for every abnormal portion.

In the case where an abnormal portion is weighted, an item can be determined to be a non-defective item (Good) when the total weight (Total) is less than or equal to a threshold, and can be determined to be a defective item (Bad) when the total weight (Total) is greater than or equal to the threshold. FIG. 7B shows a display example of the input/output device 21 in which an item is determined to be a non-defective item (Good) when the total weight is less than or equal to 5, and is determined to be a defective item (Bad) when the total weight is greater than or equal to 6. In the case illustrated in FIG. 7B, the total weight is 12; thus, the item is determined to be a defective item (Bad) and information to that effect is displayed on the input/output device 21. Furthermore, the non-defective item (Good)/defective item (Bad) criteria can be displayed on the input/output device 21.

By weighting an abnormal portion, good or bad determination on an inspection sample can be performed with high accuracy. Moreover, by displaying the weight on the input/output device 21, the user of the inspection device 1 can easily recognize a cause of a defect of a sample.

In the above manner, with the inspection device of one embodiment of the present invention, an abnormality included in an inspection image can be automatically sensed with high accuracy. In addition, an abnormality can be automatically sensed with low power consumption. Alternatively, with the inspection method of one embodiment of the present invention, an abnormality included in an inspection image can be automatically sensed with high accuracy. In addition, an abnormality can be automatically sensed with low power consumption.

The structure examples described in this embodiment can be combined with each other as appropriate. This embodiment can be combined with any of the other embodiments and the like in this specification as appropriate.

### Embodiment 2

In Embodiment 1, an inspection image on which the inspection device of one embodiment of the present invention performs abnormality determination is assumed to be an image taken by an electron microscope; however, one embodiment of the present invention is not limited thereto. In this embodiment, a structure example of the inspection device of one embodiment of the present invention in the case where an image other than an image taken by an electron microscope is used as an inspection image will be described.

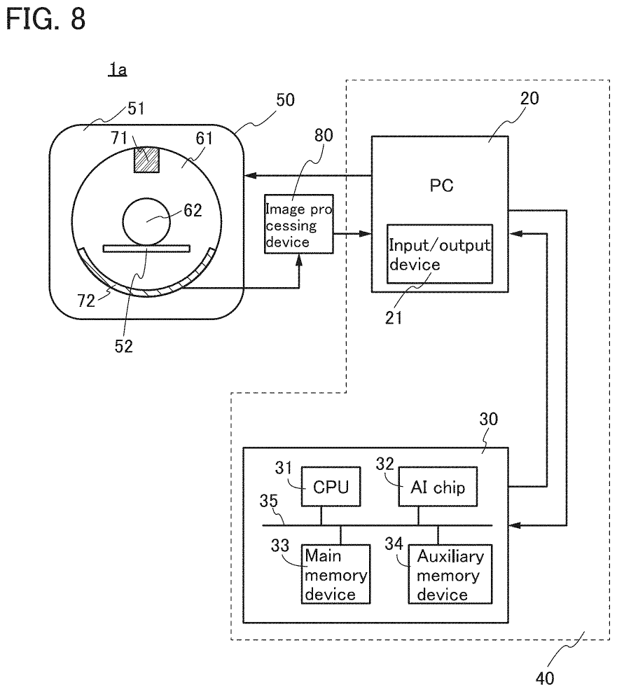

FIG. 8 is a block diagram showing a structure example of an inspection device 1a. The inspection device 1a is different from the inspection device 1 described in Embodiment 1 in including a computed tomography device 50 instead of the electron microscope 10.

The computed tomography device 50 includes a gantry 51 and a cradle 52. An opening portion 61 is provided in the gantry 51, and an X-ray tube 71 and a detector 72 are provided to have regions in contact with a sidewall of the opening portion 61. An inspection object 62 is placed on the cradle 52. The inspection object 62 can be a human body, for example.

The X-ray tube 71 has a function of generating an X-ray (e.g., an electromagnetic wave having a wavelength of greater than or equal to 1 μm and less than or equal to 10 nm), for example. The detector 72 has a function of detecting an X-ray, for example.

When the inspection object 62 is irradiated with the electromagnetic wave generated by the X-ray tube 71, part of the electromagnetic wave used for the irradiation is absorbed by the inspection object 62. The detector 72 is irradiated with the electromagnetic wave that passes through the inspection object 62 without being absorbed by the inspection object 62. A signal representing the intensity of the electromagnetic wave with which the detector 72 is irradiated is converted into an image by the image processing device 80.

For the functions or the like of the PC 20 and the server 30, the inspection device 1 described in Embodiment 1 can be referred to. Here, the PC 20 included in the inspection device 1a has a function of controlling the computed tomography device 50 and can control the position of the X-ray tube 71, for example.

For the inspection method using the inspection device 1a, the description of the inspection method using the inspection device 1 described in Embodiment 1 can be referred to when the electron microscope 10 is rephrased as the computed tomography device 50 and a sample is rephrased as an inspection object, for example.

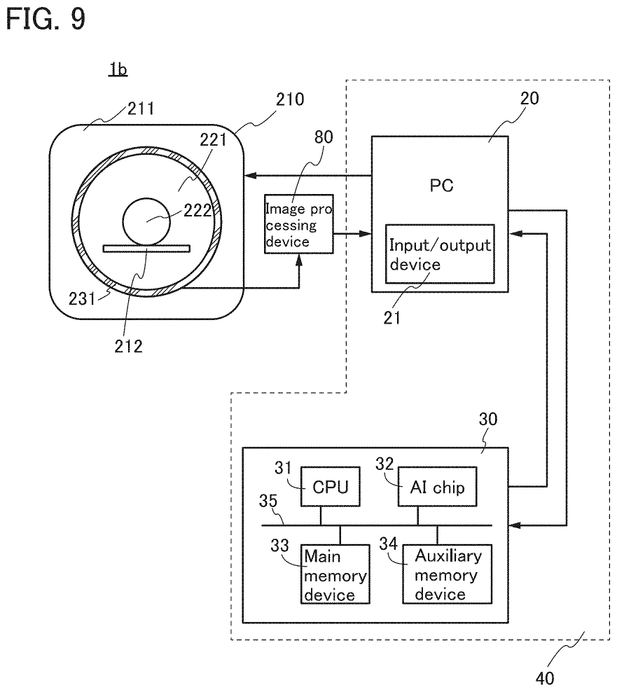

FIG. 9 is a block diagram showing a structure example of an inspection device 1b. The inspection device 1b is different from the inspection device 1 described in Embodiment 1 in including a nuclear magnetic resonance device 210 instead of the electron microscope 10.

The nuclear magnetic resonance device 210 includes a gantry 211 and a cradle 212. An opening portion 221 is provided in the gantry 211. A coil 231 is provided in the gantry 211 to cover a sidewall of the opening portion 221. An inspection object 222 is placed on the cradle 212. Like the inspection object 62 illustrated in FIG. 8, the inspection object 222 can be a human body, for example. Note that the inspection object 222 is preferably a living body.

The coil 231 has a function of generating a magnetic field. When the inspection object 222 is irradiated with the magnetic field generated by the coil 231, a resonance phenomenon occurs between a hydrogen atom contained in the inspection object 222 and the magnetic field. Thus, a nuclear magnetic resonance signal is generated. The nuclear magnetic resonance signal is converted into an image by the image processing device 80.

For the functions or the like of the PC 20 and the server 30, the inspection device 1 described in Embodiment 1 can be referred to. Here, the PC 20 included in the inspection device 1b has a function of controlling the nuclear magnetic resonance device 210, and can change the direction of the magnetic field generated by the coil 231, for example.

For the inspection method using the inspection device 1b, the description of the inspection method using the inspection device 1 described in Embodiment 1 can be referred to when the electron microscope 10 is rephrased as the nuclear magnetic resonance device 210 and a sample is rephrased as an inspection object, for example.

The structure examples described in this embodiment can be combined with each other as appropriate. This embodiment can be combined with any of the other embodiments and the like in this specification as appropriate.

### Embodiment 3

In this embodiment, an example of an arithmetic circuit that is a circuit used for an inspection device of one embodiment of the present invention and performs arithmetic operation of a neural network is described.

### <Hierarchical Neural Network>

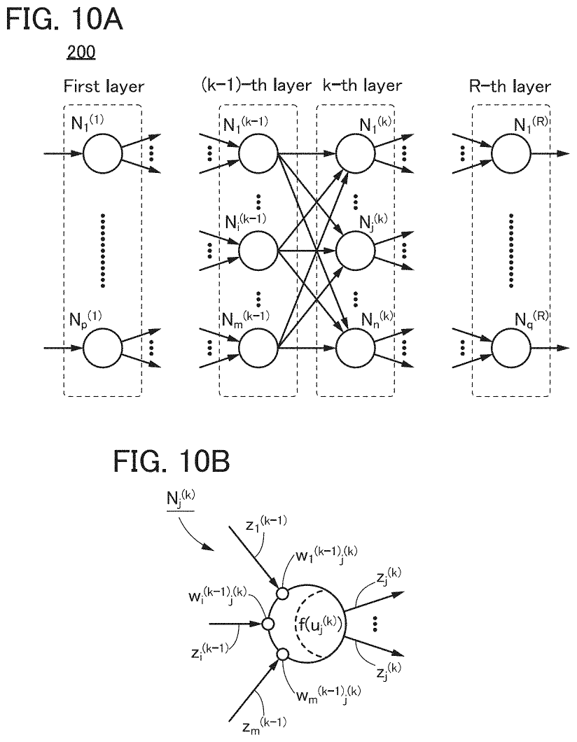

First, a hierarchical neural network is described. A hierarchical neural network includes one input layer, one or a plurality of intermediate layers (hidden layers), and one output layer, for example, and is configured with a total of at least three layers. A hierarchical neural network 200 illustrated in FIG. 10A is one example, and the neural network 200 includes a first layer to an R-th layer (here, R can be an integer greater than or equal to 4). Specifically, the first layer corresponds to the input layer, the R-th layer corresponds to the output layer, and the other layers correspond to the intermediate layers. Note that FIG. 10A illustrates the (k−1)-th layer and the k-th layer (here, k is an integer greater than or equal to 3 and less than or equal to R−1) as the intermediate layers, and does not illustrate the other intermediate layers.

Each of the layers of the neural network 200 includes one or a plurality of neurons. In FIG. 10A, the first layer includes a neuron Nₗ⁽¹⁾ to a neuron Nₚ⁽¹⁾ (here, p is an integer greater than or equal to 1); the (k−1)-th layer includes a neuron Nₗ^{(k-1)} to a neuron Nₘ^{(k-1)} (here, m is an integer greater than or equal to 1); the k-th layer includes a neuron Nₗ^{(k)} to a neuron Nₙ^{(k)} (here, n is an integer greater than or equal to 1); and the R-th layer includes a neuron Nₗ^{(R)} to a neuron N_{q}^{(R)} (here, q is an integer greater than or equal to 1).

FIG. 10A illustrates a neuron Nᵢ^{(k-1)} (here, i is an integer greater than or equal to 1 and less than or equal to m) in the (k−1)-th layer and a neuron Nⱼ^{(k)} (here, j is an integer greater than or equal to 1 and less than or equal to n) in the k-th layer, in addition to the neuron Nₗ⁽¹⁾ the neuron Nₚ⁽¹⁾, the neuron Nₗ^{(k-1)} the neuron Nₘ^{(k-1)}, the neuron Nₗ^{(k)}, the neuron Nₙ^{(k)}, the neuron Nₗ^{(R)}, and the neuron No; the other neurons are not illustrated.

Note that m and n may be values greater than or equal top or less than p. Alternatively, m and n may be values greater than or equal to q or less than q. In the case where the network 200 has a function of an Autoencoder (AE), for example, m and n may be values less than p and q.

Next, signal transmission from a neuron in one layer to a neuron in the subsequent layer and signals input to and output from the neurons are described. Note that description here is made focusing on the neuron Nⱼ^{(k)} in the k-th layer.

FIG. 10B illustrates the neuron Nⱼ^{(k)} in the k-th layer, signals input to the neuron Nⱼ^{(k)}, and a signal output from the neuron Nⱼ^{(k)}.

Specifically, zₗ^{(k-1)} to zₘ^{(k-1)} that are output signals from the neuron Nₗ^{(k-1)} to the neuron Nₘ^{(k-1)} in the (k−1)-th layer are output to the neuron Nⱼ^{(k)}. Then, the neuron Nⱼ^{(k)} generates zⱼ^{(k)} in accordance with zₗ^{(k-1)} to zₘ^{(k-1)}, and outputs zⱼ^{(k)} as the output signal to the neurons in the (k+1)-th layer (not illustrated).

The efficiency of transmitting a signal input from a neuron in one layer to a neuron in the subsequent layer depends on the connection strength (hereinafter, referred to as weight coefficient) of the synapse that connects the neurons to each other. In the neural network 200, a signal output from a neuron in one layer is multiplied by a corresponding weight coefficient and then is input to a neuron in the subsequent layer. When i is an integer greater than or equal to 1 and less than or equal to m and the weight coefficient of the synapse between the neuron Nᵢ^{(k-1)} in the (k−1)-th layer and the neuron Nⱼ^{(k)} in the k-th layer is Nᵢ^{(k-1)}ⱼ^{(k)} a signal input to the neuron Nⱼ^{(k)} in the k-th layer can be expressed by Formula (D1).

$$\begin{matrix}[ Formula 2 ] & \\ {w}_{ij}^{( k - 1 ) ( k )} \cdot {z}_{i}^{( k - 1 )} & ( D1 )\end{matrix}$$

That is, when the signals are transmitted from the neuron Nₗ^{(k-1)} to the neuron Nₘ^{(k-1)} in the (k−1)-th layer to the neuron Nⱼ^{(k)} in the k-th layer, the signals zₗ^{(k-1)} to zₘ^{(k-1)} are multiplied by respective weight coefficients (wₗ^{(k-1)}ⱼ^{(k)} to wₘ^{(k-1)}ⱼ^{(k)}. Then, wₗ^{(k-1)}ⱼ^{(k)}·zₗ^{(k-1)} to wₘ^{(k-1)}ⱼ^{(k)}·zₘ^{(k-1)} are input to the neuron Nⱼ^{(k)} in the k-th layer. At that time, the total sum uⱼ^{(k)} of the signals input to the neuron Nⱼ^{(k)} in the k-th layer is expressed by Formula (D2).

$$\begin{matrix}[ Formula 3 ] & \\ {u}_{j}^{( k )} = {\sum }_{i = 1}^{m} {w}_{ij}^{( k - 1 ) ( k )} \cdot {z}_{i}^{( k - 1 )} & ( D2 )\end{matrix}$$

In addition, a bias may be added to the product-sum result of the weight coefficients wₗ^{(k-1)}ⱼ^{(k)} to wₘ^{(k-1)}ⱼ(k) and the signals zₗ^{(k-1)} to zₘ^{(k-1)} of the neurons. When the bias is b, Formula (D2) can be rewritten into the following formula.

$$\begin{matrix}[ Formula 4 ] & \\ {u}_{j}^{( k )} = {\sum }_{i = 1}^{m} {w}_{ij}^{( k - 1 ) ( k )} \cdot {z}_{i}^{( k - 1 )} + b & ( D3 )\end{matrix}$$

The neuron Nⱼ^{(k)} generates the output signal zⱼ^{(k)} in accordance with uⱼ^{(k)}. Here, an output signal zⱼ^{(k)} from the neuron Nⱼ^{(k)} is defined by the following formula.

[Formula 5]

zⱼ^{(k)}=ƒ(uⱼ^{(k)}) (D4)

A function ƒ(uⱼ^{(k)}) is an activation function in a hierarchical neural network, and a step function, a linear ramp function, a sigmoid function, or the like can be used. Note that the activation function may be the same or different among all neurons. In addition, the neuron activation function may be the same or different between the layers.

A signal output from the neuron in each layer, the weight coefficient w, or the bias b may be an analog value or a digital value. For example, a binary or ternary digital value may be used. A value having a larger number of bits may be used. In the case of an analog value, for example, a linear ramp function, a sigmoid function, or the like is used as the activation function. In the case of a binary digital value, a step function with an output of −1 or 1 or an output of 0 or 1 is used. Alternatively, the neuron in each layer may output a ternary or higher-level signal; in this case, a step function with an output of −1, 0, or 1, a step function with an output of 0, 1, or 2, or the like is used as a ternary or higher-level activation function, for example. Moreover, a step function with an output of −2, −1, 0, 1, or 2 or the like may be used as a quinary or higher-level activation function, for example. The use of a digital value as at least one of a signal output from the neuron in each layer, the weight coefficient w, and the bias b can reduce a circuit scale, reduce power consumption, or improve the speed of arithmetic operation, for example. In addition, the use of an analog value as at least one of a signal output from the neuron in each layer, the weight coefficient w, and the bias b can increase the accuracy of arithmetic operation.

The neural network 200 performs operation in which an input signal is input to the first layer (input layer), output signals are sequentially generated in layers from the first layer (input layer) to the last layer (output layer) according to Formula (D1) and Formula (D2) (or Formula (D3) and Formula (D4)) on the basis of the signals input from the previous layers, and the output signals are output to the subsequent layers. The signal output from the last layer (the output layer) corresponds to the calculation results of the neural network 200.

<Structure Example 1 of Arithmetic Circuit>

Next, an example of a circuit that performs product-sum operation and arithmetic operation of an activation function in the above-described neural network 200 will be described.

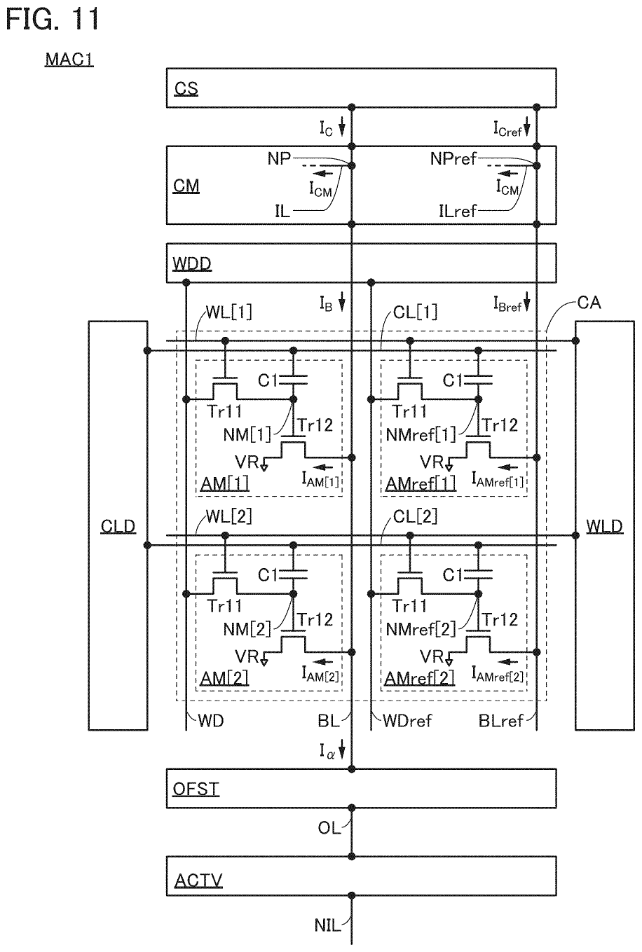

FIG. 11 shows a structure example of an arithmetic circuit MAC1. The arithmetic circuit MAC1 illustrated in FIG. 11 is a circuit that performs product-sum operation of first data retained in a memory cell described later and second data input to the memory cell, and performs arithmetic operation of an activation function using the result of the product-sum operation. Note that the first data and the second data can be analog data or multilevel data (discrete data), for example.

The arithmetic circuit MAC1 includes a current supply circuit CS, a current mirror circuit CM, a circuit WDD, a circuit WLD, a circuit CLD, an offset circuit OFST, an activation function circuit ACTV, and a memory cell array CA.

The memory cell array CA includes a memory cell AM[1], a memory cell AM[2], a memory cell AMref[1], and a memory cell AMref[2]. The memory cell AM[1] and the memory cell AM[2] each have a function of retaining the first data, and the memory cell AMref[1] and the memory cell AMref[2] each have a function of retaining reference data that is needed to perform product-sum operation. Note that the reference data can also be analog data or multilevel data (discrete data), like the first data and the second data.

In the memory cell array CA in FIG. 11, memory cells are arranged in a matrix of two rows and two columns; however, the memory cell array CA may have a structure in which memory cells are arranged in a matrix of three or more rows and three or more columns. In the case where not product-sum operation but multiplication is performed, the memory cell array CA may have a structure in which memory cells are arranged in a matrix of one row and two or more columns.

The memory cell AM[1], the memory cell AM[2], the memory cell AMref[1], and the memory cell AMref[2] each include a transistor Tr11, a transistor Tr12, and a capacitor C1.

Note that the transistor Tr11 is preferably an OS transistor. In addition, it is further preferable that a channel formation region of the transistor Tr11 be a metal oxide containing at least one of an indium, an element M (examples of the element M include one or more kinds selected from aluminum, gallium, yttrium, copper, vanadium, beryllium, boron, titanium, iron, nickel, germanium, zirconium, molybdenum, lanthanum, cerium, neodymium, hafnium, tantalum, tungsten, magnesium, and the like), and zinc. It is further preferable that the transistor Tr11 have a structure of the transistor described in the following embodiment, in particular.

With the use of an OS transistor as the transistor Tr11, the leakage current of the transistor Tr11 can be suppressed, so that a product-sum operation circuit with high calculation accuracy can be obtained in some cases. Furthermore, with the use of an OS transistor as the transistor Tr11, the amount of leakage current from a retention node to a writing word line can be extremely small when the transistor Tr11 is in a non-conduction state. In other words, the frequency of refresh operation for the potential at the retention node can be reduced; thus, power consumption of the product-sum operation circuit can be reduced.

The use of an OS transistor also as the transistor Tr12 allows the transistor Tr12 to be formed concurrently with the transistor Tr11, leading to a reduction in the number of manufacturing steps for the product-sum operation circuit, in some cases. A channel formation region of the transistor Tr12 may include not an oxide but silicon. As the silicon, for example, amorphous silicon, microcrystalline silicon, polycrystalline silicon, single crystal silicon, hydrogenated amorphous silicon, or the like may be used.

In each of the memory cell AM[1], the memory cell AM[2], the memory cell AMref[1], and the memory cell AMref[2], a first terminal of the transistor Tr11 is electrically connected to a gate of the transistor Tr12. A first terminal of the transistor Tr12 is electrically connected to a wiring VR. A first terminal of the capacitor C1 is electrically connected to the gate of the transistor Tr12.

In the memory cell AM[1], a second terminal of the transistor Tr11 is electrically connected to a wiring WD, and a gate of the transistor Tr11 is electrically connected to a wiring WL[1]. A second terminal of the transistor Tr12 is electrically connected to a wiring BL, and a second terminal of the capacitor C1 is electrically connected to a wiring CL[1]. In FIG. 11, in the memory cell AM[1], a connection portion of the first terminal of the transistor Tr11, the gate of the transistor Tr12, and the first terminal of the capacitor C1 is a node NM[1]. In addition, current that flows from the wiring BL to the second terminal of the transistor Tr12 is I_{AM[1]}.

In the memory cell AM[2], the second terminal of the transistor Tr11 is electrically connected to the wiring WD, and the gate of the transistor Tr11 is electrically connected to a wiring WL[2]. The second terminal of the transistor Tr12 is electrically connected to the wiring BL, and the second terminal of the capacitor C1 is electrically connected to a wiring CL[2]. In FIG. 11, in the memory cell AM[2], a connection portion of the first terminal of the transistor Tr11, the gate of the transistor Tr12, and the first terminal of the capacitor C1 is a node NM[2]. In addition, current that flows from the wiring BL to the second terminal of the transistor Tr12 is I_{AM[2]}.

In the memory cell AMref[1], the second terminal of the transistor Tr11 is electrically connected to a wiring WDref, and the gate of the transistor Tr11 is electrically connected to the wiring WL[1]. The second terminal of the transistor Tr12 is electrically connected to a wiring BLref, and the second terminal of the capacitor C1 is electrically connected to the wiring CL[1]. In FIG. 11, in the memory cell AMref[1], a connection portion of the first terminal of the transistor Tr11, the gate of the transistor Tr12, and the first terminal of the capacitor C1 is a node NMref[1]. In addition, current that flows from the wiring BLref to the second terminal of the transistor Tr12 iS I_{AMref[1]}.

In the memory cell AMref[2], the second terminal of the transistor Tr11 is electrically connected to the wiring WDref, and the gate of the transistor Tr11 is electrically connected to the wiring WL[2]. The second terminal of the transistor Tr12 is electrically connected to the wiring BLref, and the second terminal of the capacitor C1 is electrically connected to the wiring CL[2]. In FIG. 11, in the memory cell AMref[2], a connection portion of the first terminal of the transistor Tr11, the gate of the transistor Tr12, and the first terminal of the capacitor C1 is a node NMref[2]. In addition, current that flows from the wiring BLref to the second terminal of the transistor Tr12 is I_{AMref[2]}.

The node NM[1], the node NM[2], the node NMref[1], and the node NMref[2] described above function as retention nodes of their respective memory cells.

The wiring VR is a wiring for supplying current between the first terminal and the second terminal of the transistor Tr12 in each of the memory cell AM[1], the memory cell AM[2], the memory cell AMref[1], and the memory cell AMref[2]. Thus, the wiring VR functions as a wiring for supplying a predetermined potential. In this embodiment, a potential to be supplied from the wiring VR can be a reference potential or a potential lower than the reference potential.

The current supply circuit CS is electrically connected to the wiring BL and the wiring BLref. The current supply circuit CS has a function of supplying current to the wiring BL and the wiring BLref. Note that the amounts of current supplied to the wiring BL and the wiring BLref may be different from each other. In this structure example, a current that is supplied from the current supply circuit CS to the wiring BL is I_{C}, and a current that is supplied from the current supply circuit CS to the wiring BLref is I_{Cref}.

The current mirror circuit CM includes a wiring IL and a wiring ILref. The wiring IL is electrically connected to the wiring BL, and in FIG. 11, a connection portion of the wiring IL and the wiring BL is shown as a node NP. The wiring ILref is electrically connected to the wiring BLref, and in FIG. 11, a connection portion of the wiring ILref and the wiring BLref is shown as a node NPref. The current mirror circuit CM has a function of letting out current according to the potential of the node NPref from the node NPref of the wiring BLref to the wiring ILref, and letting out the same amount of current as the above current from the node NP of the wiring BL to the wiring IL. In FIG. 11, a current that is let out from the node NP to the wiring IL and a current that is let out from the node NPref to the wiring ILref are represented by I_{CM}. In addition, a current that flows from the current mirror circuit CM to the memory cell array CA in the wiring BL is represented by I_{B}, and a current that flows from the current mirror circuit CM to the memory cell array CA in the wiring BLref is represented by I_{Bref}.

The circuit WDD is electrically connected to the wiring WD and the wiring WDref. The circuit WDD has a function of transmitting data that is to be stored in each memory cell included in the memory cell array CA.

The circuit WLD is electrically connected to the wiring WL[1] and the wiring WL[2]. The circuit WLD has a function of selecting a memory cell to which data is written in data writing to the memory cell included in the memory cell array CA.

The circuit CLD is electrically connected to the wiring CL[1] and the wiring CL[2]. The circuit CLD has a function of applying a potential to the second terminal of the capacitor C1 of each memory cell included in the memory cell array CA.

The circuit OFST is electrically connected to the wiring BL and a wiring OL. The circuit OFST has a function of measuring the amount of current flowing from the wiring BL to the circuit OFST and/or the amount of change in current flowing from the wiring BL to the circuit OFST. In addition, the circuit OFST has a function of outputting the measurement result to the wiring OL. Note that the circuit OFST may have a structure in which the measurement result is output as it is as current to the wiring OL or have a structure in which the measurement result is converted into voltage and then output to the wiring OL. In FIG. 11, a current flowing from the wiring BL to the circuit OFST is represented L_{α}.

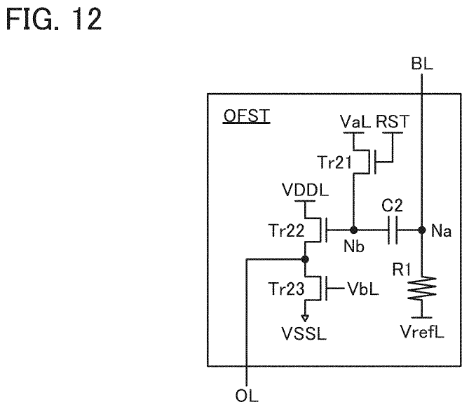

The circuit OFST can have a structure illustrated in FIG. 12, for example. In FIG. 12, the circuit OFST includes a transistor Tr21, a transistor Tr22, a transistor Tr23, a capacitor C2, and a resistor R1.

A first terminal of the capacitor C2 is electrically connected to the wiring BL, and a first terminal of the resistor R1 is electrically connected to the wiring BL. A second terminal of the capacitor C2 is electrically connected to a first terminal of the transistor Tr21, and the first terminal of the transistor Tr21 is electrically connected to a gate of the transistor Tr22. A first terminal of the transistor Tr22 is electrically connected to a first terminal of the transistor Tr23, and the first terminal of the transistor Tr23 is electrically connected to the wiring OL. An electrical connection point of the first terminal of the capacitor C2 and the first terminal of the resistor R1 is a node Na, and an electrical connection point of the second terminal of the capacitor C2, the first terminal of the transistor Tr21, and the gate of the transistor Tr22 is a node Nb.

A second terminal of the resistor R1 is electrically connected to a wiring VrefL. A second terminal of the transistor Tr21 is electrically connected to a wiring VaL, and a gate of the transistor Tr21 is electrically connected to a wiring RST. A second terminal of the transistor Tr22 is electrically connected to a wiring VDDL. A second terminal of the transistor Tr23 is electrically connected to a wiring VSSL, and a gate of the transistor Tr23 is electrically connected to a wiring VbL.

The wiring VrefL is a wiring for supplying a potential Vref, the wiring VaL is a wiring for supplying a potential Va, and the wiring VbL is a wiring for supplying a potential Vb. The wiring VDDL is a wiring for supplying a potential VDD, and the wiring VSSL is a wiring for supplying a potential VSS. Particularly in this structure example of the circuit OFST, the potential VDD is a high-level potential and the potential VSS is a low-level potential. The wiring RST is a wiring for supplying a potential for switching the conduction state and the non-conduction state of the transistor Tr21.

In the circuit OFST illustrated in FIG. 12, a source follower circuit is composed of the transistor Tr22, the transistor Tr23, the wiring VDDL, the wiring VSSL, and the wiring VbL.

In the circuit OFST illustrated in FIG. 12, owing to the resistor R1 and the wiring VrefL, a potential according to current flowing through the wiring BL and the resistance of the resistor R1 is supplied to the node Na.

An operation example of the circuit OFST illustrated in FIG. 12 is described. When first-time current (hereinafter referred to as first current) flows through the wiring BL, a potential according to the first current and the resistance of the resistor R1 is supplied to the node Na owing to the resistor R1 and the wiring VrefL. At this time, the transistor Tr21 is brought into a conduction state so that the potential Va is supplied to the node Nb. After that, the transistor Tr21 is brought into a non-conduction state.

Next, when second-time current (hereinafter referred to as second current) flows through the wiring BL, a potential according to the second current and the resistance of the resistor R1 is supplied to the node Na owing to the resistor R1 and the wiring VrefL as in the case where the first current flows. At this time, the node Nb is in a floating state; thus, a change in the potential of the node Na changes the potential of the node Nb because of capacitive coupling. When the change in the potential of the node Na is ΔV_{Na} and the capacitive coupling coefficient is 1, the potential of the node Nb is Va+ΔV_{Na}. When the threshold voltage of the transistor Tr22 is Vₜₕ, a potential Va+ΔV_{Na}−Vₜₕ is output through the wiring OL. When the potential Va is the threshold voltage Vₜₕ here, a potential ΔV_{Na} can be output through the wiring OL.

The potential ΔV_{Na} is determined by the amount of change from the first current to the second current, the resistance value of the resistor R1, and the potential Vref. The resistance value of the resistor R1 and the potential Vref can be regarded as known; therefore, the use of the circuit OFST illustrated in FIG. 12 allows the amount of change in current flowing through the wiring BL to be obtained from the potential ΔV_{Na}.

The activation function circuit ACTV is electrically connected to the wiring OL and a wiring NIL. The result of the amount of change in current measured by the circuit OFST is input to the activation function circuit ACTV through the wiring OL. The activation function circuit ACTV is a circuit that performs arithmetic operation according to a function system defined in advance, on the result. As the function system, for example, a sigmoid function, a tan h function, a softmax function, a ReLU function, a threshold function, or the like can be used, and these functions are used as activation functions in a neural network.

### <Operation Example 1 of Arithmetic Circuit>

Next, an operation example of the arithmetic circuit MAC1 is described.

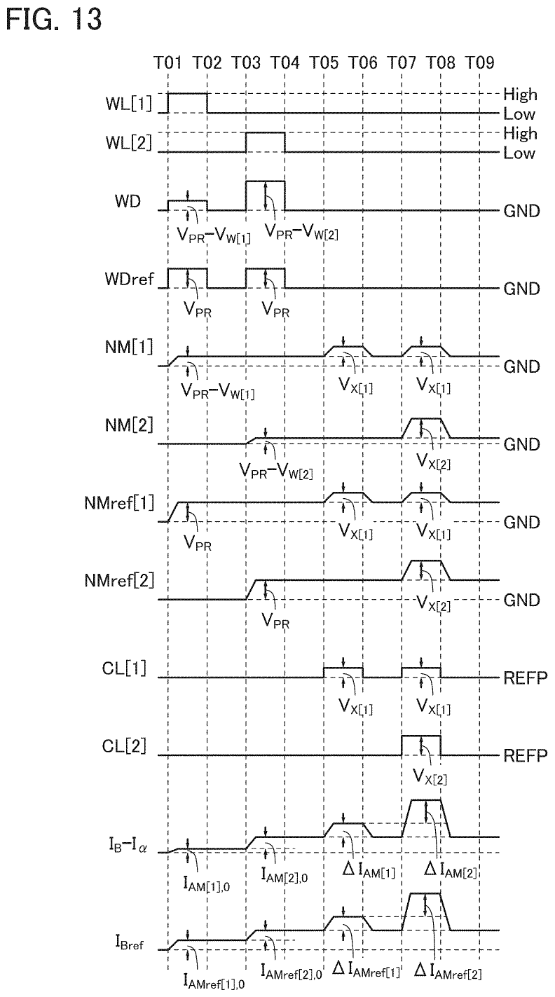

FIG. 13 shows a timing chart of the operation example of the arithmetic circuit MAC1. The timing chart in FIG. 13 shows changes in the potentials of the wiring WL[1], the wiring WL[2], the wiring WD, the wiring WDref, the node NM[1], the node NM[2], the node NMref[1], the node NMref[2], the wiring CL[1], and the wiring CL[2] and changes in the amounts of current I_{B}-I_{α}, and current I_{Bref} from Time T01 to Time T09. In particular, the current I_{B}-I_{α}, represents the total amount of current that flows from the wiring BL to the memory cell AM[1] and the memory cell AM[2] in the memory cell array CA.

### <<From Time T01 to Time T02>>

In the period from Time T01 to Time T02, a high-level potential (denoted by High in FIG. 13) is applied to the wiring WL[1], and a low-level potential (denoted by Low in FIG. 13) is applied to the wiring WL[2]. Furthermore, a potential higher than a ground potential (denoted as GND in FIG. 13) by V_{PR}-V_{W[1]} is applied to the wiring WD, and a potential higher than the ground potential by V_{PR} is applied to the wiring WDref. Moreover, a reference potential (denoted by REFP in FIG. 13) is applied to each of the wiring CL[1] and the wiring CL[2].

The potential V_{W[1]} is a potential corresponding to one piece of the first data. The potential V_{PR} is a potential corresponding to reference data.

At this time, the high-level potential is applied to each of the gates of the transistors Tr11 in the memory cell AM[1] and the memory cell AMref[1]; accordingly, the transistors Tr11 in the memory cell AM[1] and the memory cell AMref[1] are brought into an on state. Accordingly, in the memory cell AM[1], electrical continuity is established between the wiring WD and the node NM[1], so that the potential of the node NM[1] becomes V_{PR}-V_{W[1]}. Similarly, in the memory cell AMref[1], electrical continuity is established between the wiring WDref and the node NMref[1], and the potential of the node NMref[1] becomes V_{PR}.

Here, the current flowing from the second terminal to the first terminal of the transistor Tr12 in each of the memory cell AM[1] and the memory cell AMref[1] is considered. When the current flowing from the wiring BL to the first terminal of the transistor Tr12 in the memory cell AM[1] through its second terminal is I_{AM[1],0}, I_{AM[1],0} can be expressed by the following formula.

[Formula 6]

I_{AM[1],0}=k(V_{PR}−V_{W[1]}−Vₜₕ)² (E1)

Note that k is a constant determined by the channel length, the channel width, the mobility, the capacitance of a gate insulating film, and the like of the transistor Tr12. Furthermore, Vₜₕ is the threshold voltage of the transistor Tr12.

When current flowing from the wiring BLref to the first terminal of the transistor Tr12 in the memory cell AMref[1] through its second terminal is I_{AMref[1],0}, I_{AMref[1],0} can be expressed similarly by the following formula.

[Formula 7]

I_{AMref[1],0}=k(V_{PR}−Vₜₕ)² (E2)

Note that since the low-level potential is applied to each of the gates of the transistors Tr11 in the memory cell AM[2] and the memory cell AMref[2], the transistors Tr11 in the memory cell AM[2] and the memory cell AMref[2] are brought into an off state. Thus, the potentials are not written to the node NM[2] and the node NMref[2].

### <<From Time T02 to Time T03>>

In the period from Time T02 to Time T03, a low-level potential is applied to the wiring WL[1]. At this time, the low-level potential is applied to each of the gates of the transistors Tr11 in the memory cell AM[1] and the memory cell AMref[1]; accordingly, the transistors Tr11 in the memory cell AM[1] and the memory cell AMref[1] are brought into an off state.

In addition, the low-level potential is continuously applied to the wiring WL[2] before Time T02. Thus, the transistors Tr11 in the memory cell AM[2] and the memory cell AMref[2] each remain in an off state since before Time T02.

Since the transistors Tr11 in the memory cell AM[1], the memory cell AM[2], the memory cell AMref[1], and the memory cell AMref[2] are each in an off state as described above, the potentials of the node NM[1], the node NM[2], the node NMref[1], and the node NMref[2] are each retained during the period from Time T02 to Time T03.

In particular, when an OS transistor is applied to each of the transistors Tr11 in the memory cell AM[1], the memory cell AM[2], the memory cell AMref[1], and the memory cell AMref[2] as mentioned in the description of the circuit structure of the arithmetic circuit MAC1, leakage current flowing between the first terminal and the second terminal of the transistor Tr11 can be made low, which makes it possible to retain the potential of each of the node NM[1], the node NM[2], the node NMref[1], and the node NMref[2] for a long time.

During the period from Time T02 to Time T03, the ground potential is applied to the wiring WD and the wiring WDref Since the transistors Tr11 in the memory cell AM[1], the memory cell AM[2], the memory cell AMref[1], and the memory cell AMref[2] are each in an off state, the potentials retained at the node NM[1], the node NM[2], the node NMref[1], and the node NMref[2] are not rewritten by application of potentials from the wiring WD and the wiring WDref.

### <<From Time T03 to Time T04>>

In the period from Time T03 to Time T04, a low-level potential is applied to the wiring WL[1], and the high-level potential is applied to the wiring WL[2]. Furthermore, a potential higher than the ground potential by V_{PR}-V_{W[2]} is applied to the wiring WD, and a potential higher than the ground potential by V_{PR} is applied to the wiring WDref. Moreover, the reference potential is continuously applied to each of the wiring CL[1] and the wiring CL[2] since before Time T02.

Note that the potential V_{W[2]} is a potential corresponding to one piece of the first data.

At this time, the high-level potential is applied to each of the gates of the transistors Tr11 in the memory cell AM[2] and the memory cell AMref[2]; accordingly, the transistors Tr11 in the memory cell AM[2] and the memory cell AMref[2] are brought into an on state. Accordingly, in the memory cell AM[2], electrical continuity is established between the wiring WD and the node NM[2], so that the potential of the node NM[2] becomes V_{PR}-V_{W[2]}. Similarly, in the memory cell AMref[2], electrical continuity is established between the wiring WDref and the node NMref[2], and the potential of the node NMref[2] becomes V_{PR}.

Here, the current flowing from the second terminal to the first terminal of the transistor Tr12 in each of the memory cell AM[2] and the memory cell AMref[2] is considered. When the current flowing from the wiring BL to the first terminal of the transistor Tr12 in the memory cell AM[2] through its second terminal is I_{AM[2],0}, I_{AM[2],0} can be expressed by the following formula.

[Formula 8]

I_{AM[2],0}=k(V_{PR}−V_{W[2]}−Vₜₕ)² (E3)

When current flowing from the wiring BLref to the first terminal of the transistor Tr12 in the memory cell AMref[2] through its second terminal is I_{AMref[2],0}, I_{AMref[2],0} can be expressed similarly by the following formula.

[Formula 9]

I_{AMref[2],0}=k(V_{PR}−Vₜₕ)² (E4)

### <<From Time T04 to Time T05>>

Here, currents that flow in the wiring BL and the wiring BLref during a period from Time T04 to Time TOS are described.

Current from the current supply circuit CS is supplied to the wiring BLref. In addition, current is let out by the current mirror circuit CM, the memory cell AMref[1], and the memory cell AMref[2] to the wiring BLref. When the current supplied from the current supply circuit CS is I_{Cref} and the current let out by the current mirror circuit CM is I_{CM,0} in the wiring BLref, the following formula is satisfied according to Kirchhoff s law.

[Formula 10]

I_{Cref}−I_{CM,0}=I_{AMref[1],0}+I_{AMref[2],0} (E5)

Current from the current supply circuit CS is supplied to the wiring BL. In addition, current is let out by the current mirror circuit CM, the memory cell AM[1], and the memory cell AM[2] to the wiring BL. Moreover, current also flows from the wiring BL to the circuit OFST. When the current supplied from the current supply circuit CS is I_{C} and the current that flows from the wiring BL to the circuit OFST is I_{α,0} in the wiring BL, the following formula is satisfied according to Kirchhoff s law.

[Formula 11]

I_{C}−I_{CM,0}=I_{AM[1],0}+I_{AM[2],0}+I_{α,0} (E6)

### <<From Time T05 to Time T06>>

During a period from Time T05 to Time T06, a potential higher than the reference potential by V_{X[1]} is applied to the wiring CL[1]. At this time, the potential V_{X[1]} is applied to the second terminal of the capacitor C1 in each of the memory cell AM[1] and the memory cell AMref[1], so that the potentials of the gates of the transistors Tr12 increase.

Note that the potential V_{X[1]} is a potential corresponding to one piece of the second data.

Note that an increase in the potential of the gate of the transistor Tr12 corresponds to a potential obtained by multiplying a change in the potential of the wiring CL[1] by a capacitive coupling coefficient determined by the memory cell structure. The capacitive coupling coefficient is calculated using the capacitance of the capacitor C1, the gate capacitance of the transistor Tr12, the parasitic capacitance, and the like. In this operation example, to avoid complexity of description, description is made on the assumption that an increase in the potential of the wiring CL[1] is equal to the increase in the potential of the gate of the transistor Tr12. This corresponds to the case where the capacitive coupling coefficient in each of the memory cell AM[1] and the memory cell AMref[1] is set to 1.

Since the capacitive coupling coefficient is set to 1, when the potential V_{X[1]} is applied to the second terminal of the capacitor C1 in each of the memory cell AM[1] and the memory cell AMref[1], the potentials of the node NM[1] and the node NMref[1] each increase by V_{X[1]}.

Here, the current flowing from the second terminal to the first terminal of the transistor Tr12 in each of the memory cell AM[1] and the memory cell AMref[1] is considered. When the current flowing from the wiring BL to the first terminal of the transistor Tr12 in the memory cell AM[1] through its second terminal is I_{AM[1],1}, I_{AM[1],1} can be expressed by the following formula.

[Formula 12]

I_{AM[1],1}=k(V_{PR}−V_{W[1]}+V_{X[1]}−Vₜₕ)² (E7)

In other words, by application of the potential V_{X[1]} to the wiring CL[1], the current flowing from the wiring BL to the first terminal of the transistor Tr12 in the memory cell AM[1] through its second terminal increases by I_{AM[1],1}−I_{AM[1],0} (denoted by ΔI_{AM[1]} in FIG. 13).

Similarly, when current flowing from the wiring BLref to the first terminal of the transistor Tr12 in the memory cell AMref[1] through its second terminal is I_{AMref[1],1}, I_{AMref[1],1} can be expressed by the following formula.

[Formula 13]

I_{AMref[1],1}=k(V_{PR}+V_{X[1]}−Vₜₕ)² (E8)

In other words, by application of the potential V_{X[1]} to the wiring CL[1], the current flowing from the wiring BLref to the first terminal of the transistor Tr12 in the memory cell AMref[1] through its second terminal increases by I_{AMref[1],1}−I_{AMref[1],0} (denoted by ΔI_{AMref[1]} in FIG. 13).

Here, currents that flow in the wiring BL and the wiring BLref are described.

As in the period from Time T04 to Time T05, the current I_{Cref} from the current supply circuit CS is supplied to the wiring BLref. At the same time, current is let out by the current mirror circuit CM, the memory cell AMref[1], and the memory cell AMref[2] to the wiring BLref. When the current let out by the current mirror circuit CM is I_{CM,1} in the wiring BLref, the following formula is satisfied according to Kirchhoff's law.

[Formula 14]

I_{Cref}−I_{CM,1}=I_{AMref[1],1}+I_{AMref[2],0} (E9)

As in the period from Time T04 to Time T05, the current I_{C} from the current supply circuit CS is supplied to the wiring BL. At the same time, current is let out by the current mirror circuit CM, the memory cell AM[1], and the memory cell AM[2] to the wiring BL. Moreover, current flows from the wiring BL to the circuit OFST. When the current that flows from the wiring BL to the circuit OFST is I_{α,1} in the wiring BL, the following formula is satisfied according to Kirchhoff's law.

[Formula 15]

I_{C}−I_{CM,1}=I_{AM[1],1}+I_{AM[2],0} (E10)

Note that ΔI_{α} represents the difference between the current I_{α,0} flowing from the wiring BL to the circuit OFST during the period from Time T04 to Time T05 and the current I_{α,1} flowing from the wiring BL to the circuit OFST during the period from Time T05 to Time T06. Hereinafter, ΔI_{α} is referred to as a differential current in the arithmetic circuit MAC1. The differential current ΔI_{α} can be expressed by the following formula, using Formula (E1) to Formula (E10).

[Formula 16]

ΔI_{α}=I_{α,1}=2kV_{W[1]}V_{X[1]} (E11)

### <<From Time T06 to Time T07>>

During a period from Time T06 to Time T07, the reference potential is applied to the wiring CL[1]. At this time, the reference potential is applied to the second terminal of the capacitor C1 in each of the memory cell AM[1] and the memory cell AMref[1]; thus, the potentials of the node NM[1] and the node NMref[1] return to the potentials during the period from Time T04 to Time T05.

### <<From Time T07 to Time T08>>

During a period from Time T07 to Time T08, a potential higher than the reference potential by V_{X[1]} is applied to the wiring CL[1], and a potential higher than the reference potential by V_{X[2]} is applied to the wiring CL[2]. At this time, the potential V_{X[1]} is applied to the second terminal of the capacitor C1 in each of the memory cell AM[1] and the memory cell AMref[1], and the potential V_{X[2]} is applied to the second terminal of the capacitor C1 in each of the memory cell AM[2] and the memory cell AMref[2]. Consequently, the potential of the gate of the transistor Tr12 in each of the memory cell AM[1], the memory cell AM[2], the memory cell AMref[1], and the memory cell AMref[2] increases.

For the potential change at the node in each of the memory cell AM[1] and the memory cell AMref[1], refer to the operation during the period from Time T05 to Time T06. Similarly, the memory cell AM[2] and the memory cell AMref[2] are described on the assumption that the capacitive coupling coefficient of each memory cell is 1.

Since the capacitive coupling coefficient is set to 1, when the potential V_{X[2]} is applied to the second terminal of the capacitor C1 in each of the memory cell AM[2] and the memory cell AMref[2], the potentials of the node NM[2] and the node NMref[2] each increase by V_{X[2]}.

Here, the current flowing from the second terminal to the first terminal of the transistor Tr12 in each of the memory cell AM[2] and the memory cell AMref[2] is considered. When the current flowing from the wiring BL to the first terminal of the transistor Tr12 in the memory cell AM[1] through its second terminal is I_{AM[2],1}, I_{AM[2],1} can be expressed by the following formula.

[Formula 17]

I_{AM[2],1}=k(V_{PR}−V_{W[2]}+V_{X[2]}−Vₜₕ)² (E12)

In other words, by application of the potential V_{X[2]} to the wiring CL[2], the current flowing from the wiring BL to the first terminal of the transistor Tr12 in the memory cell AM[2] through its second terminal increases by I_{AM[2],0}−I_{AM[2],0} (denoted by ΔI_{AM[2]} in FIG. 13).

Similarly, when current flowing from the wiring BLref to the first terminal of the transistor Tr12 in the memory cell AMref[2] through its second terminal is I_{AMref[2],1}, I_{AMref[2],1} can be expressed by the following formula.

[Formula 18]

I_{AMref[2],1}=k(V_{PR}+V_{X[2]}−Vₜₕ)² (E13)

In other words, by application of the potential V_{X[2]} to the wiring CL[2], the current flowing from the wiring BLref to the first terminal of the transistor Tr12 in the memory cell AMref[2] through its second terminal increases by I_{AMref[2],1}−I_{AMref[2],0} (denoted by ΔI_{AMref[2]} in FIG. 13).

Here, currents that flow in the wiring BL and the wiring BLref are described.

As in the period from Time T04 to Time T05, the current I_{Cref} from the current supply circuit CS is supplied to the wiring BLref. At the same time, current is let out by the current mirror circuit CM, the memory cell AMref[1], and the memory cell AMref[2] to the wiring BLref. When the current let out by the current mirror circuit CM is I_{CM,2} in the wiring BLref, the following formula is satisfied according to Kirchhoff's law.

[Formula 19]

I_{Cref}−I_{CM,2}=I_{AMref[1],1}+I_{AMref[2],1} (E14)

As in the period from Time T04 to Time T05, the current I_{C} from the current supply circuit CS is supplied to the wiring BL. At the same time, current is let out by the current mirror circuit CM, the memory cell AM[1], and the memory cell AM[2] to the wiring BL. Moreover, current flows from the wiring BL to the circuit OFST. When the current that flows from the wiring BL to the circuit OFST is I_{α,3} in the wiring BL, the following formula is satisfied according to Kirchhoff s law.

[Formula 20]

I_{C}−I_{CM,2}=I_{AM[1],1}+I_{AM[2],1}+I_{α,3} (E15)

The differential current ΔI_{α}, the difference between the current I_{α,0} flowing from the wiring BL to the circuit OFST during the period from Time T04 to Time T05 and the current I_{α,3} flowing from the wiring BL to the circuit OFST during the period from Time T07 to Time T08, can be expressed by the following formula, using Formula (E1) to Formula (E8) and Formula (E12) to Formula (E15).

[Formula 21]

ΔI_{α}=I_{α,0}−I_{α,3}=2k(V_{W[1]}V_{X[1]}V_{W[2]}V_{X[2]}) (E16)

As shown by Formula (E11) and Formula (E16), the differential current ΔI_{α} input to the circuit OFST has a value corresponding to the sum of products of the potential V_{W}, which is a plurality of pieces of the first data, and the potential V_{X}, which is a plurality of pieces of the second data. In other words, when the differential current ΔI_{α} is measured by the circuit OFST, the value of the sum of products of the first data and the second data can be obtained.

### <<From Time T08 to Time T09>>

During a period from Time T08 to Time T09, the reference potential is applied to the wiring CL[1] and the wiring CL[2]. At this time, the reference potential is applied to the second terminal of the capacitor C1 in each of the memory cell AM[1], the memory cell AM[2], the memory cell AMref[1], and the memory cell AMref[2]; thus, the potentials of the node NM[1], the node NM[2], the node NMref[1], and the node NMref[2] return to the potentials during the period from Time T06 to Time T07.

Although V_{X[1]} was applied to the wiring CL[1] during the period from Time T05 to Time T06 and V_{X[1]} and V_{X[2]} were applied to the wiring CL[1] and the wiring CL[2], respectively, during the period from Time T07 to Time T08, potentials that are applied to the wiring CL[1] and the wiring CL[2] may be lower than the reference potential REFP. In the case where a potential lower than the reference potential REFP is applied to the wiring CL[1] and/or the wiring CL[2], the potential of a retention node of a memory cell connected to the wiring CL[1] and/or the wiring CL[2] can be decreased by capacitive coupling. Thus, multiplication of the first data and one piece of the second data, which is a negative value, can be performed in the product-sum operation. For example, in the case where −V_{X[2]}, instead of V_{X[2]}, is applied to the wiring CL[2] during the period from Time T07 to Time T08, the differential current ΔL can be expressed by the following formula.

[Formula 22]

ΔI_{α}=I_{α,0}I_{α,3}=2k(V_{W[1]}V_{X[1]}−V_{W[2]}V_{X[2]}) (E17)

Although the memory cell array CA including memory cells arranged in a matrix of two rows and two columns is used in this operation example, product-sum operation can be similarly performed in a memory cell array of one row and two or more columns and a memory cell array of three or more rows and three or more columns. In a product-sum operation circuit of such a case, memory cells in one of the plurality of columns are used for retaining reference data (potential V_{PR}), whereby product-sum operations, the number of which corresponds to the number of rest of the columns among the plurality of columns, can be executed concurrently. That is, when the number of columns in a memory cell array is increased, a semiconductor apparatus that achieves high-speed product-sum operation can be provided. Furthermore, when the number of rows is increased, the number of terms to be added in the product-sum operation can be increased. The differential current ΔL when the number of rows is increased can be expressed by the following formula.

$$\begin{matrix}[ Formula 23 ] & \\ Δ {I}_{α} = 2 k {\sum }_{i} {V}_{W [ i ]} {V}_{X [ i ]} & ( E18 )\end{matrix}$$

In the case where the product-sum operation circuit described in this embodiment is used as the above-described hidden layer, the weight coefficient w_{s[k]s[k-1]}_{^{(k)}} is stored as the first data in each of the memory cells AM in the same column and the output signal z_{s[k-1]}_{^{(k-1)}} from the s[k−1]-th neuron in the (k−1)-th layer is used as a potential (the second data) applied from the wiring CL in each row, so that the sum of products of the first data and the second data can be obtained from the differential current ΔI_{α}. In addition, the value of the activation function is obtained using the value of the sum of products, so that the value of the activation function can be, as a signal, the output signal z_{s[k]}^{(k)} of the s[k]-th neuron in the k-th layer.

In the case where the product-sum operation circuit described in this embodiment is used as the above-described output layer, the weight coefficient w_{s[L]}_{ₛ}_{[L-1]}^{(L)} is stored as the first data in each of the memory cells AM in the same column and the output signal w_{s[L-1]}^{(L-1)} from the s[L−1]-th neuron in the (L−1)-th layer is used as a potential (the second data) applied from the wiring CL in each row, so that the sum of products of the first data and the second data can be obtained from the differential current ΔL_{α}. In addition, the value of the activation function is obtained using the value of the sum of products, so that the value of the activation function can be, as a signal, the output signal z_{s[L]}^{(L)} of the s[L]-th neuron in the L-th layer.

Note that the input layer described in this embodiment may function as a buffer circuit that outputs an input signal to the second layer.

By the way, in the arithmetic circuit described in this embodiment, the number of rows of the memory cells AM corresponds to the number of neurons in the previous layer. In other words, the number of rows of the memory cells AM corresponds to the number of output signals of the neurons in the previous layer that are input to one neuron in the next layer. The number of columns of the memory cells AM corresponds to the number of neurons in the next layer. In other words, the number of columns of the memory cells AM corresponds to the number of output signals that are output from the neurons in the next layer. That is to say, the number of rows and the number of columns in the memory cell array of the arithmetic circuit are determined depending on the number of neurons in each of the previous layer and the next layer; thus, a neural network is designed by determining the number of rows and the number of columns in the memory cell array depending on the desired structure.

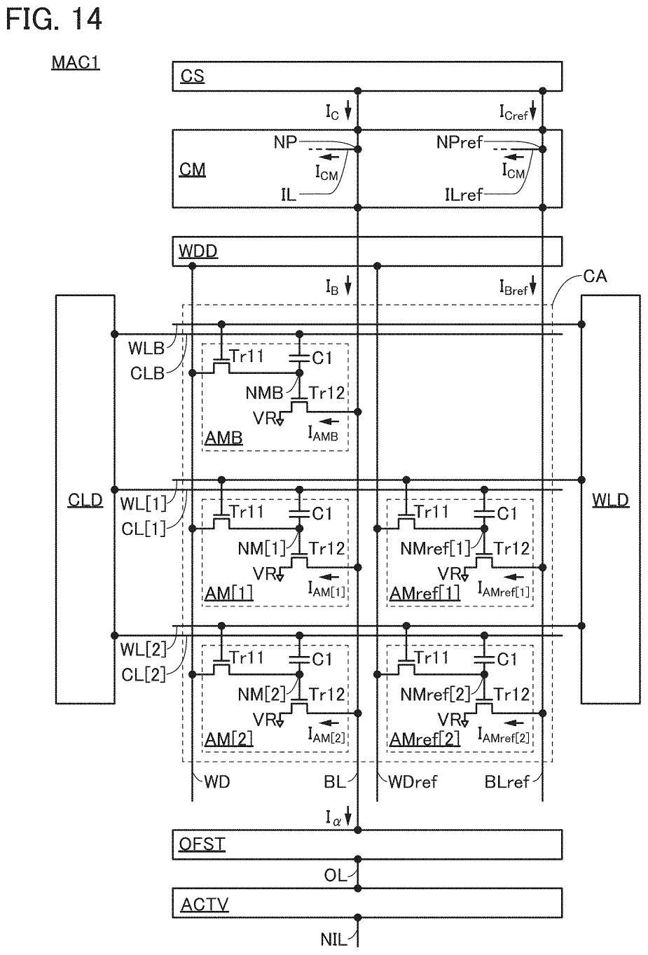

The structure of the arithmetic circuit described in this embodiment may be changed depending on circumstances. For example, the arithmetic circuit MAC1 illustrated in FIG. 11 may be changed into the arithmetic circuit MAC1 illustrated in FIG. 14. The arithmetic circuit MAC1 in FIG. 14 has a structure in which a memory cell AMB is added to the column including the memory cell AM[1] and the memory cell AM[1] in the memory cell array CA of the arithmetic circuit MAC1 in FIG. 11.

The memory cell AMB is electrically connected to the wiring WD, the wiring BL, a wiring WLB, and a wiring CLB. The wiring WLB is electrically connected to the circuit WLD, and the wiring CLB is electrically connected to the circuit CLD.

In the memory cell AMB, a connection portion of the first terminal of the transistor Tr11, the gate of the transistor Tr12, and the first terminal of the capacitor C1 is a node NMB.

The wiring WLB functions as a wiring for supplying a selection signal from the circuit WLD to the memory cell AMB when data is written to the memory cell AMB. The wiring CLB functions as a wiring for applying a constant potential to the second terminal of the capacitor C1 of the memory cell AMB. The constant potential is preferably a ground potential or a low-level potential.

An operation example of the arithmetic circuit MAC1 in FIG. 14 is that a ground potential, a low-level potential, or a potential supplied by the wiring VR is retained at the node NMB in the period from Time T01 to Time T05 in the timing chart in FIG. 13 so that the transistor Tr12 of the memory cell AMB is in an off state, for example. Then, a potential V_{BIAs} is retained at the node NMB in the period from Time T05 to Time T09 in the timing chart in FIG. 13 so that a given current ImAs flows between a source and a drain of the transistor Tr12 of the memory cell AMB. Here, I_{BIAs} is expressed by the following formula.

[Formula 24]

I_{BIAS}=k(V_{PR}−V_{BIAS}−Vₜₕ)² (E19)

In this case, Formula (E16) and Formula (E18) can be rewritten into the following formulae.

$$\begin{matrix}[ Formula 25 ] & \\ Δ {I}_{α} = {I}_{α , 0} - {I}_{α , 3} = 2 k ( {V}_{W [ 1 ]} {V}_{X [ 1 ]} + {V}_{W [ 2 ]} {V}_{X [ 2 ]} ) - {I}_{B I A S} & ( E20 ) \\ [ Formula 26 ] & \\ Δ {I}_{α} = 2 k {\sum }_{i} {V}_{W [ i ]} {V}_{X [ i ]} - {I}_{BIAS} & ( E21 )\end{matrix}$$

Formula (E20) and Formula (E21) each correspond to arithmetic operation for further supplying a given bias for the result of the product-sum operation. That is, by using the arithmetic circuit MAC1 in FIG. 14, the arithmetic operation of Formula (D3) can be performed. Note that I_{BIAS} is determined by not only the potential of the node NMB but also a potential supplied by the wiring CLB; thus, for example, in the timing chart in FIG. 13, a ground potential may be supplied to the wiring CLB in the period from Time T01 to Time T05 so that the transistor Tr12 of the memory cell AMB is in an off state, and the potential of the wiring CLB may be changed from the ground potential to a given potential in the period from Time T05 to Time T09 so that the given current I_{BIAS} flows between the source and the drain of the transistor Tr12 of the memory cell AMB.

### <Structure Example 2 of Arithmetic Circuit>

Next, an example of a circuit, which has a circuit structure different from that of the arithmetic circuit MAC1 and performs product-sum operation and arithmetic operation of an activation function, in the above-described neural network 200 will be described.

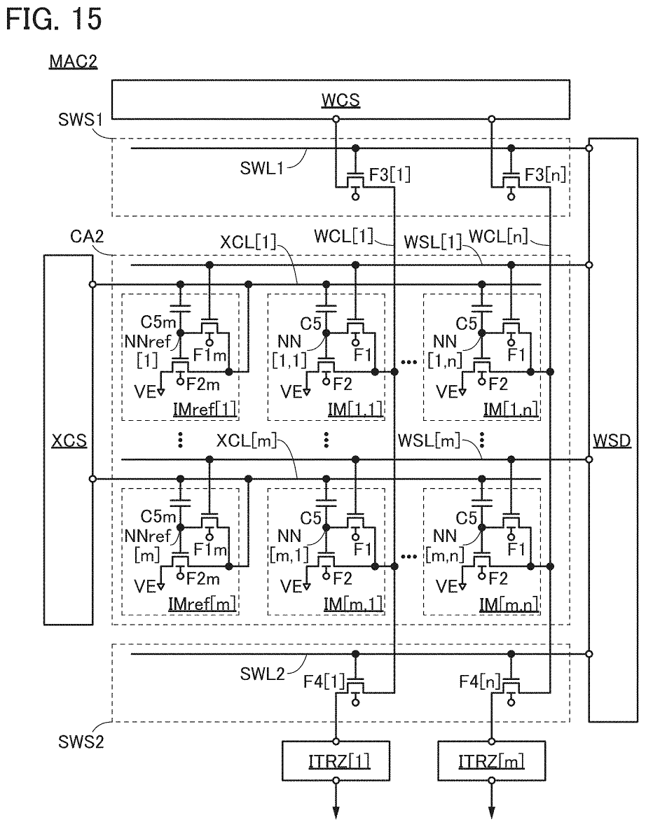

FIG. 15 shows a structure example of an arithmetic circuit MAC2. The arithmetic circuit MAC2 illustrated in FIG. 15 is a circuit that performs product-sum operation of the first data corresponding to a voltage retained in each cell and the second data input to the memory cell, and performs arithmetic operation of an activation function using the result of the product-sum operation. Note that the first data and the second data can be analog data or multilevel data (discrete data), for example.

The arithmetic circuit MAC2 includes a circuit WCS, a circuit XCS, a circuit WSD, a circuit SWS1, a circuit SWS2, a cell array CA2, and a converter circuit ITRZ[1] to a converter circuit ITRZ [m].

The cell array CA2 includes a cell IM[1,1] to a cell IM[m,n] (here, m is an integer greater than or equal to 1 and n is an integer greater than or equal to 1) and a cell IMref[1] to a cell IMref[m]. The cell IM[1,1] to the cell IM[m,n] have a function of retaining a potential corresponding to the amount of current corresponding to the first data, and the cell IMref[1] to the cell IMref[m] have a function of supplying a voltage corresponding to the second data required for performing product-sum operation with the retained potential to signal lines XCL[1] to XCL[m], respectively.

In the cell array CA2 in FIG. 15, cells are arranged in a matrix of n+1 rows and m columns; however, the cell array CA2 may have a structure in which cells are arranged in a matrix of two or more rows and one or more columns.

The cell IM[1,1] to the cell IM[m,n] each include a transistor F1, a transistor F2, and a capacitor C5, and the cell IMref[1] to the cell IMref[m] each include a transistor F1m, a transistor F2m, and a capacitor C5m.

Unless otherwise specified, the transistor F1 and the transistor F1m in an on state may operate in a linear region in the end. In other words, the gate voltage, the source voltage, and the drain voltage of each of the above-described transistors may be appropriately biased to voltages in the range where the transistor operates in the linear region. However, one embodiment of the present invention is not limited thereto. For example, the transistor F1 and the transistor F1m in an on state may operate in a saturation region or may operate both in a linear region and a saturation region.

Unless otherwise specified, the transistor F2 and the transistor F2m may operate in a subthreshold region (i.e., the gate-source voltage of the transistor F2 or the transistor F2m may be lower than the threshold voltage). In other words, the gate voltage, the source voltage, and the drain voltage of each of the above-described transistors may be appropriately biased to voltages in the range where the transistor operates in the subthreshold region. Thus, the transistors F2 and the transistor F2m may operate so that an off-state current flows between a source and a drain.

Like the transistor Tr11, the transistor F1 and/or the transistor F1m is preferably an OS transistor. In addition, it is further preferable that a channel formation region of the transistor F1 and/or the transistor F1m be a metal oxide containing at least one of an indium, an element M (examples of the element M include one or more kinds selected from aluminum, gallium, yttrium, copper, vanadium, beryllium, boron, titanium, iron, nickel, germanium, zirconium, molybdenum, lanthanum, cerium, neodymium, hafnium, tantalum, tungsten, magnesium, and the like), and zinc. It is further preferable that the transistor Tr11 have a structure of the transistor described in the following embodiment, in particular.

With the use of an OS transistor as the transistor F1 and/or the transistor F1m, the leakage current of the transistor F1 and/or the transistor F1m can be suppressed, so that a product-sum operation circuit with high calculation accuracy can be obtained in some cases. Furthermore, with the use of an OS transistor as the transistor F1 and/or the transistor F1m, the amount of leakage current from a retention node to a writing word line can be extremely small when the transistor F1 and/or the transistor F1m is in a non-conduction state. In other words, the frequency of refresh operation for the potential at the retention node can be reduced; thus, power consumption of the product-sum operation circuit can be reduced.

The use of an OS transistor also as the transistor F2 and/or the transistor F2m enables operation with a wide range of current in the subthreshold region, leading to a reduction in the current consumption. The use of an OS transistor also as the transistor F2 and/or the transistor F2m allows the transistor F2 and/or the transistor F2m to be formed concurrently with the transistor Tr11, leading to a reduction in the number of manufacturing steps for the product-sum operation circuit, in some cases. The transistor F2 and/or the transistor F2m may be a transistor including silicon in a channel formation region. As the silicon, for example, amorphous silicon, microcrystalline silicon, polycrystalline silicon, single crystal silicon, hydrogenated amorphous silicon, or the like can be used.

In each of the cell IM[1,1] to the cell IM[m,n], a first terminal of the transistor F1 is electrically connected to a gate of the transistor F2. A first terminal of the transistor F2 is electrically connected to a wiring VE. A first terminal of the capacitor C5 is electrically connected to the gate of the transistor F2.

One embodiment of the present invention does not depend on the connection structure of a back gate of a transistor. In each of the transistor F1 and the transistor F2 in FIG. 15, the back gate is illustrated and the structure including the back gate is illustrated, but the connection structure of the back gate is not illustrated; however, a target to which the back gate is electrically connected can be determined at the design stage. For example, in a transistor including a back gate, a gate and the back gate may be electrically connected to each other to increase the on-state current of the transistor. In other words, the gate and the back gate of a transistor M2 may be electrically connected to each other, for example. Alternatively, for example, in a transistor including a back gate, a wiring electrically connected to an external circuit or the like may be provided and a potential may be supplied to the back gate of the transistor by the external circuit or the like to change the threshold voltage of the transistor or to reduce the off-state current of the transistor. Note that the same applies to the transistor F1m and the transistor F2m, a transistor F3[1] to a transistor F3 [n] and a transistor F4[1] to a transistor F4[n] which are described later, a transistor described in other parts of the specification, and a transistor illustrated in drawings other than FIG. 15.

The semiconductor apparatus of one embodiment of the present invention does not depend on the structure of a transistor included in the semiconductor apparatus. For example, the transistor F1 and the transistor F2 illustrated in FIG. 15 may each be a transistor having a structure not including a back gate, that is, a single-gate structure as illustrated in FIG. 15. It is also possible that some transistors have a structure including a back gate and the other transistors have a structure not including a back gate. Note that the same applies to the transistor F1m and the transistor F2m, the transistor F3[1] to the transistor F3[n] and the transistor F4[1] to the transistor F4[n] which are described later, a transistor described in other parts of the specification, and a transistor illustrated in drawings other than the circuit diagram illustrated in FIG. 15.

The wiring VE functions as a wiring for flowing a current between the first terminal and a second terminal of the transistor F2 of each of the cell IM[1,1], the cell IM[m,1], the cell IM[1,n], and the cell IM[m,n] and a wiring for flowing a current between the first terminal and the second terminal of the transistor F2 of each of the cell IMref[1] and the cell IMref[m]. The wiring VE functions as a wiring for supplying a constant voltage, for example. The constant voltage can be, for example, a low-level voltage, a ground potential, or the like.

In the cell IM[1,1], a second terminal of the transistor F1 is electrically connected to a wiring WCL[1], and a gate of the transistor F1 is electrically connected to a wiring WSL[1]. The second terminal of the transistor F2 is electrically connected to the wiring WCL[1], and a second terminal of the capacitor C5 is electrically connected to the wiring XCL[1]. In FIG. 15, in the cell IM[1,1], a connection portion of the first terminal of the transistor F1, the gate of the transistor F2, and the first terminal of the capacitor C5 is a node NN[1,1].

In the cell IM[m,1], the second terminal of the transistor F1 is electrically connected to the wiring WCL[1], and the gate of the transistor F1 is electrically connected to a wiring WSL[m]. The second terminal of the transistor F2 is electrically connected to the wiring WCL[1], and the second terminal of the capacitor C5 is electrically connected to the wiring XCL[m]. In FIG. 15, in the cell IM[m,1], a connection portion of the first terminal of the transistor F1, the gate of the transistor F2, and the first terminal of the capacitor C5 is a node NN[m,1].

In the cell IM[1,n], the second terminal of the transistor F1 is electrically connected to a wiring WCL[n], and the gate of the transistor F1 is electrically connected to the wiring WSL[1]. The second terminal of the transistor F2 is electrically connected to the wiring WCL[n], and the second terminal of the capacitor C5 is electrically connected to the wiring XCL[1]. In FIG. 15, in the cell IM[1,n], a connection portion of the first terminal of the transistor F1, the gate of the transistor F2, and the first terminal of the capacitor C5 is a node NN[1,n].

In the cell IM[m,n], the second terminal of the transistor F1 is electrically connected to the wiring WCL[n], and the gate of the transistor F1 is electrically connected to the wiring WSL[m]. The second terminal of the transistor F2 is electrically connected to the wiring WCL[n], and the second terminal of the capacitor C5 is electrically connected to the wiring XCL[m]. In FIG. 15, in the cell IM[m,n], a connection portion of the first terminal of the transistor F1, the gate of the transistor F2, and the first terminal of the capacitor C5 is a node NN[m,n].

In the cell IMref[1], a second terminal of the transistor F1m is electrically connected to the wiring XCL[1], and a gate of the transistor F1m is electrically connected to the wiring WSL[1]. A second terminal of the transistor F2m is electrically connected to the wiring XCL[1], and the second terminal of the capacitor C5 is electrically connected to the wiring XCL[1]. In FIG. 15, in the cell IMref[1], a connection portion of a first terminal of the transistor Flm, a gate of the transistor F2m, and the first terminal of the capacitor C5 is a node NNref[1].

In the cell IMref[m], the second terminal of the transistor F1m is electrically connected to the wiring XCL[m], and the gate of the transistor F1m is electrically connected to the wiring WSL[m]. A second terminal of the transistor F2m is electrically connected to the wiring XCL[m], and the second terminal of the capacitor C5 is electrically connected to the wiring XCL[m]. In FIG. 15, in the cell IMref[m], a connection portion of the first terminal of the transistor Flm, the gate of the transistor F2m, and the first terminal of the capacitor C5 is a node NNref[m].

The node NN[1,1], the node NN[m,1], the node NN[1,n], the node NN[m,n], the node NNref[1], and the node NMref[m] described above function as a retention node of the respective cells.

The circuit SWS1 includes the transistor F3[1] to the transistor F3[n]. A first terminal of the transistor F3[1] is electrically connected to the wiring WCL[1], a second terminal of the transistor F3[1] is electrically connected to the circuit WCS, and a gate of the transistor F3[1] is electrically connected to a wiring SWL1. A first terminal of the transistor F3[m] is electrically connected to the wiring WCL[m], a second terminal of the transistor F3[m] is electrically connected to the circuit WCS, and a gate of the transistor F3[m] is electrically connected to the wiring SWL1.

Like the transistor Tr11, the transistor F3[1] to the transistor F3[n] are each preferably an OS transistor. In addition, it is further preferable that a channel formation region of the transistor F1 and/or the transistor F1m be a metal oxide containing at least one of an indium, an element M (examples of the element M include one or more kinds selected from aluminum, gallium, yttrium, copper, vanadium, beryllium, boron, titanium, iron, nickel, germanium, zirconium, molybdenum, lanthanum, cerium, neodymium, hafnium, tantalum, tungsten, magnesium, and the like), and zinc. It is further preferable that the transistor F4[1] to the transistor F4[n] each have a structure of the transistor described in the following embodiment, in particular.

The circuit SWS1 functions as a circuit that switches the conduction state and the non-conduction state between the circuit WCS and each of the wiring WCL[1] to the wiring WCL[n].

The circuit SWS2 includes the transistor F4[1] to the transistor F4[n]. A first terminal of the transistor F4[1] is electrically connected to the wiring WCL[1], a second terminal of the transistor F4[1] is electrically connected to the converter circuit ITRZ[1], and a gate of the transistor F4[1] is electrically connected to a wiring SWL2. A first terminal of the transistor F4[m] is electrically connected to the wiring WCL[m], a second terminal of the transistor F4[m] is electrically connected to the converter circuit ITRZ[1], and a gate of the transistor F4[m] is electrically connected to the wiring SWL2.

Like the transistor Tr11, the transistor F4[1] to the transistor F4[n] are each preferably an OS transistor. In addition, it is further preferable that a channel formation region of the transistor F1 and/or the transistor F1m be a metal oxide containing at least one of an indium, an element M (examples of the element M include one or more kinds selected from aluminum, gallium, yttrium, copper, vanadium, beryllium, boron, titanium, iron, nickel, germanium, zirconium, molybdenum, lanthanum, cerium, neodymium, hafnium, tantalum, tungsten, magnesium, and the like), and zinc. It is further preferable that the transistor F4[1] to the transistor F4[n] each have a structure of the transistor described in the following embodiment, in particular.

The circuit SWS2 functions as a circuit that switches the conduction state and the non-conduction state between the wiring WCL[1] and the circuit ITRZ[1] and between the wiring WCL[n] and a circuit ITRZ[n].

The circuit WCS has a function of transmitting data that is to be stored in each memory cell included in the cell array CA2.

The circuit XCS is electrically connected to the wiring XCL[1] to the wiring XCL[m]. The circuit XCS has a function of flowing a current corresponding to reference data or a current corresponding to the second data to each of the cell IMref[1] to the cell IMref[m] included in the cell array CA2.

The circuit WSD is electrically connected to the wiring WSL[1] to the wiring WSL[m]. The circuit WSD has a function of selecting a memory cell to which data is written by transmitting a predetermined signal to each of the wiring WSL[1] to the wiring WSL[m] when the first data is written to the cell included in the cell array CA2.

The circuit WSD is electrically connected to the wiring SWL1 and the wiring SWL2. The circuit WSD has a function of establishing or breaking electrical continuity between the circuit WCS and the cell array CA2 by transmitting a predetermined signal to the wiring SWL1, and a function of establishing or breaking electrical continuity between the cell array CA2 and each of the converter circuit ITRZ[1] to the converter circuit ITRZ[m] by transmitting a predetermined signal to the wiring SWL2.

The converter circuit ITRZ[1] to the converter circuit ITRZ[m] each include an input terminal and an output terminal. The converter circuit ITRZ[1] to the converter circuit ITRZ[m] each have a function of converting a current input to the input terminal into a voltage and outputting the voltage from the output terminal. As each of the converter circuit ITRZ[1] to the converter circuit ITRZ[m], the circuit OFST can be used, for example. The converter circuit ITRZ[1] to the converter circuit ITRZ[m] may each include the activation function circuit ACTV, and may each perform arithmetic operation of an activation function by using the converted voltage and output the result of the arithmetic operation to the output terminal.

### <Operation Example 2 of Arithmetic Circuit>

Next, an operation example of the arithmetic circuit MAC2 is described.

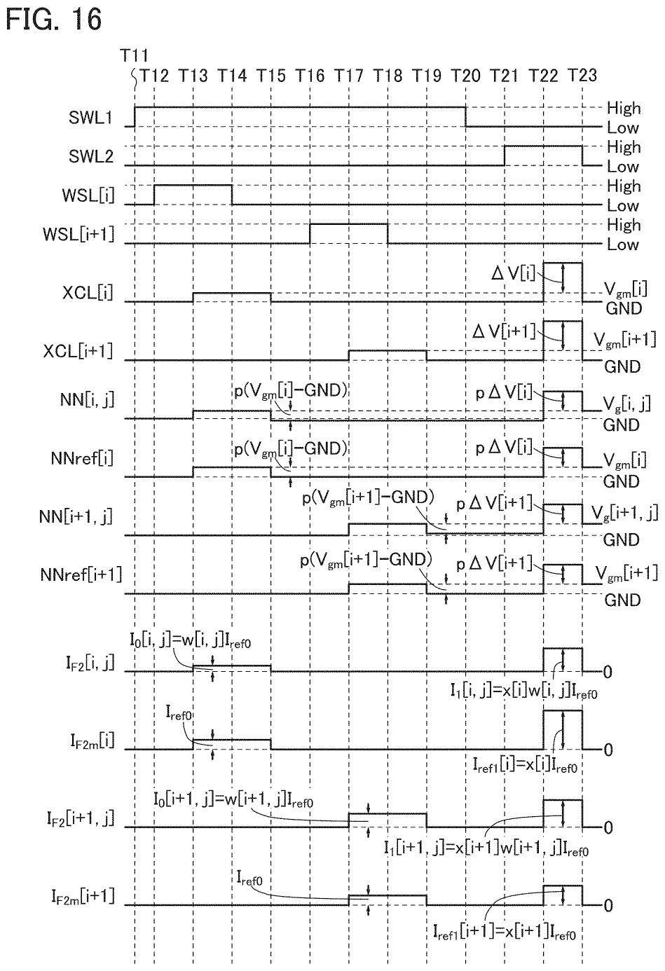

FIG. 16 shows a timing chart of the operation example of the arithmetic circuit MAC2. The timing chart in FIG. 16 shows changes in the potentials of the wiring SWL1, the wiring SWL2, a wiring WSL[i] (i is an integer greater than or equal to 1 and less than or equal to m−1), a wiring WSL[i+1], a wiring XCL[i], a wiring XCL[i+1], a node NN[i,j], a node NN[i+1,j], a node NNref[i], and a node NN[i+1] in the period from Time T11 to Time T21 and around the period. The timing chart in FIG. 16 also shows changes in the amount of current I_{F2}[i,j] flowing between the first terminal and the second terminal of the transistor F2 included in the cell IM[i,j]; the amount of current I_{F2m}[i] flowing between a first terminal and the second terminal of the transistor F2m included in the cell IMref[i]; the amount of current I_{F2}[i+1,j] flowing between the first terminal and the second terminal of the transistor F2 included in the cell IM[i+1,j]; and the amount of current I_{F2m}[i+1] flowing between the first terminal and the second terminal of the transistor F2m included in the cell IMref[i+1].

Note that in this operation example, the potential of the wiring VE is the ground potential GND. In addition, before Time T11, the transistors F1 included in the cell IM[i,j] and the cell IM[i+1,j] and the transistors F1m included in the cell IMref[i] and the cell IMref[i+1] are turned on and the potentials of the node NN[i,j], the node NN[i+1,j], the node NNref[i], and the node NN[i+1] are set to the ground potential GND.

Furthermore, as an initial setting, the transistors F1 included in the cell IM[1,1] to the cell IM[m,n] and the transistors F1m included in the cell IMref[1] to the cell IMref[m] are turned on and the potentials of the node NN[1,1] to the node NN[m,n] and the node NNref[1] to the node NNref[m] are set to the ground potential GND.

### <<From Time T11 to Time T12>>

In the period from Time T11 to Time T12, a high-level potential (denoted by High in FIG. 16) is applied to the wiring SWL1, and a low-level potential (denoted by Low in FIG. 16) is applied to the wiring SWL2. Accordingly, the high-level potential is applied to each of the gates of the transistor F3[1] to the transistor F3[n] and the transistor F3[1] to the transistor F3[n] are turned on, and the low-level potential is applied to each of the gates of the transistor F4[1] to the transistor F4[n] and the transistor F4[1] to the transistor F4[n] are turned off.

In the period from Time T11 to Time T12, a low-level potential is applied to each of the wiring WSL[i] and the wiring WSL[i+1]. Accordingly, in the i-th row of the cell array CA2, the low-level potential is applied to each of the gates of the transistors F1 included in a cell IM[i,1] to a cell IM[i,n] and the gate of the transistor F1m included in the cell IMref[i], and the transistors F1 and the transistor F1m are turned off. In addition, in the i+1-th row of the cell array CA2, the low-level potential is applied to each of the gates of the transistors F1 included in a cell IM[i+1,1] to a cell IM[i+1,n] and the gate of the transistor F1m included in the cell IMref[i+1], and the transistors F1 and the transistor F1m are turned off.

In the period from Time T11 to Time T12, the ground potential GND is applied to the wiring XCL[i] and the wiring XCL[i+1].

In the period from Time T11 to Time T12, a current does not flow through a wiring WCL[j], the wiring XCL[i], and the wiring XCL[i+1]. Therefore, I_{F2[i,j]}, I_{F2m[i]}, I_{F2[i+1,j]}, and I_{F2m[i+1]} are each 0.

### <<From Time T12 to Time T13>>

In the period from Time T12 to Time T13, a high-level potential is applied to the wiring WSL[i]. Accordingly, in the i-th row of the cell array CA2, the high-level potential is applied to each of the gates of the transistors F1 included in the cell IM[i,1] to the cell IM[i,n] and the gate of the transistor F1m included in the cell IMref[i], and the transistors F1 and the transistor F1m are turned on. Furthermore, in the period from Time T12 to Time T13, a low-level potential is applied to each of the wiring WSL[1] to the wiring WSL[m] except the wiring WSL[i], and in the cell array CA2, the transistors F1 included in the cell IM[1,1] to the cell IM[m,n] in the rows other than the i-th row and the transistors F1m included in the cell IMref[1] to the cell IMref[m] in the rows other than the i-th row are in an off state.

Furthermore, a low-level potential is applied to each of the wiring XCL[1] to the wiring XCL[m].

### <<From Time T13 to Time T14>>

In the period from Time T13 to Time T14, a current of I₀[i,j] flows from the circuit WCS to the cell array CA2 through a transistor F3[j]. Since electrical continuity is established between the wiring WCL[j] and the first terminal of the transistor F1 included in the cell in the i-th row of the cell array CA2 and electrical continuity is broken between the wiring WCL[j] and the first terminal of the transistor F1 included in each of the cell IM[i,j] to the cell IM[m,j] in the rows other than the i-th row of the cell array CA2, so that the current of I₀[i,j] flows from the wiring WCL[j] to the cell IM[i,j].

When the transistor F1 included in the cell IM[i,j] is turned on, the transistor F2 included in the cell IM[i,j] has a diode-connected structure. Therefore, when a current flows from the wiring WCL[j] to the cell the potentials of the gate of the transistor F2 and the second terminal of the transistor F2 are substantially equal to each other. The potentials are determined by the amount of current flowing from the wiring WCL[j] to the cell IM[i,j] the potential of the first terminal of the transistor F2 (here, GND), and the like. In this operation example, the current of I₀[i,j] flows from the wiring WCL[j] to the cell IM[i,j], whereby the potential of the gate of the transistor F2 (the node NN[i,j]) becomes V_{g}[i,j]. That is, the gate-source voltage of the transistor F2 is V_{g}[i,j]-GND, and the current of I₀[i,j] flows between the first terminal and the second terminal of the transistor F2.

Here, the amount of current I₀[i,j] in the case where the threshold voltage of the transistor F2 is Vₜₕ and the transistor F2 operates in a subthreshold region can be expressed by the following formula.

[Formula 27]

I₀[i,j]=Iₐ exp{K(V_{g}[i,j]−vₜₕ[i,j])} (F1)

Note that Iₐ represents a drain current when V_{g} is Vₜₕ[i,j], and K represents a correction coefficient determined in accordance with temperature, a device structure, or the like.

Furthermore, in the period from Time T13 to Time T14, a current of I_{ref0} flows from the circuit XCS to the wiring XCL[i]. At this time, electrical continuity is established between the first terminal of the transistor F1m included in the cell IMref[i] and the wiring XCL[i], so that the current of I_{ref0} flows from the wiring XCL[i] to the cell IMref[i].

As in the cell when the transistor F1m included in the cell IMref[i] is turned on, the transistor F2m included in the cell IMref[i,j] has a diode-connected structure. Therefore, when a current flows from the wiring XCL[i] to the cell IMref[i], the potentials of the gate of the transistor F2m and the second terminal of the transistor F2m are substantially equal to each other. The potentials are determined by the amount of current flowing from the wiring XCL[i] to the cell IMref[i], the potential of the first terminal of the transistor F2m (here, GND), and the like. In this operation example, the current of I_{ref0} flows from the wiring XCL[i] to the cell IMref[i], whereby the potential of the gate of the transistor F2 (the node NNref[i]) becomes V_{gm}[i], and the potential of the wiring XCL[i] at this time is also V_{gm}[i]. That is, the gate-source voltage of the transistor F2m is V_{gm}[i]-GND, and the current of I_{ref0} flows between the first terminal and the second terminal of the transistor F2m.

Here, the amount of current I_{ref0} in the case where the threshold voltage of the transistor F2m is Vₜₕₘ[i] and the transistor F2m operates in a subthreshold region can be expressed by the following formula. Note that the correction coefficient K is the same as that of the transistor F2 included in the cell IM[i,j]. For example, the device structures, sizes (channel lengths or channel widths), or the like of the transistors are the same. In addition, although the correction coefficient K of each transistor varies due to variation in manufacturing, the variation is suppressed so that the following arguments make sense with sufficient accuracy for practical use.

[Formula 28]

I_{ref0}=Iₐ exp{K(V_{gm}[i]−Vₜₕₘ[i])} (F2)

Here, a weight coefficient w[i,j] that is the first data is defined as follows.

[Formula 29]

w[i,j]=exp{K(V_{g}[i,j]−Vₜₕ[i,j]−V_{gm}[i]+Vₜₕₘ[i])} (F3)

Therefore, Formula (F1) can be rewritten into the following formula.

[Formula 30]

I₀[i,j]=w[i,j]I_{ref0} (F4)

### <<From Time T14 to Time T15>>

In the period from Time T14 to Time T15, a low-level potential is applied to the wiring WSL[i]. Accordingly, in the i-th row of the cell array CA2, the low-level potential is applied to each of the gates of the transistors F1 included in the cell IM[i,1] to the cell IM[i,n] and the gate of the transistor F1m included in the cell IMref[i], and the transistors F1 and the transistor F1m are turned off.

When the transistor F1 included in the cell IM[i,j] is turned off, V_{g}[i,j]−V_{gm}[i], which is a difference between the potential of the gate of the transistor F2 (the node NN[i,j]) and the potential of the wiring XCL[i], is retained in the capacitor C5. Moreover, when the transistor F1 included in the cell IMref[i] is turned off, 0, which is a difference between the potential of the gate of the transistor F2m (the node NNref[i]) and the potential of the wiring XCL[i], is retained in the capacitor C5m. Note that in the operation in the period from Time T13 to Time T14, the potential retained in the capacitor C5m may be a potential that is not 0 (here, Δ) depending on the transistor characteristics or the like of the transistor F1m and the transistor F2m. However, when the potential of the node NNref[i] is considered to be a potential obtained by adding Δ to the potential of the wiring XCL[i], the following arguments make sense.

### <<From Time T15 to Time T16>>

In the period from Time T15 to Time T16, GND is applied to the wiring XCL[i]. Thus, the potentials of the node NN[i,1] to the node NN[i,n] change because of capacitive coupling of the capacitors C5 included in the cell IM[i,1] to the cell IM[i,n] in the i-th row, and the potential of the node NNref[i] changes because of capacitive coupling of the capacitor C5 included in the cell IMref[i].

The amount of change in the potentials of the node NN[i,1] to the node NN[i,n] is a potential obtained by multiplying the amount of change in the potential of the wiring XCL[i] by a capacitive coupling coefficient determined by the structures of the cell IM[i,1] to the cell IM[i,n] included in the cell array CA2. The capacitive coupling coefficient is calculated using the capacitance of the capacitor C5, the gate capacitance of the transistor F2, the parasitic capacitance, and the like. In the case where the capacitive coupling coefficient due to the capacitor C5 is p in the cell IM[i,1] to the cell IM[i,n], the potential of the node NN[i,j] of the cell decreases from the potential in the period from Time T14 to Time T15 by p(V_{gm}[i]−GND).

Similarly, when the potential of the wiring XCL[i] changes, the potential of the node NNref[i] also changes because of capacitive coupling of the capacitor C5m included in the cell IMref[i]. The potential of the node NNref[i] of the cell IMref[i] in the case where the capacitive coupling coefficient due to the capacitor C5m is p like that due to the capacitor C5 decreases from the potential in the period from Time T14 to Time T15 by p(V_{gm}[i]−GND).

Accordingly, the potential of the node NN[i,j] of the cell decreases, so that the transistor F2 is turned off; similarly, the potential of the node NNref[i] of the cell IMref[i] decreases, so that the transistor F2m is also turned off. Therefore, I_{F2}[i,j] and I_{F2m}[i] are each 0 in the period from Time T15 to Time T16.

### <<From Time T16 to Time T17>>

In the period from Time T16 to Time T17, a high-level potential is applied to the wiring WSL[i+1]. Accordingly, in the i+1-th row of the cell array CA2, the high-level potential is applied to each of the gates of the transistors F1 included in the cell IM[i+1,1] to the cell IM[i+1,n] and the gate of the transistor F1m included in the cell IMref[i+1], and the transistors F1 and the transistor F1m are turned on. Furthermore, in the period from Time T16 to Time T17, a low-level potential is applied to each of the wiring WSL[1] to the wiring WSL[m] except the wiring WSL[i+1], and in the cell array CA2, the transistors F1 included in the cell IM[1,1] to the cell IM[m,n] in the rows other than the i+1-th row and the transistors F1m included in the cell IMref[1] to the cell IMref[m] in the rows other than the i+1-th row are in an off state.

Furthermore, a low-level potential is applied to each of the wiring XCL[1] to the wiring XCL[m].

### <<From Time T17 to Time T18>>

In the period from Time T17 to Time T18, a current of I₀[i+1,j] flows from the circuit WCS to the cell array CA2 through the transistor F3[j]. Since electrical continuity is established between the wiring WCL[j] and the first terminal of the transistor F1 included in the cell IM[i+1,j] in the i+1-th row of the cell array CA2 and electrical continuity is broken between the wiring WCL[j] and the first terminal of the transistor F1 included in each of the cell IM[1,j] to the cell IM[m,j] in the rows other than the i+1-th row of the cell array CA2, so that the current of I₀[i+1,j] flows from the wiring WCL[j] to the cell IM[i+1,j].

When the transistor F1 included in the cell IM[i+1,j] is turned on, the transistor F2 included in the cell IM[i+1,j] has a diode-connected structure. Therefore, when a current flows from the wiring WCL[j] to the cell IM[i+1,j], the potentials of the gate of the transistor F2 and the second terminal of the transistor F2 are substantially equal to each other. The potentials are determined by the amount of current flowing from the wiring WCL[j] to the cell IM[i+1,j], the potential of the first terminal of the transistor F2 (here, GND), and the like. In this operation example, the current of I₀[i+1,j] flows from the wiring WCL[j] to the cell IM[i+1,j], whereby the potential of the gate of the transistor F2 (the node NN[i+1,j]) becomes V_{g}[i+1,j]. That is, the gate-source voltage of the transistor F2 is V_{g}[i+1,j]−GND, and the current of I₀[i+1,j] flows between the first terminal and the second terminal of the transistor F2.

Here, the amount of current I₀[i+1,j] in the case where the threshold voltage of the transistor F2 is Vₜₕ[i+1,j] and the transistor F2 operates in a subthreshold region can be expressed by the following formula. Note that a correction coefficient is K, which is the same as those of the transistor F2 included in the cell IM[i,j] and the transistor F2m included in the cell IMref[i].

[Formula 31]

I₀[i+1,j]=Iₐ exp{K(V_{g}[i+1,j]−Vₜₕ[i+1,j])} (F5)

Furthermore, in the period from Time T17 to Time T18, a current of I_{ref0} flows from the circuit XCS to the wiring XCL[i+1]. At this time, electrical continuity is established between the first terminal of the transistor F1m included in the cell IMref[i+1] and the wiring XCL[i+1], so that the current of I_{ref0} flows from the wiring XCL[i+1] to the cell IMref[i+1].

As in the cell IM[i+1,j], when the transistor F1m included in the cell IMref[i+1] is turned on, the transistor F2m included in the cell IMref[i+1,j] has a diode-connected structure. Therefore, when a current flows from the wiring XCL[i+1] to the cell IMref[i+1], the potentials of the gate of the transistor F2m and the second terminal of the transistor F2m are substantially equal to each other. The potentials are determined by the amount of current flowing from the wiring XCL[i+1] to the cell IMref[i+1], the potential of the first terminal of the transistor F2m (here, GND), and the like. In this operation example, the current of I_{ref0} flows from the wiring XCL[i+1] to the cell IMref[i+1], whereby the potential of the gate of the transistor F2 (the node NNref[i+1]) becomes V_{gm}[i+1], and the potential of the wiring XCL[i+1] is also V_{gm}[i+1]. That is, the gate-source voltage of the transistor F2m is V_{gm}[i+1]−GND, and the current of I_{ref0} flows between the first terminal and the second terminal of the transistor F2m.

Here, the amount of current I_{ref0} in the case where the threshold voltage of the transistor F2m is Vₜₕₘ[i+1,j] and the transistor F2m operates in a subthreshold region can be expressed by the following formula. Note that the correction coefficient K is the same as that of the transistor F2 included in the cell IM[i+1,j].

[Formula 32]

I_{ref0}=Iₐ exp{K(V_{gm}[i+1]−Vₜₕₘ[i+1])} (F6)

Here, a weight coefficient w[i+1,j] that is the first data is defined as follows.

[Formula 33]

w[i+1,j]=

exp{K(V_{g}[i+1,j]−Vₜₕ[i+1,j]−V_{gm}[i+1]+Vₜₕₘ[i+1])} (F7)

Therefore, Formula (F5) can be rewritten into the following formula.

[Formula 34]

I₀[i+1,j]=w[i+1,j]I_{ref0} (F8)

<<From Time T18 to Time T19>>

In the period from Time T18 to Time T19, a low-level potential is applied to the wiring WSL[i+1]. Accordingly, in the i-th row of the cell array CA2, the low-level potential is applied to each of the gates of the transistors F1 included in the cell IM[i+1,1] to the cell IM[i+1,n] and the gate of the transistor F1m included in the cell IMref[i+1], and the transistors F1 and the transistor F1m are turned off.

When the transistor F1 included in the cell IM[i+1,j] is turned off, V_{g}[i+1,j]−V_{gm}[i+1], which is a difference between the potential of the gate of the transistor F2 (the node NN[i+1,j]) and the potential of the wiring XCL[i+1], is retained in the capacitor C5. Moreover, when the transistor F1 included in the cell IMref[i+1] is turned off, 0, which is a difference between the potential of the gate of the transistor F2m (the node NNref[i+1]) and the potential of the wiring XCL[i+1], is retained in the capacitor C5m. Note that in the operation in the period from Time T18 to Time T19, the potential retained in the capacitor C5m may be a potential that is not 0 (here, Δ) depending on the transistor characteristics or the like of F1m and F2m. However, when the potential of the node NNref[i] is considered to be a potential obtained by adding Δ to the potential of the wiring XCL[i], the following arguments make sense.

### <<From Time T19 to Time T20>>

In the period from Time T19 to Time T20, GND is applied to the wiring XCL[i+1]. Thus, the potentials of the node NN[i,1] to the node NN[i+1,n] change because of capacitive coupling of the capacitors C5 included in the cell IM[i+1,1] to the cell IM[i+1,n] in the i+1-th row, and the potential of the node NNref[i+1] changes because of capacitive coupling of the capacitor C5 included in the cell IMref[i+1].

The amount of change in the potentials of the node NN[i+1,1] to the node NN[i+1,n] is a potential obtained by multiplying the amount of change in the potential of the wiring XCL[i+1] by a capacitive coupling coefficient determined by the structures of the cell IM[i+1,1] to the cell IM[i+1,n] included in the cell array CA2. The capacitive coupling coefficient is calculated using the capacitance of the capacitor C5, the gate capacitance of the transistor F2, the parasitic capacitance, and the like. In each of the cell IM[i+1,1] to the cell IM[i+1,n], in the case where the capacitive coupling coefficient due to the capacitor C5 is p, which is the same as the capacitive coupling coefficient due to the capacitor C5 in each of the cell IM[i,1] to the cell IM[i,n], the potential of the node NN[i+1,j] of the cell IM[i+1,j] decreases from the potential in the period from Time T18 to Time T19 by p(V_{gm}[i+1]−GND).

Similarly, when the potential of the wiring XCL[i+1] changes, the potential of the node NNref[i+1] also changes because of capacitive coupling of the capacitor C5m included in the cell IMref[i+1]. The potential of the node NNref[i+1] of the cell IMref[i+1] in the case where the capacitive coupling coefficient due to the capacitor C5m is p like that due to the capacitor C5 decreases from the potential in the period from Time T18 to Time T19 by p(V_{gm}[i+1]−GND).

Accordingly, the potential of the node NN[i+1,j] of the cell IM[i+1,j] decreases, so that the transistor F2 is turned off; similarly, the potential of the node NNref[i] of the cell IMref[i+1] decreases, so that the transistor F2m is also turned off. Therefore, I_{F2}[i+1,j] and I_{F2m}[i+1] are each 0 in the period from Time T19 to Time T20.

### <<From Time T20 to Time T21>>

In the period from Time T20 to Time T21, a low-level potential is applied to the wiring SWL1. Accordingly, the low-level potential is applied to each of the gates of the transistor F3[1] to the transistor F3[n], whereby the transistor F3[1] to the transistor F3[n] are brought into an off state.

### <<From Time T21 to Time T22>>

In the period from Time T21 to Time T22, a high-level potential is applied to the wiring SWL2. Accordingly, the high-level potential is applied to each of the gates of the transistor F4[1] to the transistor F4[n], whereby the transistor F4[1] to the transistor F4[n] are brought into an off state.

### <<From Time T22 to Time T23>>

In the period from Time T22 to Time T23, a current of x[i]I_{ref0}, which is x[i] times as high as I_{ref0}, flows from the circuit XCS to the wiring XCL[i]. Note that in this operation example, x corresponds to the value of a signal of a neuron that is the second data. At this time, the potential of the wiring XCL[i] changes from 0 to V_{gm}[i]+ΔV[i].

When the potential of the wiring XCL[i] changes, the potentials of the node NN[i,1] to the node NN[i,n] also change because of the capacitive coupling of the capacitors C5 included in the cell IM[i,1] to the cell IM[i,n] in the i-th row of the cell array CA2. Thus, the potential of the node NN[i,j] of the cell IM[i,j] becomes V_{g}[i,j]+pΔV[i].

Similarly, when the potential of the wiring XCL[i] changes, the potential of the node NNref[i] included in the cell IMref[i] also changes because of the capacitive coupling of the capacitor C5m. Thus, the potential of the node NNref[i] of the cell IMref[i] becomes V_{gm}[i,j]+pΔV[i].

Accordingly, a current I₁[i,j] flowing between the first terminal and the second terminal of the transistor F2 and a current I_{ref1}[i,j] flowing between the first terminal and the second terminal of the transistor F2m in the period from Time T22 to Time T23 can be described as follows.

$$\begin{matrix}[ Formula 35 ] & \\ \begin{matrix}{I}_{1} [ i , j ] = {I}_{a} exp \{ K ( {V}_{g} [ i , j ] + p Δ V [ i ] - {V}_{th} [ i , j ] ) \} \\ = {I}_{0} [ i , j ] exp ( Kp Δ V [ i ] )\end{matrix} & ( F9 ) \\ [ Formula 36 ] & \\ \begin{matrix}{I}_{ref 1} [ i ] = {I}_{a} exp \{ K ( {V}_{gm} [ i ] + p Δ V [ i ] - {V}_{thm} [ i ] ) \} \\ = x [ i ] {I}_{ref 0}\end{matrix} & ( F10 )\end{matrix}$$

According to Formula (F9) and Formula (F10), x[i] can be expressed by the following formula.

[Formula 37]

x[i]=exp(KpΔV[i]) (F11)

Therefore, Formula (F9) can be rewritten into the following formula.

[Formula 38]

I₁[i,j]=x[i]w[i,j]I_{ref0} (F12)

That is, the current flowing between the first terminal and the second terminal of the transistor F2 included in the cell IM[i,j] is proportional to the product of the weight coefficient w[i,j] that is the first data and the value x[i] of a signal of a neuron that is the second data.

In the period from Time T22 to Time T23, a current of x[i+1]I_{ref0}, which is x[i+1] times as high as I_{ref0}, flows from the circuit XCS to the wiring XCL[i+1]. Note that in this operation example, x corresponds to the value of a signal of a neuron that is the second data. At this time, the potential of the wiring XCL[i+1] changes from 0 to V_{gm}[i+1]+ΔV[i+1].

When the potential of the wiring XCL [1+1] changes, the potentials of the node NN[i+1,1] to the node NN[i+1,n] also change because of the capacitive coupling of the capacitors C5 included in the cell IM[i+1,1] to the cell IM[i+1,n] in the i+1-th row of the cell array CA2. Thus, the potential of the node NN[i+1,j] of the cell IM[i+1,j] becomes V_{g}[i+1,j]+pΔV[i+1].

Similarly, when the potential of the wiring XCL[i+1] changes, the potential of the node NNref[i+1] included in the cell IMref[i+1] also changes because of the capacitive coupling of the capacitor C5m. Thus, the potential of the node NNref[i+1] of the cell IMref[i+1] becomes V_{gm}[i+1]+pΔV[i+1].

Accordingly, a current I₁[i+1,j] flowing between the first terminal and the second terminal of the transistor F2 and a current I_{ref1}[i+1,j] flowing between the first terminal and the second terminal of the transistor F2m in the period from Time T22 to Time T23 can be described as follows.

$$\begin{matrix} [ Formula 39 ] & \\ {I}_{1} [ i + 1 , j ] = {I}_{a} exp \{ K ( {V}_{g} [ i + 1 , j ] + p Δ V [ i + 1 ] - {V}_{th} [ i + 1 , j ] ) \} = {I}_{0} [ i + 1 , j ] exp ( Kp Δ V [ i + 1 ] ) & ( F13 ) \\ [ Formula 40 ] & \\ {I}_{ref 1} [ i + 1 ] = {I}_{a} exp \{ K ( {V}_{gm} [ i + 1 ] + p Δ V [ i + 1 ] - {V}_{thm} [ i + 1 ] ) \} = x [ i + 1 ] {I}_{ref 0} & ( F14 )\end{matrix}$$

According to Formula (F13) and Formula (F14), x[i+1] can be expressed by the following formula.

[Formula 41]

x[i+1]=exp(KpΔV[i+1]) (F15)

Therefore, Formula (F13) can be rewritten into the following formula.

[Formula 42]

I₁[i+1,j]=x[i+1]w[i+1,j]I_{ref0} (F16)

That is, the current flowing between the first terminal and the second terminal of the transistor F2 included in the cell IM[i+1,j] is proportional to the product of the weight coefficient w[i+1,j] that is the first data and the value x[i+1] of a signal of a neuron that is the second data.

Here, the sum of currents flowing from the converter circuit ITRZ[j] to the cell IM[i,j] and the cell IM[i+1,j] through the transistor F4[j] and the wiring WCL[j] is considered. According to Formula (F12) and Formula (F16), when the sum of the currents is Is[j], Is[j] can be expressed by the following formula.

$$\begin{matrix}[ Formula 43 ] & \\ \begin{matrix}{I}_{S} [ j ] = {I}_{1} [ i , j ] + {I}_{1} [ i + 1 , j ] \\ = {I}_{ref 0} ( x [ i ] w [ i , j ] + x [ i + 1 ] w [ i + 1 , j ] )\end{matrix} & ( F17 )\end{matrix}$$

Thus, a current output from the converter circuit ITRZ[j] is a current proportional to the sum of products of the weight coefficients w[i,j] and w[i+1,j] that are the first data and the values x[i] and x[i+1] of the signals of the neurons that are the second data.

Although in the above-described operation example, the sum of the currents flowing to the cell IM[i,j] and the cell IM[i+1,j] is described, the sum of currents flowing to a plurality of cells, i.e., the cell IM[i,j] to the cell IM[m,j] may be described. In this case, Formula (F17) can be rewritten into the following formula.

$$\begin{matrix}[ Formula 44 ] & \\ {I}_{S} [ j ] = {I}_{ref 0} {\sum }_{i = 1}^{m} x [ i ] w [ i , j ] & ( F18 )\end{matrix}$$

Thus, even in the case of the arithmetic circuit MAC2 including the cell array CA2 including three or more rows and two or more columns, product-sum operation can be performed in the above-described manner. In a product-sum operation circuit of such a case, memory cells in one of the plurality of columns are used for retaining I_{ref0} and xI_{ref0} as the amount of current, whereby product-sum operations, the number of which corresponds to the number of rest of the columns among the plurality of columns, can be executed concurrently. That is, when the number of columns in a memory cell array is increased, a semiconductor apparatus that achieves high-speed product-sum operation can be provided.

In the case where the product-sum operation circuit described in this embodiment is used as the above-described hidden layer, the weight coefficient w_{s[k]}_{ₛ}_{[k1-]}^{(k)} is used as the first data, the amount of current corresponding to the first data is stored in each of the cells IM in the same column sequentially, the output signal z_{s[k-1]}^{(k-1)} from the s[k−1]-th neuron in the (k−1)-th layer is used as the second data, and a current corresponding to the second data is made to flow from the circuit XCS to the wiring XCL in each row, so that the sum of products of the first data and the second data can be obtained from the current Is output from the circuit ITRZ. In addition, the value of the activation function is obtained using the value of the sum of products, so that the value of the activation function can be, as a signal, the output signal z_{s[k]}^{(k)} of the s[k]-th neuron in the k-th layer.

In the case where the product-sum operation circuit described in this embodiment is used as the above-described output layer, the weight coefficient w_{s[L]}_{ₛ}_{[L-1]}^{(L)} is used as the first data, the amount of current corresponding to the first data is stored in each of the cells IM in the same column sequentially, the output signal z_{s[L-1]}^{(L-1)} from the s[L−1]-th neuron in the (L−1)-th layer is used as the second data, and a current corresponding to the second data is made to flow from the circuit XCS to the wiring XCL in each row, so that the sum of products of the first data and the second data can be obtained from the current Is output from the circuit ITRZ. In addition, the value of the activation function is obtained using the value of the sum of products, so that the value of the activation function can be, as a signal, the output signal z_{s[L]}^{(L)} of the s[L]-th neuron in the L-th layer.

Note that the input layer described in this embodiment may function as a buffer circuit that outputs an input signal to the second layer.

Although this embodiment describes the case where the transistors included in the arithmetic circuit MAC1 and the arithmetic circuit MAC2 are OS transistors or Si transistors, one embodiment of the present invention is not limited thereto. As each of the transistors included in the arithmetic circuit MAC1 and the arithmetic circuit MAC2, it is possible to use, for example, a transistor containing a compound semiconductor such as Ge, ZnSe, CdS, GaAs, InP, GaN, or SiGe in an active layer; a transistor containing a carbon nanotube in an active layer; and a transistor containing an organic semiconductor in an active layer.

The structure examples described in this embodiment can be combined with each other as appropriate. This embodiment can be combined with any of the other embodiments and the like in this specification as appropriate.

### Embodiment 4

In this embodiment, structure examples of memory devices such as a main memory device and an auxiliary memory device which are included in an inspection device of one embodiment of the present invention will be described.

The memory device included in the inspection device of one embodiment of the present invention can have a structure including an OS transistor and a capacitive element. Since the OS transistor has an extremely low off-state current, the OS memory has excellent retention characteristics and thus can function as a nonvolatile memory.

### <Structure Example of Memory Device>

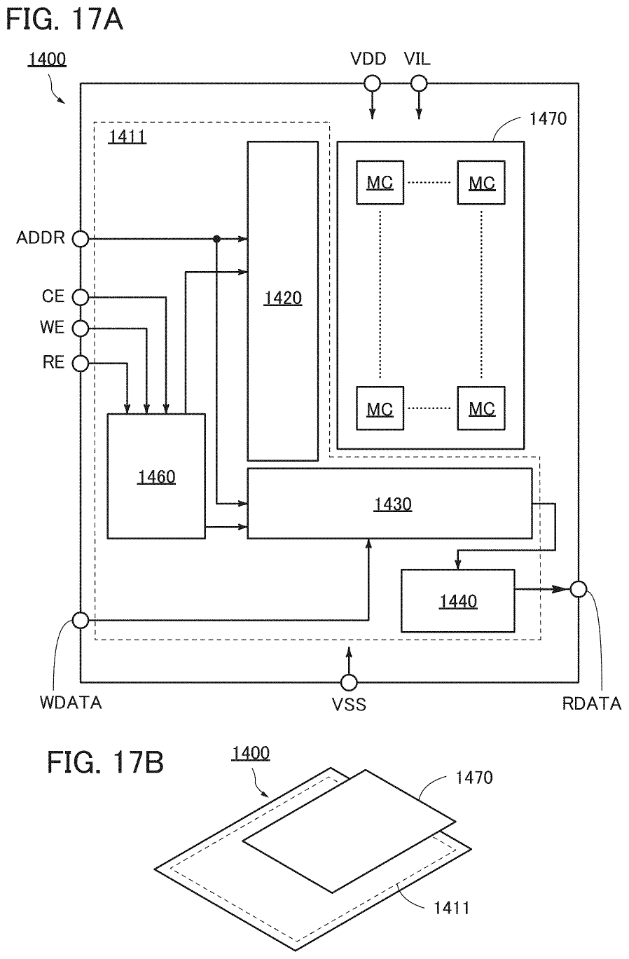

FIG. 17A shows a structure example of the OS memory. A memory device 1400 includes a peripheral circuit 1411 and a memory cell array 1470. The peripheral circuit 1411 includes a row circuit 1420, a column circuit 1430, an output circuit 1440, and a control logic circuit 1460.

The column circuit 1430 includes, for example, a column decoder, a precharge circuit, a sense amplifier, a write circuit, and the like. The precharge circuit has a function of precharging wirings. The sense amplifier has a function of amplifying a data signal read from a memory cell. Note that the wirings are connected to the memory cell included in the memory cell array 1470, and will be described later in detail. The amplified data signal is output as a data signal RDATA to the outside of the memory device 1400 through the output circuit 1440. The row circuit 1420 includes, for example, a row decoder and a word line driver circuit, and can select a row to be accessed.

As power supply voltages from the outside, a low power supply voltage (VSS), a high power supply voltage (VDD) for the peripheral circuit 1411, and a high power supply voltage (VIL) for the memory cell array 1470 are supplied to the memory device 1400. Control signals (CE, WE, and RE), an address signal ADDR, and a data signal WDATA are also input to the memory device 1400 from the outside. The address signal ADDR is input to the row decoder and the column decoder, and WDATA is input to the write circuit.

The control logic circuit 1460 processes the input signals (CE, WE, and RE) from the outside, and generates control signals for the row decoder and the column decoder. CE is a chip enable signal, WE is a write enable signal, and RE is a read enable signal. Signals processed by the control logic circuit 1460 are not limited thereto, and other control signals may be input as necessary.

The memory cell array 1470 includes a plurality of memory cells MC arranged in a matrix and a plurality of wirings. Note that the number of wirings that connect the memory cell array 1470 to the row circuit 1420 depends on the structure of the memory cell MC, the number of memory cells MC in a column, and the like. The number of wirings that connect the memory cell array 1470 to the column circuit 1430 depends on the structure of the memory cell MC, the number of memory cells MC in a row, and the like.

Note that FIG. 17A shows an example in which the peripheral circuit 1411 and the memory cell array 1470 are formed on the same plane; however, this embodiment is not limited thereto. For example, as illustrated in FIG. 17B, the memory cell array 1470 may be provided to overlap part of the peripheral circuit 1411. For example, the sense amplifier may be provided below the memory cell array 1470 so that they overlap with each other.

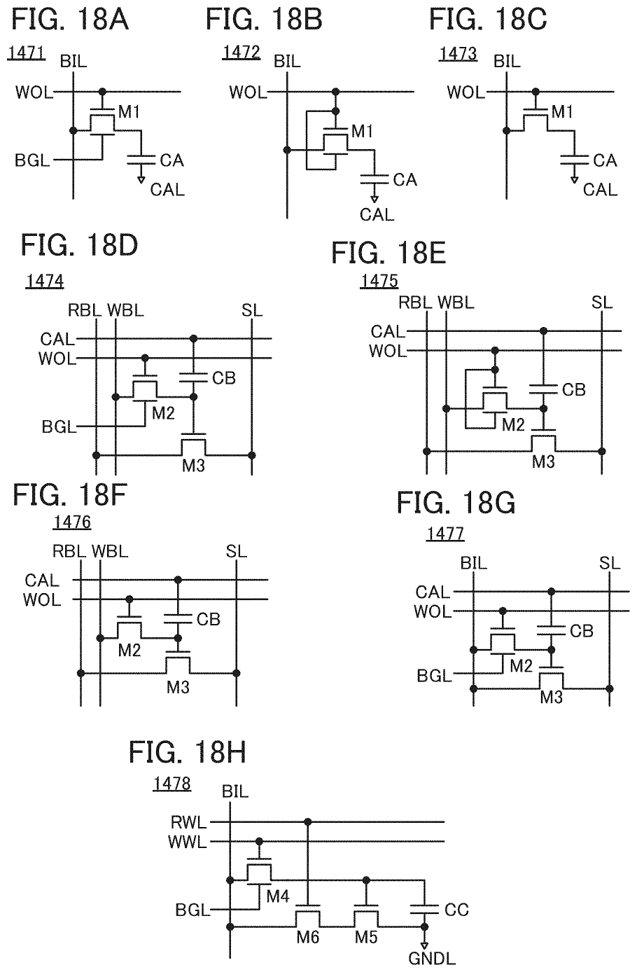

FIG. 18 shows structure examples of memory cells applicable to the above-described memory cell MC.

### <<DOSRAM>>

FIG. 18A to FIG. 18C show circuit structure examples of memory cells of a DRAM. In this specification and the like, a DRAM using a memory cell including one OS transistor and one capacitive element is referred to as DOSRAM in some cases. A memory cell 1471 illustrated in FIG. 18A includes a transistor M1 and a capacitive element CA. Note that the transistor M1 includes a gate (also referred to as a top gate in some cases) and a back gate.

A first terminal of the transistor M1 is connected to a first terminal of the capacitive element CA; a second terminal of the transistor M1 is connected to a wiring BIL; the gate of the transistor M1 is connected to a wiring WOL; and the back gate of the transistor M1 is connected to a wiring BGL. A second terminal of the capacitive element CA is connected to a wiring CAL.

The wiring BIL functions as a bit line, and the wiring WOL functions as a word line. The wiring CAL functions as a wiring for applying a predetermined potential to the second terminal of the capacitive element CA. In the time of data writing and data reading, a low-level potential is preferably applied to the wiring CAL. The wiring BGL functions as a wiring for applying a potential to the back gate of the transistor M1. By application of a given potential to the wiring BGL, the threshold voltage of the transistor M1 can be increased or decreased.

The memory cell MC is not limited to the memory cell 1471, and the circuit structure can be changed. For example, as in a memory cell 1472 illustrated in FIG. 18B, the back gate of the transistor M1 may be connected not to the wiring BGL but to the wiring WOL in the memory cell MC. Alternatively, for example, the memory cell MC may be a memory cell including a single-gate transistor, that is, the transistor M1 not including a back gate, as in a memory cell 1473 illustrated in FIG. 18C.

In the case where the semiconductor apparatus described in the above embodiment is used for the memory cell 1471 and the like, the transistor described in the following embodiment can be used as the transistor M1. When an OS transistor is used as the transistor M1, the leakage current of the transistor M1 can be extremely low. That is, with the use of the transistor M1, written data can be retained for a long time, and thus the frequency of the refresh operation for the memory cell can be decreased. In addition, refresh operation of the memory cell can be omitted. In addition, owing to an extremely low leakage current, multi-level data or analog data can be retained in the memory cell 1471, the memory cell 1472, and the memory cell 1473.

In the DOSRAM, when the sense amplifier is provided below the memory cell array 1470 so that they overlap with each other as described above, the bit line can be shortened. Thus, the bit line capacitance can be small, and the storage capacitance of the memory cell can be reduced.

### <<NOSRAM>>

FIG. 18D to FIG. 18G show circuit structure examples of gain-cell memory cells each including two transistors and one capacitive element. A memory cell 1474 illustrated in FIG. 18D includes the transistor M2, a transistor M3, and a capacitive element CB. Note that the transistor M2 includes a top gate (simply referred to as a gate in some cases) and a back gate. In this specification and the like, a memory device including a gain-cell memory cell using an OS transistor as the transistor M2 is referred to as NOSRAM in some cases.

A first terminal of the transistor M2 is connected to a first terminal of the capacitive element CB; a second terminal of the transistor M2 is connected to a wiring WBL; the gate of the transistor M2 is connected to the wiring WOL; and the back gate of the transistor M2 is connected to the wiring BGL. A second terminal of the capacitive element CB is connected to the wiring CAL. A first terminal of the transistor M3 is connected to a wiring RBL; a second terminal of the transistor M3 is connected to a wiring SL; and a gate of the transistor M3 is connected to the first terminal of the capacitive element CB.

The wiring WBL functions as a write bit line, the wiring RBL functions as a read bit line, and the wiring WOL functions as a word line. The wiring CAL functions as a wiring for applying a predetermined potential to the second terminal of the capacitive element CB. In the time of data writing, data retaining, and data reading, a low-level potential is preferably applied to the wiring CAL. The wiring BGL functions as a wiring for applying a potential to the back gate of the transistor M2. By application of a given potential to the wiring BGL, the threshold voltage of the transistor M2 can be increased or decreased.

The memory cell MC is not limited to the memory cell 1474, and the circuit structure can be changed as appropriate. For example, as in a memory cell 1475 illustrated in FIG. 18E, the back gate of the transistor M2 may be connected not to the wiring BGL but to the wiring WOL in the memory cell MC. Alternatively, for example, the memory cell MC may be a memory cell including a single-gate transistor, that is, the transistor M2 not including a back gate, as in a memory cell 1476 illustrated in FIG. 18F. Alternatively, for example, in the memory cell MC, the wiring WBL and the wiring RBL may be combined into one wiring BIL, as in a memory cell 1477 illustrated in FIG. 18G.

In the case where the semiconductor apparatus described in the above embodiment is used for the memory cell 1474 and the like, the transistor described in the following embodiment can be used as the transistor M2. When an OS transistor is used as the transistor M2, the leakage current of the transistor M2 can be extremely low. Accordingly, with the use of the transistor M2, written data can be retained for a long time, and thus the frequency of the refresh operation for the memory cell can be decreased. In addition, refresh operation of the memory cell can be omitted. In addition, owing to an extremely low leakage current, multi-level data or analog data can be retained in the memory cell 1474. The same applies to the memory cells 1475 to 1477.

Note that the transistor M3 may be a transistor containing silicon in a channel formation region (hereinafter, also referred to as a Si transistor in some cases). The conductivity type of the Si transistor may be of either an n-channel type or a p-channel type. The Si transistor has higher field-effect mobility than the OS transistor in some cases. Therefore, a Si transistor may be used as the transistor M3 functioning as a reading transistor. Furthermore, the transistor M2 can be provided to be stacked over the transistor M3 when a Si transistor is used as the transistor M3; therefore, the area occupied by the memory cell can be reduced, leading to high integration of the memory device.

Alternatively, the transistor M3 may be an OS transistor. When an OS transistor is used as each of the transistor M2 and the transistor M3, the circuit of the memory cell array 1470 can be formed using only n-channel transistors.

FIG. 18H shows an example of a gain-cell memory cell of one capacitive element for three transistors. A memory cell 1478 illustrated in FIG. 18H includes a transistor M4 to a transistor M6 and a capacitive element CC. The capacitive element CC is provided as appropriate. The memory cell 1478 is electrically connected to the wiring BIL, a wiring RWL, a wiring WWL, the wiring BGL, and a wiring GNDL. The wiring GNDL is a wiring for supplying a low-level potential. Note that the memory cell 1478 may be electrically connected to the wiring RBL and the wiring WBL instead of the wiring BIL.

The transistor M4 is an OS transistor including a back gate, and the back gate is electrically connected to the wiring BGL. Note that the back gate and a gate of the transistor M4 may be electrically connected to each other. Alternatively, the transistor M4 may include no back gate.

Note that each of the transistor M5 and the transistor M6 may be an n-channel Si transistor or a p-channel Si transistor. Alternatively, the transistor M4 to the transistor M6 may be OS transistors, in which case the circuit of the memory cell array 1470 can be formed using only re-channel transistors.

In the case where the semiconductor apparatus described in the above embodiment is used for the memory cell 1478, the transistor described in the following embodiment can be used as the transistor M4. When an OS transistor is used as the transistor M4, the leakage current of the transistor M4 can be extremely low.

Note that the structures of the peripheral circuit 1411, the memory cell array 1470, and the like described in this embodiment are not limited to the above. Positions and functions of these circuits, wirings connected to the circuits, circuit elements, and the like can be changed, deleted, or added as needed.

The structure examples described in this embodiment can be combined with each other as appropriate. This embodiment can be combined with any of the other embodiments and the like in this specification as appropriate.

### Embodiment 5

In this embodiment, a structure example of the arithmetic circuit described in the above embodiment and structure examples of transistors that can be used in the arithmetic circuit will be described.

### <Structure Example of Semiconductor Apparatus>

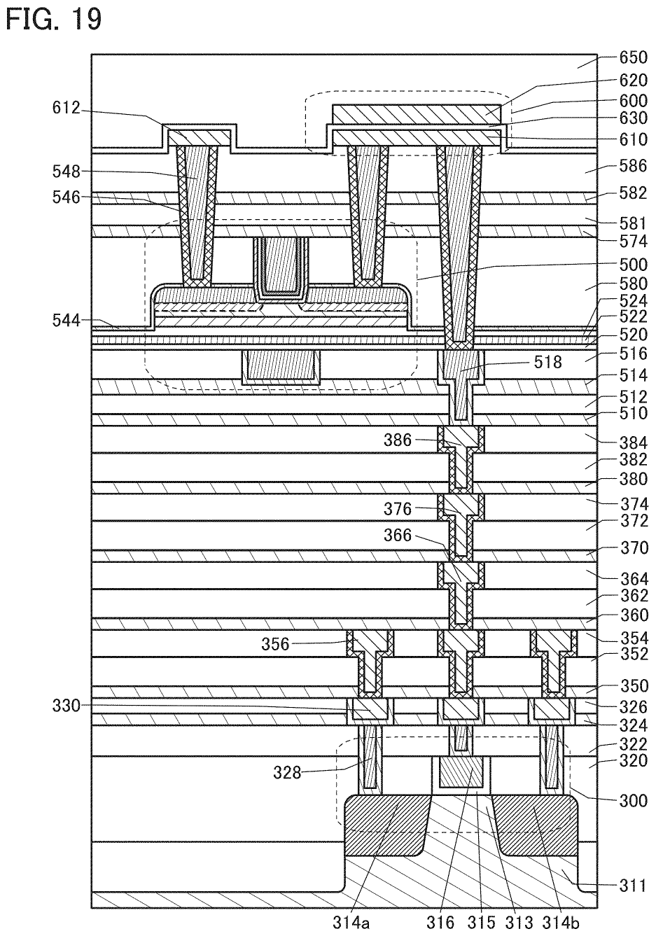

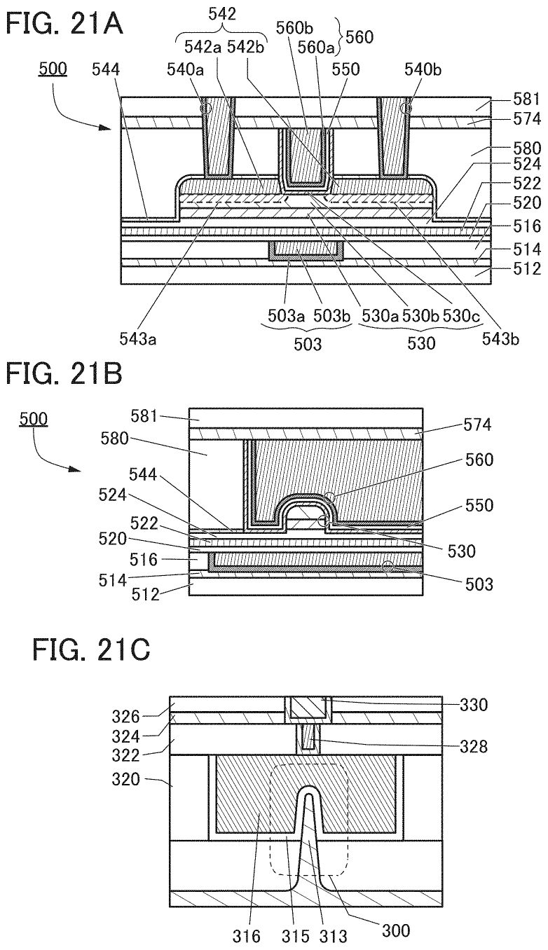

A semiconductor apparatus illustrated in FIG. 19 includes a transistor 300, a transistor 500, and a capacitive element 600. FIG. 21A is a cross-sectional view of the transistor 500 in the channel length direction, FIG. 21B is a cross-sectional view of the transistor 500 in the channel width direction, and FIG. 21C is a cross-sectional view of the transistor 300 in the channel width direction.

The transistor 500 is a transistor including a metal oxide in its channel formation region (an OS transistor). Since the off-state current of the transistor 500 is low, the use of the transistor 500 in a semiconductor apparatus, such as the transistor Tr11 of the memory cell array CA included in the arithmetic circuit MAC1 or the like, enables long-term retention of written data. In other words, the frequency of refresh operation is low or refresh operation is not required; thus, power consumption of the semiconductor apparatus can be reduced.

The semiconductor apparatus described in this embodiment includes the transistor 300, the transistor 500, and the capacitive element 600 as illustrated in FIG. 19. The transistor 500 is provided above the transistor 300, and the capacitive element 600 is provided above the transistor 300 and the transistor 500. Note that the capacitive element 600 can be the capacitor C1 of the memory cell array CA, the capacitor C2 of the circuit OFST, or the like included in the arithmetic circuit MAC1 or the like described in the above embodiment.

The transistor 300 is provided over a substrate 311. The transistor 300 includes a conductor 316 and an insulator 315. The transistor 300 includes a semiconductor region 313 that is part of the substrate 311, and a low-resistance region 314a and a low-resistance region 314b functioning as a source region and a drain region. Note that the transistor 300 can be used as the transistor Tr12 or the like of the memory cell array CA included in the arithmetic circuit MAC1 or the like described in the above embodiment, for example.

A semiconductor substrate (e.g., a single crystal substrate or a silicon substrate) is preferably used as the substrate 311.

As illustrated in FIG. 21C, in the transistor 300, the top surface and the side surface in the channel width direction of the semiconductor region 313 are covered with the conductor 316 with the insulator 315 therebetween. Such a Fin-type transistor 300 can have an increased effective channel width, and thus the transistor 300 can have improved on-state characteristics. In addition, contribution of an electric field of the gate electrode can be increased, so that the off-state characteristics of the transistor 300 can be improved.

Note that the transistor 300 can be a p-channel transistor or an n-channel transistor.

A region of the semiconductor region 313 where a channel is formed, a region in the vicinity thereof, the low-resistance region 314a and the low-resistance region 314b functioning as the source region and the drain region, and the like preferably contain a semiconductor such as a silicon-based semiconductor, further preferably contain single crystal silicon. Alternatively, the regions may be formed using a material containing Ge (germanium), SiGe (silicon germanium), GaAs (gallium arsenide), GaAlAs (gallium aluminum arsenide), or the like. Silicon whose effective mass is adjusted by applying stress to the crystal lattice and thereby changing the lattice spacing may be used. Alternatively, the transistor 300 may be an HEMT (High Electron Mobility Transistor) with the use of GaAs and GaAlAs, or the like.

The low-resistance region 314a and the low-resistance region 314b contain an element that imparts n-type conductivity, such as arsenic or phosphorus, or an element that imparts p-type conductivity, such as boron, in addition to a semiconductor material used for the semiconductor region 313.

For the conductor 316 functioning as a gate electrode, a semiconductor material such as silicon containing an element that imparts n-type conductivity, such as arsenic or phosphorus, or an element that imparts p-type conductivity, such as boron can be used. Moreover, a conductive material such as a metal material, an alloy material, or a metal oxide material can be used.

Note that the work function depends on the material of the conductor; therefore, the threshold voltage of the transistor can be adjusted by selecting the material of the conductor. Specifically, it is preferable to use a material such as titanium nitride or tantalum nitride for the conductor. Moreover, in order to ensure both conductivity and embeddability, it is preferable to use stacked layers of metal materials such as tungsten and aluminum for the conductor, and it is particularly preferable to use tungsten in terms of heat resistance.

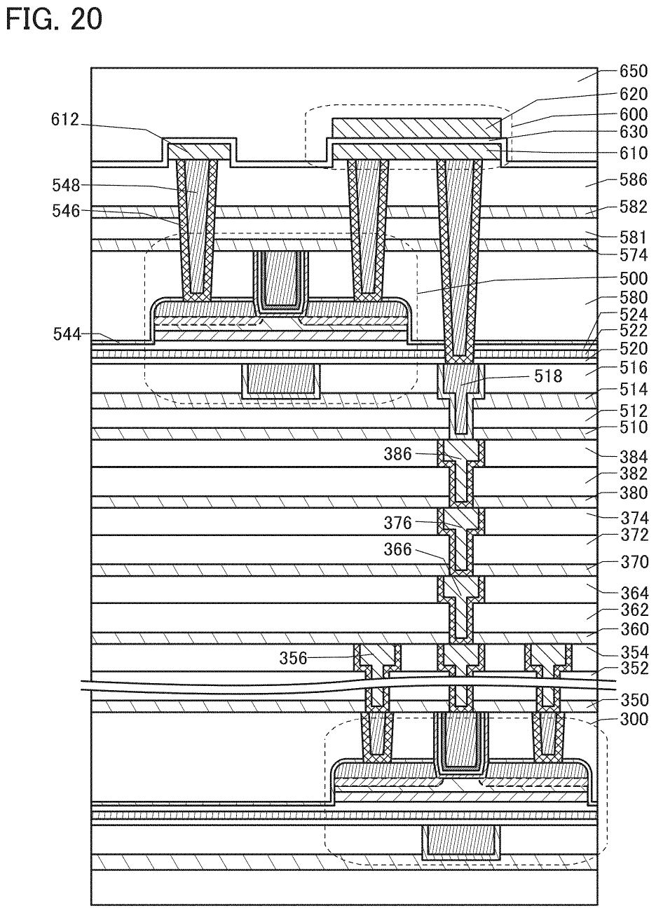

The structure of the transistor 300 illustrated in FIG. 19 is an example and the structure is not limited thereto; a transistor appropriate for a circuit structure or an operation method is used. For example, when a semiconductor apparatus is a single-polarity circuit using only OS transistors, the transistor 300 has a structure similar to the structure of the transistor 500 using an oxide semiconductor, as illustrated in FIG. 20. Note that the details of the transistor 500 will be described later.

An insulator 320, an insulator 322, an insulator 324, and an insulator 326 are stacked in this order to cover the transistor 300.

For the insulator 320, the insulator 322, the insulator 324, and the insulator 326, silicon oxide, silicon oxynitride, silicon nitride oxide, silicon nitride, aluminum oxide, aluminum oxynitride, aluminum nitride oxide, or aluminum nitride is used, for example.

Note that in this specification, silicon oxynitride refers to a material that has a higher oxygen content than a nitrogen content, and silicon nitride oxide refers to a material that has a higher nitrogen content than an oxygen content. Moreover, in this specification, aluminum oxynitride refers to a material that has a higher oxygen content than a nitrogen content, and aluminum nitride oxide refers to a material that has a higher nitrogen content than an oxygen content.

The insulator 322 may have a function of a smoothation film for eliminating a level difference caused by the transistor 300 or the like provided below the insulator 322. For example, the top surface of the insulator 322 may be smoothed by smoothing processing using a chemical mechanical polishing (CMP) method or the like to improve planarity.

As the insulator 324, it is preferable to use a film having a barrier property that prevents diffusion of hydrogen or impurities from the substrate 311, the transistor 300, or the like into a region where the transistor 500 is provided.

For the film having a barrier property against hydrogen, silicon nitride formed by a CVD method can be used, for example. The diffusion of hydrogen into a semiconductor element including an oxide semiconductor, such as the transistor 500, may result in degradation of the characteristics of the semiconductor element. Therefore, a film that inhibits hydrogen diffusion is preferably used between the transistor 500 and the transistor 300. The film that inhibits hydrogen diffusion is specifically a film from which a small amount of hydrogen is released.

The amount of released hydrogen can be measured by thermal desorption spectroscopy (TDS), for example. The amount of hydrogen released from the insulator 324 that is converted into hydrogen atoms per unit area of the insulator 324 is less than or equal to 10×10¹⁵ atoms/cm², preferably less than or equal to 5×10¹⁵ atoms/cm² in TDS analysis in a film-surface temperature range of 50° C. to 500° C., for example.

Note that the permittivity of the insulator 326 is preferably lower than that of the insulator 324. For example, the relative permittivity of the insulator 326 is preferably lower than 4, further preferably lower than 3. The relative permittivity of the insulator 326 is, for example, preferably 0.7 times or less, further preferably 0.6 times or less the relative permittivity of the insulator 324. The use of a material having a low relative permittivity for an interlayer film can reduce the parasitic capacitance generated between wirings.

A conductor 328, a conductor 330, and the like that are connected to the capacitive element 600 or the transistor 500 are embedded in the insulator 320, the insulator 322, the insulator 324, and the insulator 326. Note that the conductor 328 and the conductor 330 have a function of a plug or a wiring. A plurality of conductors having a function of a plug or a wiring are collectively denoted by the same reference numeral in some cases. Furthermore, in this specification and the like, a wiring and a plug connected to the wiring may be a single component. That is, in some cases, part of a conductor functions as a wiring or part of a conductor functions as a plug.

As a material of each of plugs and wirings (e.g., the conductor 328 and the conductor 330), a single layer or a stacked layer of a conductive material such as a metal material, an alloy material, a metal nitride material, or a metal oxide material can be used. It is preferable to use a high-melting-point material that has both heat resistance and conductivity, such as tungsten or molybdenum, and it is particularly preferable to use tungsten. Alternatively, a low-resistance conductive material such as aluminum or copper is preferably used. The use of a low-resistance conductive material can reduce wiring resistance.

A wiring layer may be provided over the insulator 326 and over the conductor 330. For example, in FIG. 19, an insulator 350, an insulator 352, and an insulator 354 are provided to be stacked in this order. Furthermore, a conductor 356 is embedded in the insulator 350, the insulator 352, and the insulator 354. The conductor 356 has a function of a plug or a wiring that is connected to the transistor 300. Note that the conductor 356 can be provided using a material similar to those for the conductor 328 and the conductor 330.

As the insulator 350, it is preferable to use, for example, an insulator having a barrier property against hydrogen, like the insulator 324. Furthermore, the conductor 356 preferably includes a conductor having a barrier property against hydrogen. It is particularly preferable to employ a structure in which the conductor having a barrier property against hydrogen is formed in an opening portion of the insulator 350 having a barrier property against hydrogen. With this structure, the transistor 300 and the transistor 500 can be separated by the barrier layer, so that the diffusion of hydrogen from the transistor 300 into the transistor 500 can be inhibited.

Note that as the conductor having a barrier property against hydrogen, tantalum nitride is used, for example. Stacking tantalum nitride and tungsten having high conductivity can inhibit the diffusion of hydrogen from the transistor 300 while the conductivity of a wiring is ensured. In this case, a tantalum nitride layer having a barrier property against hydrogen is preferably in contact with the insulator 350 having a barrier property against hydrogen.

A wiring layer may be provided over the insulator 354 and over the conductor 356. For example, in FIG. 19, an insulator 360, an insulator 362, and an insulator 364 are provided to be stacked in this order. Moreover, a conductor 366 is embedded in the insulator 360, the insulator 362, and the insulator 364. The conductor 366 has a function of a plug or a wiring. Note that the conductor 366 can be provided using a material similar to those for the conductor 328 and the conductor 330.

As the insulator 360, it is preferable to use, for example, an insulator having a barrier property against hydrogen, like the insulator 324. Furthermore, the conductor 366 preferably includes a conductor having a barrier property against hydrogen. It is particularly preferable to employ a structure in which the conductor having a barrier property against hydrogen is formed in an opening portion of the insulator 360 having a barrier property against hydrogen. With this structure, the transistor 300 and the transistor 500 can be separated by the barrier layer, so that the diffusion of hydrogen from the transistor 300 into the transistor 500 can be inhibited.

A wiring layer may be provided over the insulator 364 and over the conductor 366. For example, in FIG. 19, an insulator 370, an insulator 372, and an insulator 374 are provided to be stacked in this order. Furthermore, a conductor 376 is embedded in the insulator 370, the insulator 372, and the insulator 374. The conductor 376 has a function of a plug or a wiring. Note that the conductor 376 can be provided using a material similar to those for the conductor 328 and the conductor 330.

As the insulator 370, it is preferable to use, for example, an insulator having a barrier property against hydrogen, like the insulator 324. Furthermore, the conductor 376 preferably includes a conductor having a barrier property against hydrogen. It is particularly preferable to employ a structure in which the conductor having a barrier property against hydrogen is formed in an opening portion of the insulator 370 having a barrier property against hydrogen. With this structure, the transistor 300 and the transistor 500 can be separated by the barrier layer, so that the diffusion of hydrogen from the transistor 300 into the transistor 500 can be inhibited.

A wiring layer may be provided over the insulator 374 and over the conductor 376. For example, in FIG. 19, an insulator 380, an insulator 382, and an insulator 384 are provided to be stacked in this order. Moreover, a conductor 386 is embedded in the insulator 380, the insulator 382, and the insulator 384. The conductor 386 has a function of a plug or a wiring. Note that the conductor 386 can be provided using a material similar to those for the conductor 328 and the conductor 330.

As the insulator 380, it is preferable to use, for example, an insulator having a barrier property against hydrogen, like the insulator 324. Furthermore, the conductor 386 preferably includes a conductor having a barrier property against hydrogen. It is particularly preferable to employ a structure in which the conductor having a barrier property against hydrogen is formed in an opening portion of the insulator 380 having a barrier property against hydrogen. With this structure, the transistor 300 and the transistor 500 can be separated by the barrier layer, so that the diffusion of hydrogen from the transistor 300 into the transistor 500 can be inhibited.

The conductor 366, the conductor 376, and the conductor 386 can each have a structure similar to that of the conductor 356.

Although the semiconductor apparatus of one embodiment of the present invention includes the wiring layer including the conductor 356, the wiring layer including the conductor 366, the wiring layer including the conductor 376, and the wiring layer including the conductor 386 in the above, the semiconductor apparatus of one embodiment of the present invention is not limited thereto. The number of wiring layers similar to the wiring layer including the conductor 356 may be three or less, or the number of wiring layers similar to the wiring layer including the conductor 356 may be five or more.

An insulator 510, an insulator 512, an insulator 514, and an insulator 516 are stacked in this order over the insulator 384. A material with a barrier property against oxygen or hydrogen is preferably used for any of the insulator 510, the insulator 512, the insulator 514, and the insulator 516.

For example, as the insulator 510 and the insulator 514, it is preferable to use a film having a barrier property that prevents diffusion of hydrogen or impurities from the substrate 311, a region where the transistor 300 is provided, or the like into the region where the transistor 500 is provided. Therefore, a material similar to that for the insulator 324 can be used.

For the film having a barrier property against hydrogen, silicon nitride formed by a CVD method can be used, for example. The diffusion of hydrogen into a semiconductor element including an oxide semiconductor, such as the transistor 500, may result in degradation of the characteristics of the semiconductor element. Therefore, a film that inhibits hydrogen diffusion is preferably used between the transistor 500 and the transistor 300. The film that inhibits hydrogen diffusion is specifically a film from which a small amount of hydrogen is released.

For the film having a barrier property against hydrogen used for the insulator 510 and the insulator 514, a metal oxide such as aluminum oxide, hafnium oxide, or tantalum oxide is preferably used, for example.

In particular, aluminum oxide has an excellent blocking effect that prevents transmission of oxygen and impurities such as hydrogen and moisture which would cause a change in the electrical characteristics of the transistor. Accordingly, the use of aluminum oxide can prevent entry of impurities such as hydrogen and moisture into the transistor 500 in and after the manufacturing process of the transistor. In addition, release of oxygen from the oxide included in the transistor 500 can be inhibited. Therefore, aluminum oxide is suitably used for a protective film of the transistor 500.

For the insulator 512 and the insulator 516, a material similar to that for the insulator 320 can be used, for example. The use of a material with a relatively low permittivity for these insulators can reduce the parasitic capacitance generated between wirings. A silicon oxide film or a silicon oxynitride film can be used for the insulator 512 and the insulator 516, for example.

A conductor 518, a conductor included in the transistor 500 (e.g., a conductor 503), and the like are embedded in the insulator 510, the insulator 512, the insulator 514, and the insulator 516. Note that the conductor 518 has a function of a plug or a wiring that is connected to the capacitive element 600 or the transistor 300. The conductor 518 can be provided using a material similar to those for the conductor 328 and the conductor 330.

In particular, the conductor 518 in a region in contact with the insulator 510 and the insulator 514 is preferably a conductor having a barrier property against oxygen, hydrogen, and water. With this structure, the transistor 300 and the transistor 500 can be separated by the layer having a barrier property against oxygen, hydrogen, and water; hence, the diffusion of hydrogen from the transistor 300 into the transistor 500 can be inhibited.

The transistor 500 is provided over the insulator 516.

As illustrated in FIG. 21A and FIG. 21B, the transistor 500 includes the conductor 503 placed to be embedded in the insulator 514 and the insulator 516, an insulator 520 placed over the insulator 516 and the conductor 503, an insulator 522 placed over the insulator 520, an insulator 524 placed over the insulator 522, an oxide 530a placed over the insulator 524, an oxide 530b placed over the oxide 530a, a conductor 542a and a conductor 542b placed apart from each other over the oxide 530b, an insulator 580 that is placed over the conductor 542a and the conductor 542b and is provided with an opening formed to overlap with a region between the conductor 542a and the conductor 542b, an oxide 530c placed to have a region in contact with a bottom surface and a side surface of the opening, an insulator 550 placed on the formation surface of the oxide 530c, and a conductor 560 placed on the formation surface of the insulator 550.

As illustrated in FIG. 21A and FIG. 21B, an insulator 544 is preferably placed between the insulator 580 and the oxide 530a, the oxide 530b, the conductor 542a, and the conductor 542b. As illustrated in FIG. 21A and FIG. 21B, the conductor 560 preferably includes a conductor 560a provided inside the insulator 550 and a conductor 560b provided to be embedded inside the conductor 560a. As illustrated in FIG. 21A and FIG. 21B, an insulator 574 is preferably placed over the insulator 580, the conductor 560, and the insulator 550.

Hereinafter, the oxide 530a, the oxide 530b, and the oxide 530c may be collectively referred to as an oxide 530.

The transistor 500 has a structure in which the three layers of the oxide 530a, the oxide 530b, and the oxide 530c are stacked in the region where the channel is formed and its vicinity; however, one embodiment of the present invention is not limited to this. For example, the transistor may have a single-layer structure of the oxide 530b, a two-layer structure of the oxide 530b and the oxide 530a, a two-layer structure of the oxide 530b and the oxide 530c, or a stacked-layer structure of four or more layers. Although the conductor 560 is shown to have a two-layer structure in the transistor 500, one embodiment of the present invention is not limited to this. For example, the conductor 560 may have a single-layer structure or a stacked-layer structure of three or more layers. Moreover, the structures of the transistor 500 illustrated in FIG. 19, FIG. 20, FIG. 21A, and FIG. 21B are examples and the structure is not limited thereto; an appropriate transistor is used in accordance with a circuit structure or an operation method.

Here, the conductor 560 functions as a gate electrode of the transistor, and the conductor 542a and the conductor 542b function as a source electrode and a drain electrode. As described above, the conductor 560 is formed to be embedded in an opening of the insulator 580 and the region sandwiched between the conductor 542a and the conductor 542b. The positions of the conductor 560, the conductor 542a, and the conductor 542b are selected in a self-aligned manner with respect to the opening in the insulator 580. That is, in the transistor 500, the gate electrode can be placed between the source electrode and the drain electrode in a self-aligned manner. Thus, the conductor 560 can be formed without an alignment margin, resulting in a reduction in the area occupied by the transistor 500. Accordingly, miniaturization and high integration of the semiconductor apparatus can be achieved.

Since the conductor 560 is formed in the region between the conductor 542a and the conductor 542b in a self-aligned manner, the conductor 560 does not have a region overlapping with the conductor 542a or the conductor 542b. Thus, parasitic capacitance formed between the conductor 560 and each of the conductor 542a and the conductor 542b can be reduced. As a result, the transistor 500 can have increased switching speed and excellent frequency characteristics.

The conductor 560 functions as a first gate (also referred to as top gate) electrode in some cases. The conductor 503 functions as a second gate (also referred to as bottom gate) electrode in some cases. In that case, the threshold voltage of the transistor 500 can be controlled by changing a potential applied to the conductor 503 independently of a potential applied to the conductor 560. In particular, when a negative potential is applied to the conductor 503, the threshold voltage of the transistor 500 can be higher than 0 V, and the off-state current can be reduced. Thus, a drain current at the time when a potential applied to the conductor 560 is 0 V can be smaller in the case where a negative potential is applied to the conductor 503 than in the case where a negative potential is not applied to the conductor 503.

The conductor 503 is placed to overlap with the oxide 530 and the conductor 560. Thus, when potentials are applied to the conductor 560 and the conductor 503, an electric field generated from the conductor 560 and an electric field generated from the conductor 503 are connected and can cover the channel formation region formed in the oxide 530. In this specification and the like, a transistor structure in which a channel formation region is electrically surrounded by electric fields of a first gate electrode and a second gate electrode is referred to as a surrounded channel (s-channel) structure.

The conductor 503 has a structure similar to that of the conductor 518; a conductor 503a is formed in contact with an inner wall of the opening in the insulator 514 and the insulator 516, and a conductor 503b is formed further inside. Although the transistor 500 in which the conductor 503a and the conductor 503b are stacked is illustrated, one embodiment of the present invention is not limited thereto. For example, the conductor 503 may be provided as a single layer or to have a stacked-layer structure of three or more layers.

Here, for the conductor 503a, a conductive material that has a function of inhibiting diffusion of impurities such as a hydrogen atom, a hydrogen molecule, a water molecule, and a copper atom (through which the impurities are less likely to pass) is preferably used. Alternatively, it is preferable to use a conductive material that has a function of inhibiting diffusion of oxygen (e.g., at least one of an oxygen atom, an oxygen molecule, and the like) (through which oxygen is less likely to pass). Note that in this specification, a function of inhibiting diffusion of impurities or oxygen means a function of inhibiting diffusion of any one or all of the above impurities and the above oxygen.

For example, when the conductor 503a has a function of inhibiting diffusion of oxygen, a reduction in conductivity of the conductor 503b due to oxidation can be inhibited.

When the conductor 503 also functions as a wiring, for the conductor 503b, it is preferable to use a conductive material that has high conductivity and contains tungsten, copper, or aluminum as its main component. In that case, the conductor 503a is not necessarily provided. Note that the conductor 503b is illustrated as a single layer but may have a stacked-layer structure, for example, a stack of any of the above conductive materials and titanium or titanium nitride.

The insulator 520, the insulator 522, and the insulator 524 have a function of a gate insulating film for the conductor 503.

Here, as the insulator 524 in contact with the oxide 530, an insulator containing more oxygen than oxygen in the stoichiometric composition is preferably used. That is, an excess-oxygen region is preferably formed in the insulator 524. When such an insulator containing excess oxygen is provided in contact with the oxide 530, oxygen vacancies in the oxide 530 can be reduced, and the reliability of the transistor 500 can be improved.

As the insulator including an excess-oxygen region, specifically, an oxide material that releases part of oxygen by heating is preferably used. An oxide that releases oxygen by heating is an oxide film in which the amount of released oxygen converted into oxygen atoms is greater than or equal to 1.0×10¹⁸ atoms/cm³, preferably greater than or equal to 1.0×10¹⁹ atoms/cm³, further preferably greater than or equal to 2.0×10¹⁹ atoms/cm³ or greater than or equal to 3.0×10²⁰ atoms/cm³ in TDS (Thermal Desorption Spectroscopy) analysis. Note that the temperature of the film surface in the TDS analysis is preferably in the range of 100° C. to 700° C. or 100° C. to 400° C.

One or more of heat treatment, microwave treatment, and RF treatment may be performed in a state where the insulator including the excess-oxygen region and the oxide 530 are in contact with each other. By the treatment, water or hydrogen in the oxide 530 can be removed. For example, in the oxide 530, dehydrogenation can be performed when a reaction in which a bond of VoH is cut occurs, i.e., a reaction of “VoH→Vo+H” occurs. Part of hydrogen generated at this time is bonded to oxygen to be H₂O, and removed from the oxide 530 or an insulator in the vicinity of the oxide 530 in some cases. Part of hydrogen is diffused into or gettered (also referred to as gettering) by the conductor 542a or the conductor 542b in some cases.

For the microwave treatment, for example, an apparatus including a power supply that generates high-density plasma or an apparatus including a power supply that applies RF to the substrate side is suitably used. For example, the use of an oxygen-containing gas and high-density plasma enables high-density oxygen radicals to be generated. Application of the RF to the substrate side allows the oxygen radicals generated by the high-density plasma to be efficiently introduced into the oxide 530 or an insulator in the vicinity of the oxide 530. The pressure in the microwave treatment is higher than or equal to 133 Pa, preferably higher than or equal to 200 Pa, further preferably higher than or equal to 400 Pa. As a gas introduced into an apparatus for performing the microwave treatment, for example, oxygen and argon are used and the oxygen flow rate (O₂/(O₂+Ar)) is lower than or equal to 50%, preferably higher than or equal to 10% and lower than or equal to 30%.

In a manufacturing process of the transistor 500, the heat treatment is preferably performed with the surface of the oxide 530 exposed. The heat treatment is performed at higher than or equal to 100° C. and lower than or equal to 450° C., preferably higher than or equal to 350° C. and lower than or equal to 400° C. Note that the heat treatment is performed in a nitrogen gas or inert gas atmosphere, or an atmosphere containing an oxidizing gas at 10 ppm or more, 1% or more, or 10% or more. For example, the heat treatment is preferably performed in an oxygen atmosphere. Accordingly, oxygen can be supplied to the oxide 530 to reduce oxygen vacancies (Vo). Alternatively, the heat treatment may be performed under reduced pressure. Alternatively, the heat treatment may be performed in such a manner that heat treatment is performed in a nitrogen gas or inert gas atmosphere, and then another heat treatment is performed in an atmosphere containing an oxidizing gas at 10 ppm or more, 1% or more, or 10% or more in order to compensate for released oxygen. Alternatively, the heat treatment may be performed in such a manner that heat treatment is performed in an atmosphere containing an oxidizing gas at 10 ppm or more, 1% or more, or 10% or more, and then another heat treatment is performed in a nitrogen gas or inert gas atmosphere.

Note that the oxygen adding treatment performed on the oxide 530 can promote a reaction in which oxygen vacancies in the oxide 530 are filled with supplied oxygen, i.e., a reaction of “Vo+O→null”. Furthermore, hydrogen remaining in the oxide 530 reacts with supplied oxygen, so that the hydrogen can be removed as H₂O (dehydration). This can inhibit recombination of hydrogen remaining in the oxide 530 with oxygen vacancies and formation of VoH.

When the insulator 524 includes an excess-oxygen region, it is preferable that the insulator 522 have a function of inhibiting diffusion of oxygen (e.g., an oxygen atom and an oxygen molecule) (or that the insulator 522 be less likely to transmit the above oxygen).

The insulator 522 preferably has a function of inhibiting diffusion of oxygen or impurities, in which case diffusion of oxygen contained in the oxide 530 to the insulator 520 side is prevented. Furthermore, the conductor 503 can be prevented from reacting with oxygen in the insulator 524 or the oxide 530, which is preferable.

The insulator 522 is preferably a single layer or stacked layers using an insulator containing what is called a high-k material (high dielectric constant material) such as aluminum oxide, hafnium oxide, an oxide containing aluminum and hafnium (hafnium aluminate), tantalum oxide, zirconium oxide, lead zirconate titanate (PZT), strontium titanate (SrTiO₃), or (Ba,Sr)TiO₃ (BST). As miniaturization and high integration of transistors progress, a problem such as leakage current may arise because of a thinner gate insulating film. When a high-k material is used for an insulator functioning as the gate insulating film, a gate potential at the time when the transistor operates can be lowered while the physical thickness of the gate insulating film is maintained.

It is particularly preferable to use an insulator containing an oxide of one or both of aluminum and hafnium, which is an insulating material having a function of inhibiting diffusion of impurities, oxygen, and the like (i.e., an insulating material through which the above oxygen is less likely to pass). As the insulator containing an oxide of one or both of aluminum and hafnium, aluminum oxide, hafnium oxide, an oxide containing aluminum and hafnium (hafnium aluminate), or the like is preferably used. In the case where the insulator 522 is formed using such a material, the insulator 522 functions as a layer that inhibits release of oxygen from the oxide 530 and entry of impurities such as hydrogen from the periphery of the transistor 500 into the oxide 530.

Alternatively, aluminum oxide, bismuth oxide, germanium oxide, niobium oxide, silicon oxide, titanium oxide, tungsten oxide, yttrium oxide, or zirconium oxide may be added to these insulators, for example. Alternatively, these insulators may be subjected to nitriding treatment. Silicon oxide, silicon oxynitride, or silicon nitride may be stacked over the above insulator.

It is preferable that the insulator 520 be thermally stable. For example, silicon oxide and silicon oxynitride, which have thermal stability, are suitable. Furthermore, when an insulator that is a high-k material is combined with silicon oxide or silicon oxynitride, the insulator 520 having a stacked-layer structure that has thermal stability and a high relative permittivity can be obtained.

Note that in the transistor 500 in FIG. 21A and FIG. 21B, the insulator 520, the insulator 522, and the insulator 524 are illustrated as the gate insulating film having a three-layer structure for the conductor 503; however, the gate insulating film may have a single-layer structure, a two-layer structure, or a stacked-layer structure of four or more layers. In such cases, without limitation to a stacked-layer structure formed of the same material, a stacked-layer structure formed of different materials may be employed.

In the transistor 500, a metal oxide functioning as an oxide semiconductor is preferably used as the oxide 530 including a channel formation region. For example, as the oxide 530, a metal oxide such as an In-M-Zn oxide (the element M is one or more selected from aluminum, gallium, yttrium, copper, vanadium, beryllium, boron, titanium, iron, nickel, germanium, zirconium, molybdenum, lanthanum, cerium, neodymium, hafnium, tantalum, tungsten, magnesium, and the like) is used. In particular, the In-M-Zn oxide which can be used as the oxide 530 is preferably a CAAC-OS (C-Axis Aligned Crystalline Oxide Semiconductor) or a CAC-OS (Cloud-Aligned Composite Oxide Semiconductor). Alternatively, an In—Ga oxide, an In—Zn oxide, an In oxide, or the like may be used as the oxide 530.

Furthermore, a metal oxide with a low carrier concentration is preferably used for the transistor 500. In order to reduce the carrier concentration of the metal oxide, the concentration of impurities in the metal oxide is reduced so that the density of defect states is reduced. In this specification and the like, a state with a low impurity concentration and a low density of defect states is referred to as a highly purified intrinsic or substantially highly purified intrinsic state. As examples of the impurities in the metal oxide, hydrogen, nitrogen, alkali metal, alkaline earth metal, iron, nickel, silicon, and the like are given.

In particular, hydrogen contained in a metal oxide reacts with oxygen bonded to a metal atom to be water, and thus forms an oxygen vacancy in the metal oxide in some cases. In the case where hydrogen enters an oxygen vacancy in the oxide 530, the oxygen vacancy and the hydrogen are bonded to each other to form VoH in some cases. The VoH serves as a donor and an electron that is a carrier is generated in some cases. In other cases, bonding of part of hydrogen to oxygen bonded to a metal atom generates electrons serving as carriers. Thus, a transistor using a metal oxide containing much hydrogen is likely to have normally-on characteristics. Moreover, hydrogen in a metal oxide easily moves by stress such as heat and an electric field; thus, the reliability of a transistor may be low when the metal oxide contains a plenty of hydrogen. In one embodiment of the present invention, VoH in the oxide 530 is preferably reduced as much as possible so that the oxide 530 becomes a highly purified intrinsic or substantially highly purified intrinsic oxide. It is important to remove impurities such as moisture and hydrogen in a metal oxide (sometimes described as dehydration or dehydrogenation treatment) and to compensate for oxygen vacancies by supplying oxygen to the metal oxide (sometimes described as oxygen supplying treatment) to obtain a metal oxide whose VoH is reduced enough. When a metal oxide in which impurities such as VoH are sufficiently reduced is used for a channel formation region of a transistor, stable electrical characteristics can be given.

A defect in which hydrogen has entered an oxygen vacancy can function as a donor of the metal oxide. However, it is difficult to evaluate the defects quantitatively. Thus, the metal oxide is sometimes evaluated by not its donor concentration but its carrier concentration. Therefore, in this specification and the like, the carrier concentration assuming the state where an electric field is not applied is sometimes used, instead of the donor concentration, as the parameter of the metal oxide. That is, “carrier concentration” in this specification and the like can be replaced with “donor concentration” in some cases.

Therefore, when a metal oxide is used as the oxide 530, hydrogen in the metal oxide is preferably reduced as much as possible. Specifically, the hydrogen concentration of the metal oxide, which is obtained by secondary ion mass spectrometry (SIMS), is lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³. When a metal oxide with sufficiently reduced concentration of impurities such as hydrogen is used for a channel formation region of a transistor, stable electrical characteristics can be given.

In the case where a metal oxide is used as the oxide 530, the metal oxide is an intrinsic (also referred to as I-type) or substantially intrinsic semiconductor that has a large band gap, and the carrier concentration of the metal oxide in the channel formation region is preferably lower than 1×10¹⁸ cm⁻³, further preferably lower than 1×10¹⁷ cm⁻³, still further preferably lower than 1×10¹⁶ cm³, yet further preferably lower than 1×10¹³ cm⁻³, yet still further preferably lower than 1×10¹² cm³. Note that the lower limit of the carrier concentration of the metal oxide in the channel formation region is not particularly limited and can be, for example, 1×10⁻⁹ cm³.

When a metal oxide is used as the oxide 530, contact between the oxide 530 and each of the conductor 542a and the conductor 542b may diffuse oxygen in the oxide 530 into the conductor 542a and the conductor 542b, resulting in oxidation of the conductor 542a and the conductor 542b. It is highly possible that oxidation of the conductor 542a and the conductor 542b lowers the conductivity of the conductor 542a and the conductor 542b. Note that diffusion of oxygen from the oxide 530 into the conductor 542a and the conductor 542b can be interpreted as absorption of oxygen in the oxide 530 by the conductor 542a and the conductor 542b.

When oxygen in the oxide 530 is diffused into the conductor 542a and the conductor 542b, a layer is sometimes formed between the conductor 542a and the oxide 530b and between the conductor 542b and the oxide 530b. Since the layer contains a larger amount of oxygen than the conductor 542a and the conductor 542b, the layer seems to have an insulating property. In this case, a three-layer structure of the conductor 542a or the conductor 542b, the layer, and the oxide 530b can be regarded as a three-layer structure of a metal, an insulator, and a semiconductor and is sometimes referred to as a MIS (Metal-Insulator-Semiconductor) structure or referred to as a diode-connected structure mainly formed of the MIS structure.

The above layer is not necessarily formed between the oxide 530b and each of the conductor 542a and the conductor 542b; for example, the layer may be formed between the oxide 530c and each of the conductor 542a and the conductor 542b, or between the oxide 530b and each of the conductor 542a and the conductor 542b and between the oxide 530c and each of the conductor 542a and the conductor 542b.

The metal oxide functioning as the channel formation region in the oxide 530 has a band gap of preferably 2 eV or higher, further preferably 2.5 eV or higher. The use of a metal oxide having a wide band gap can reduce the off-state current of the transistor.

By including the oxide 530a under the oxide 530b, the oxide 530 can inhibit diffusion of impurities into the oxide 530b from the components formed below the oxide 530a. Moreover, including the oxide 530c over the oxide 530b makes it possible to inhibit diffusion of impurities into the oxide 530b from the components formed above the oxide 530c.

The oxide 530 preferably has a stacked-layer structure of a plurality of oxide layers that differ in the atomic ratio of metal atoms. Specifically, the atomic proportion of the element M to the constituent elements in the metal oxide used as the oxide 530a is preferably greater than the atomic proportion of the element M to the constituent elements in the metal oxide used as the oxide 530b. The atomic proportion of the element M to In in the metal oxide used as the oxide 530a is preferably greater than the atomic proportion of the element M to In in the metal oxide used as the oxide 530b. The atomic proportion of In to the element M in the metal oxide used as the oxide 530b is preferably greater than the atomic proportion of In to the element M in the metal oxide used as the oxide 530a. As the oxide 530c, a metal oxide that can be used as the oxide 530a or the oxide 530b can be used.

Specifically, as the oxide 530a, a metal oxide in which an atomic ratio of In to Ga and Zn is In:Ga:Zn=1:3:4 or 1:1:0.5 is used. As the oxide 530b, a metal oxide in which an atomic ratio of In to Ga and Zn is In:Ga:Zn=4:2:3 or 1:1:1 is used. As the oxide 530c, a metal oxide in which an atomic ratio of In to Ga and Zn is In:Ga:Zn=1:3:4 or an atomic ratio of Ga to Zn is Ga:Zn=2:1 or Ga:Zn=2:5 is used. Specific examples of the oxide 530c having a stacked-layer structure include a stacked-layer structure of a layer in which an atomic ratio of In to Ga and Zn is In:Ga:Zn=4:2:3 and a layer in which an atomic ratio of In to Ga and Zn is In:Ga:Zn=1:3:4, a stacked-layer structure of a layer in which an atomic ratio of Ga to Zn is Ga:Zn=2:1 and a layer in which an atomic ratio of In to Ga and Zn is In:Ga:Zn=4:2:3, a stacked-layer structure of a layer in which an atomic ratio of Ga to Zn is Ga:Zn=2:5 and a layer in which an atomic ratio of In to Ga and Zn is In:Ga:Zn=4:2:3, and a stacked-layer structure of gallium oxide and a layer in which an atomic ratio of In to Ga and Zn is In:Ga:Zn=4:2:3.

In the case where the atomic proportion of In to the element M in the metal oxide used as the oxide 530a is less than the atomic proportion of In to the element M in the metal oxide used as the oxide 530b, an In—Ga—Zn oxide in which an atomic ratio of In to Ga and Zn is In:Ga:Zn=5:1:6 or a neighborhood thereof, In:Ga:Zn=5:1:3 or a neighborhood thereof, In:Ga:Zn=10:1:3 or a neighborhood thereof, or the like can be used as the oxide 530b.

Furthermore, as a composition other than the above, as the oxide 530b, for example, a metal oxide having a composition of In:Zn=2:1, a composition of In:Zn=5:1, a composition of In:Zn=10:1, or a composition that is in the neighborhood of any one of them can be used.

The oxide 530a, the oxide 530b, and the oxide 530c are preferably combined to satisfy the above relation of the atomic ratios. For example, it is preferable that the oxide 530a and the oxide 530c be a metal oxide having a composition of In:Ga:Zn=1:3:4 or a composition that is in the neighborhood thereof and the oxide 530b be a metal oxide having a composition of In:Ga:Zn=4:2:3 to 4:2:4.1 or a composition that is in the neighborhood thereof. Note that the above composition represents the atomic ratio of an oxide formed over a base or the atomic ratio of a sputtering target. Furthermore, it is preferable that the proportion of In be increased in the composition of the oxide 530b to increase the on-state current, the field-effect mobility, or the like of the transistor.

The energy of the conduction band minimum of the oxide 530a and the oxide 530c is preferably higher than the energy of the conduction band minimum of the oxide 530b. In other words, the electron affinity of the oxide 530a and the oxide 530c is preferably smaller than the electron affinity of the oxide 530b.

Here, the energy level of the conduction band minimum is gradually varied at junction portions of the oxide 530a, the oxide 530b, and the oxide 530c. In other words, the energy level of the conduction band minimum at the junction portions of the oxide 530a, the oxide 530b, and the oxide 530c is continuously varied or continuously connected. To vary the energy level gradually, the density of defect states in a mixed layer formed at the interface between the oxide 530a and the oxide 530b and the interface between the oxide 530b and the oxide 530c is preferably made low.

Specifically, when the oxide 530a and the oxide 530b or the oxide 530b and the oxide 530c contain the same element (as a main component) in addition to oxygen, a mixed layer with a low density of defect states can be formed. For example, in the case where the oxide 530b is an In—Ga—Zn oxide, it is preferable to use an In—Ga—Zn oxide, a Ga—Zn oxide, gallium oxide, or the like as the oxide 530a and the oxide 530c.

At this time, the oxide 530b serves as a main carrier path. When the oxide 530a and the oxide 530c have the above-described structure, the density of defect states at the interface between the oxide 530a and the oxide 530b and the interface between the oxide 530b and the oxide 530c can be made low. Thus, the influence of interface scattering on carrier conduction is small, and the transistor 500 has a high on-state current.

The conductor 542a and the conductor 542b functioning as the source electrode and the drain electrode are provided over the oxide 530b. For the conductor 542a and the conductor 542b, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing any of the above-described metal elements; an alloy containing a combination of the above-described metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that hold their conductivity even after absorbing oxygen. Furthermore, a metal nitride film of tantalum nitride or the like is preferable because it has a barrier property against hydrogen or oxygen.

In addition, although the conductor 542a and the conductor 542b each having a single-layer structure are illustrated in FIG. 21A and FIG. 21B, a stacked-layer structure of two or more layers may be employed. For example, a tantalum nitride film and a tungsten film are preferably stacked. Alternatively, a titanium film and an aluminum film may be stacked. Alternatively, a two-layer structure in which an aluminum film is stacked over a tungsten film, a two-layer structure in which a copper film is stacked over a copper-magnesium-aluminum alloy film, a two-layer structure in which a copper film is stacked over a titanium film, or a two-layer structure in which a copper film is stacked over a tungsten film may be employed.

Other examples include a three-layer structure in which a titanium film or a titanium nitride film is formed, an aluminum film or a copper film is stacked over the titanium film or the titanium nitride film, and a titanium film or a titanium nitride film is formed over the aluminum film or the copper film; and a three-layer structure in which a molybdenum film or a molybdenum nitride film is formed, an aluminum film or a copper film is stacked over the molybdenum film or the molybdenum nitride film, and a molybdenum film or a molybdenum nitride film is formed over the aluminum film or the copper film. Note that a transparent conductive material containing indium oxide, tin oxide, or zinc oxide may be used.

As illustrated in FIG. 21A, a region 543a and a region 543b are sometimes formed as low-resistance regions in the oxide 530 at and around the interface with the conductor 542a (the conductor 542b). In this case, the region 543a functions as one of a source region and a drain region, and the region 543b functions as the other of the source region and the drain region. The channel formation region is formed in a region between the region 543a and the region 543b.

When the conductor 542a (the conductor 542b) is provided in contact with the oxide 530, the oxygen concentration of the region 543a (the region 543b) sometimes decreases. In addition, a metal compound layer that contains the metal contained in the conductor 542a (the conductor 542b) and the component of the oxide 530 is sometimes formed in the region 543a (the region 543b). In such a case, the carrier concentration of the region 543a (the region 543b) increases, and the region 543a (the region 543b) becomes a low-resistance region.

The insulator 544 is provided to cover the conductor 542a and the conductor 542b and inhibits oxidation of the conductor 542a and the conductor 542b. Here, the insulator 544 may be provided to cover the side surface of the oxide 530 and to be in contact with the insulator 524.

A metal oxide containing one or more selected from hafnium, aluminum, gallium, yttrium, zirconium, tungsten, titanium, tantalum, nickel, germanium, neodymium, lanthanum, magnesium, and the like can be used as the insulator 544. Moreover, silicon nitride oxide, silicon nitride, or the like can be used as the insulator 544.

It is particularly preferable to use an insulator containing an oxide of one of aluminum and hafnium, such as aluminum oxide or hafnium oxide as the insulator 544. Alternatively, it is preferable to use an oxide containing aluminum and hafnium (hafnium aluminate) or the like. In particular, hafnium aluminate has higher heat resistance than a hafnium oxide film. Therefore, hafnium aluminate is preferable because it is less likely to be crystallized by heat treatment in a later step. Note that the insulator 544 is not an essential component when the conductor 542a and the conductor 542b are oxidation-resistant materials or materials that do not significantly lose the conductivity even after absorbing oxygen. Design is appropriately determined in consideration of required transistor characteristics.

With the insulator 544, diffusion of impurities such as water and hydrogen contained in the insulator 580 into the oxide 530b can be inhibited. Moreover, oxidation of the conductor 560 due to excess oxygen contained in the insulator 580 can be inhibited.

The insulator 550 functions as a gate insulating film for the conductor 560. The insulator 550 is preferably provided in contact with an inner side (the top surface and the side surface) of the oxide 530c. Like the insulator 524 described above, the insulator 550 is preferably formed using an insulator that contains excess oxygen and releases oxygen by heating.

Specifically, it is possible to use any of silicon oxide, silicon oxynitride, silicon nitride oxide, silicon nitride, silicon oxide to which fluorine is added, silicon oxide to which carbon is added, silicon oxide to which carbon and nitrogen are added, and porous silicon oxide, each of which contains excess oxygen. In particular, silicon oxide and silicon oxynitride, which have thermal stability, are preferable.

When an insulator from which oxygen is released by heating is provided as the insulator 550 in contact with the top surface of the oxide 530c, oxygen can be effectively supplied from the insulator 550 to the channel formation region of the oxide 530b through the oxide 530c. Furthermore, as in the insulator 524, the concentration of impurities such as water or hydrogen in the insulator 550 is preferably lowered. The thickness of the insulator 550 is preferably greater than or equal to 1 nm and less than or equal to 20 nm.

In order to efficiently supply excess oxygen contained in the insulator 550 to the oxide 530, a metal oxide may be provided between the insulator 550 and the conductor 560. The metal oxide preferably has a function of inhibiting oxygen diffusion from the insulator 550 into the conductor 560. Providing the metal oxide that inhibits oxygen diffusion suppresses diffusion of excess oxygen from the insulator 550 into the conductor 560. That is, a reduction in the amount of excess oxygen supplied to the oxide 530 can be inhibited. Moreover, oxidation of the conductor 560 due to excess oxygen can be suppressed. For the metal oxide, a material that can be used for the insulator 544 is used.

Note that the insulator 550 may have a stacked-layer structure like the gate insulating film for the conductor 503. As miniaturization and high integration of transistors progress, a problem such as leakage current may arise because of a thinner gate insulating film. For that reason, when the insulator functioning as a gate insulating film has a stacked-layer structure of a high-k material and a thermally stable material, a gate potential at the time when the transistor operates can be lowered while the physical thickness of the gate insulating film is maintained. Furthermore, the stacked-layer structure can be thermally stable and have a high relative permittivity.

Although the conductor 560 functioning as the first gate electrode has a two-layer structure in FIG. 21A and FIG. 21B, the conductor 560 may have a single-layer structure or a stacked-layer structure of three or more layers.

For the conductor 560a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (e.g., N20, NO, and NO2), and a copper atom. Alternatively, it is preferable to use a conductive material having a function of inhibiting diffusion of oxygen (e.g., at least one of an oxygen atom, an oxygen molecule, and the like). When the conductor 560a has a function of inhibiting diffusion of oxygen, it is possible to inhibit a reduction in conductivity of the conductor 560b due to oxidation of the conductor 560b caused by oxygen contained in the insulator 550. As a conductive material having a function of inhibiting oxygen diffusion, tantalum, tantalum nitride, ruthenium, or ruthenium oxide is preferably used, for example. In addition, for the conductor 560a, the oxide semiconductor that can be used as the oxide 530 can be used. In that case, when the conductor 560b is deposited by a sputtering method, the conductor 560a can have a reduced electric resistance to be a conductor. This can be referred to as an OC (Oxide Conductor) electrode.

For the conductor 560b, it is preferable to use a conductive material containing tungsten, copper, or aluminum as its main component. The conductor 560b also functions as a wiring and thus a conductor having high conductivity is preferably used. For example, a conductive material containing tungsten, copper, or aluminum as its main component can be used. The conductor 560b may have a stacked-layer structure, for example, a stacked-layer structure of titanium or titanium nitride and any of the above conductive materials.

The insulator 580 is provided over the conductor 542a and over the conductor 542b with the insulator 544 positioned therebetween. The insulator 580 preferably includes an excess-oxygen region. For example, the insulator 580 preferably contains silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like. Silicon oxide and silicon oxynitride are particularly preferable in terms of high thermal stability. Silicon oxide and porous silicon oxide are preferable because an excess-oxygen region can be formed easily in a later step.

The insulator 580 preferably includes an excess-oxygen region. When the insulator 580 from which oxygen is released by heating is provided in contact with the oxide 530c, oxygen in the insulator 580 can be efficiently supplied to the oxide 530 through the oxide 530c. The concentration of impurities such as water or hydrogen in the insulator 580 is preferably lowered.

The opening of the insulator 580 overlaps with the region between the conductor 542a and the conductor 542b. Accordingly, the conductor 560 is formed to be embedded in the opening of the insulator 580 and the region sandwiched between the conductor 542a and the conductor 542b.

For miniaturization of the semiconductor apparatus, the gate length needs to be short. Meanwhile, it is necessary to prevent a reduction in conductivity of the conductor 560. When the conductor 560 is made thick in order to prevent a reduction in conductivity of the conductor 560, the conductor 560 might have a shape with a high aspect ratio. Even when the conductor 560 has a shape with a high aspect ratio, the conductor 560 can be formed without collapsing during the process because the conductor 560 is provided to be embedded in the opening of the insulator 580 in this embodiment.

The insulator 574 is preferably provided in contact with the top surface of the insulator 580, the top surface of the conductor 560, and the top surface of the insulator 550. When the insulator 574 is deposited by a sputtering method, an excess-oxygen region can be provided in the insulator 550 and the insulator 580. Thus, oxygen can be supplied from the excess-oxygen regions to the oxide 530.

For example, a metal oxide containing one or more selected from hafnium, aluminum, gallium, yttrium, zirconium, tungsten, titanium, tantalum, nickel, germanium, magnesium, and the like can be used as the insulator 574.

In particular, aluminum oxide has a high barrier property, and even a thin aluminum oxide film having a thickness of greater than or equal to 0.5 nm and less than or equal to 3.0 nm can inhibit diffusion of hydrogen and nitrogen. Accordingly, an aluminum oxide film deposited by a sputtering method can serve both as an oxygen supply source and as a barrier film against impurities such as hydrogen.

An insulator 581 functioning as an interlayer film is preferably provided over the insulator 574. As in the insulator 524 and the like, the concentration of impurities such as water or hydrogen in the insulator 581 is preferably lowered.

A conductor 540a and a conductor 540b are placed in openings formed in the insulator 581, the insulator 574, the insulator 580, and the insulator 544. The conductor 540a and the conductor 540b are provided to face each other with the conductor 560 sandwiched therebetween. The conductor 540a and the conductor 540b each have a structure similar to a structure of a conductor 546 and a conductor 548 that will be described later.

An insulator 582 is provided over the insulator 581. A material having a barrier property against oxygen and hydrogen is preferably used for the insulator 582. Thus, for the insulator 582, a material similar to that for the insulator 514 can be used. For example, a metal oxide such as aluminum oxide, hafnium oxide, or tantalum oxide is preferably used for the insulator 582.

In particular, aluminum oxide has an excellent blocking effect that prevents transmission of oxygen and impurities such as hydrogen and moisture which would cause a change in the electrical characteristics of the transistor. Accordingly, the use of aluminum oxide can prevent entry of impurities such as hydrogen and moisture into the transistor 500 in and after the manufacturing process of the transistor. In addition, release of oxygen from the oxide included in the transistor 500 can be inhibited. Therefore, aluminum oxide is suitably used for a protective film of the transistor 500.

An insulator 586 is provided over the insulator 582. For the insulator 586, a material similar to that for the insulator 320 can be used. The use of a material with a relatively low permittivity for these insulators can reduce the parasitic capacitance generated between wirings. For example, a silicon oxide film or a silicon oxynitride film can be used for the insulator 586.

The conductor 546, the conductor 548, and the like are embedded in the insulator 520, the insulator 522, the insulator 524, the insulator 544, the insulator 580, the insulator 574, the insulator 581, the insulator 582, and the insulator 586.

The conductor 546 and the conductor 548 function as plugs or wirings that are connected to the capacitive element 600, the transistor 500, or the transistor 300. The conductor 546 and the conductor 548 can be provided using a material similar to those for the conductor 328 and the conductor 330.

Note that after the transistor 500 is formed, an opening may be formed to surround the transistor 500 and an insulator having a high barrier property against hydrogen or water may be formed to cover the opening. Surrounding the transistor 500 by the above-described insulator having a high barrier property can prevent entry of moisture and hydrogen from the outside. Alternatively, a plurality of transistors 500 may be collectively surrounded by the insulator having a high barrier property against hydrogen or water. When an opening is formed to surround the transistor 500, for example, the formation of an opening reaching the insulator 514 or the insulator 522 and the formation of the above-described insulator having a high barrier property in contact with the insulator 514 or the insulator 522 are suitable because these formation steps can also serve as some of the manufacturing steps of the transistor 500. For the insulator having a high barrier property against hydrogen or water, a material similar to that for the insulator 522 is used, for example.

The capacitive element 600 is provided above the transistor 500. The capacitive element 600 includes a conductor 610, a conductor 620, and an insulator 630.

A conductor 612 may be provided over the conductor 546 and the conductor 548. The conductor 612 has a function of a plug or a wiring that is connected to the transistor 500. The conductor 610 has a function of an electrode of the capacitive element 600. The conductor 612 and the conductor 610 can be formed at the same time.

As the conductor 612 and the conductor 610, it is possible to use a metal film containing an element selected from molybdenum, titanium, tantalum, tungsten, aluminum, copper, chromium, neodymium, and scandium; a metal nitride film containing any of the above-described elements as its component (a tantalum nitride film, a titanium nitride film, a molybdenum nitride film, or a tungsten nitride film); or the like. Alternatively, it is possible to use a conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added.

The conductor 612 and the conductor 610 each have a single-layer structure in FIG. 19; however, the structure is not limited thereto, and a stacked-layer structure of two or more layers may be employed. For example, between a conductor having a barrier property and a conductor having high conductivity, a conductor that is highly adhesive to the conductor having a barrier property and the conductor having high conductivity may be formed.

The conductor 620 is provided so as to overlap with the conductor 610 with the insulator 630 therebetween. For the conductor 620, a conductive material such as a metal material, an alloy material, or a metal oxide material can be used. It is preferable to use a high-melting-point material that has both heat resistance and conductivity, such as tungsten or molybdenum, and it is particularly preferable to use tungsten. In the case where the conductor 620 is formed concurrently with another component such as a conductor, Cu (copper), Al (aluminum), or the like, which is a low-resistance metal material, is used.

An insulator 650 is provided over the conductor 620 and the insulator 630. The insulator 650 can be provided using a material similar to that for the insulator 320. The insulator 650 may function as a smoothation film that covers an uneven shape thereunder.

With the use of this structure, a change in electrical characteristics can be reduced and the reliability can be improved in a semiconductor apparatus using a transistor including an oxide semiconductor. Alternatively, a semiconductor apparatus using a transistor including an oxide semiconductor can be miniaturized or highly integrated.

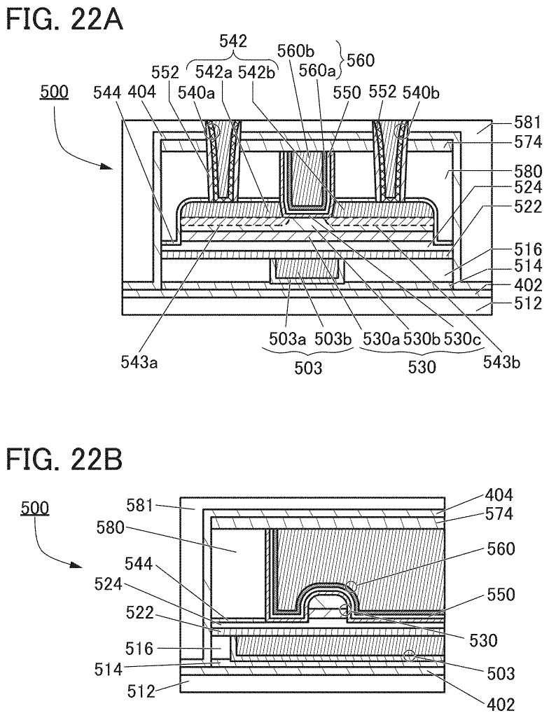

FIG. 22A and FIG. 22B show a modification example of the transistor 500 illustrated in FIG. 21A and FIG. 21B. FIG. 22A is a cross-sectional view of the transistor 500 in the channel length direction, and FIG. 22B is a cross-sectional view of the transistor 500 in the channel width direction. The transistor 500 illustrated in FIG. 22A and FIG. 22B is different from the transistor 500 illustrated in FIG. 21A and FIG. 21B in that the insulator 402 and the insulator 404 are included. Another difference from the transistor 500 illustrated in FIG. 21A and FIG. 21B is that insulators 552 are provided in contact with the side surface of the conductor 540a and the side surface of the conductor 540b. Another difference from the transistor 500 illustrated in FIG. 21A and FIG. 21B is that the insulator 520 is not included. Note that the structure illustrated in FIG. 22A and FIG. 22B can also be employed for other transistors, such as the transistor 300, included in the semiconductor apparatus of one embodiment of the present invention.

In the transistor 500 having the structure illustrated in FIG. 22A and FIG. 22B, the insulator 402 is provided over the insulator 512. The insulator 404 is provided over the insulator 574 and the insulator 402.

In the transistor 500 having the structure illustrated in FIG. 22A and FIG. 22B, the insulator 514, the insulator 516, the insulator 522, the insulator 524, the insulator 544, the insulator 580, and the insulator 574 are provided and covered with the insulator 404. That is, the insulator 404 is in contact with the top surface of the insulator 574, the side surface of the insulator 574, the side surface of the insulator 580, the side surface of the insulator 544, the side surface of the insulator 524, the side surface of the insulator 522, the side surface of the insulator 516, the side surface of the insulator 514, and the top surface of the insulator 402. Thus, the oxide 530 and the like are isolated from the outside by the insulator 404 and the insulator 402.

The insulator 402 and the insulator 404 preferably have high capability of inhibiting diffusion of hydrogen (e.g., at least one of a hydrogen atom, a hydrogen molecule, and the like) or a water molecule. For example, as the insulator 402 and the insulator 404, silicon nitride or silicon nitride oxide that is a material having a high hydrogen barrier property is preferably used. This can inhibit diffusion of hydrogen or the like into the oxide 530, thereby suppressing the degradation of the characteristics of the transistor 500. Consequently, the reliability of the semiconductor apparatus of one embodiment of the present invention can be increased.

The insulator 552 is provided in contact with the insulator 581, the insulator 404, the insulator 574, the insulator 580, and the insulator 544. The insulator 552 preferably has a function of inhibiting diffusion of hydrogen or water molecules. For example, as the insulator 552, an insulator such as silicon nitride, aluminum oxide, or silicon nitride oxide that is a material having a high hydrogen barrier property is preferably used. In particular, silicon nitride is suitably used for the insulator 552 because of its high hydrogen barrier property. The use of a material having a high hydrogen barrier property for the insulator 552 can inhibit diffusion of impurities such as water or hydrogen from the insulator 580 and the like into the oxide 530 through the conductor 540a or the conductor 540b. Furthermore, oxygen contained in the insulator 580 can be inhibited from being absorbed by the conductor 540a and the conductor 540b. As described above, the reliability of the semiconductor apparatus of one embodiment of the present invention can be increased.

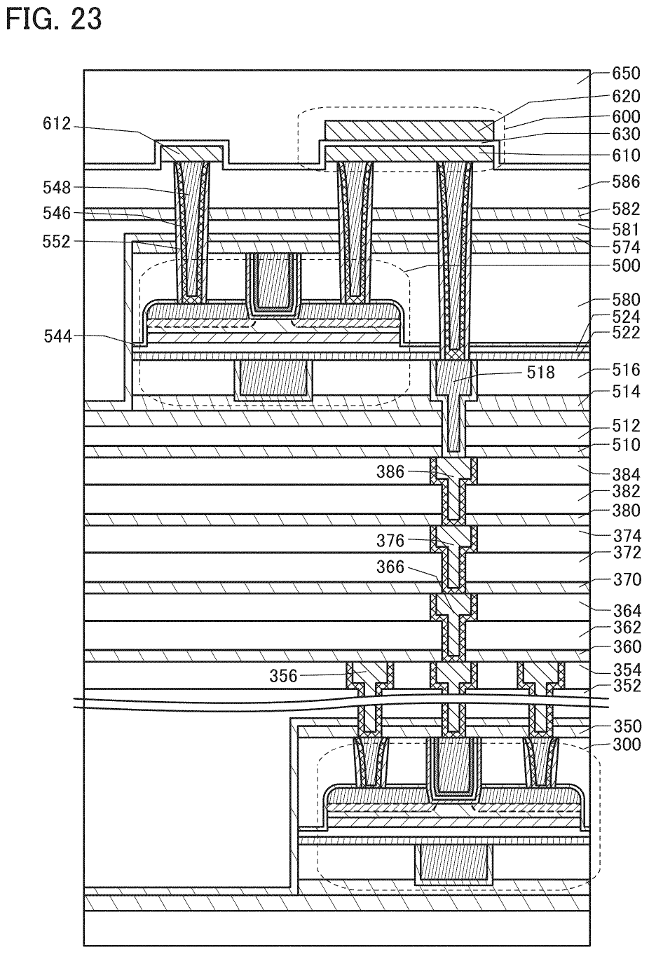

FIG. 23 is a cross-sectional view showing a structure example of the semiconductor apparatus in the case where the transistor 500 and the transistor 300 have the structure illustrated in FIG. 22A and FIG. 22B. The insulator 552 is provided on the side surface of the conductor 546.

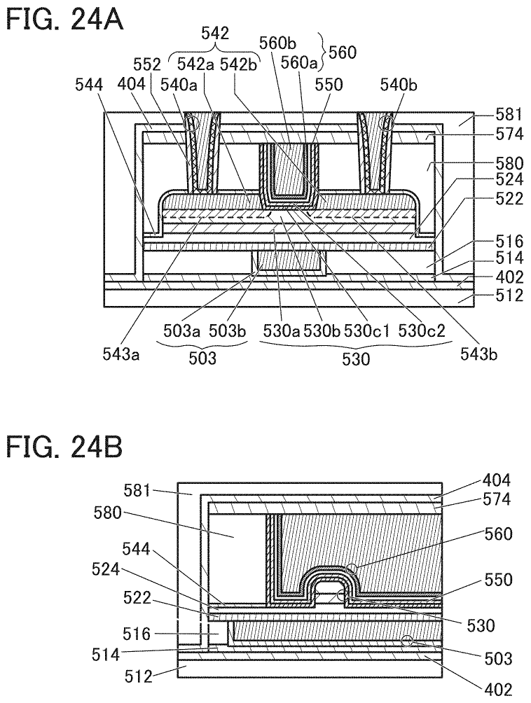

FIG. 24A and FIG. 24B show a modification example of the transistor illustrated in FIG. 22A and FIG. 22B. FIG. 24A is a cross-sectional view of the transistor in the channel length direction, and FIG. 24B is a cross-sectional view of the transistor in the channel width direction. The transistor illustrated in FIG. 24A and FIG. 24B is different from the transistor illustrated in FIG. 22A and FIG. 22B in that the oxide 530c has a two-layer structure of an oxide 530c1 and an oxide 530c2.

The oxide 530c1 is in contact with the top surface of the insulator 524, the side surface of the oxide 530a, the top surface and the side surface of the oxide 530b, the side surfaces of the conductor 542a and the conductor 542b, the side surface of the insulator 544, and the side surface of the insulator 580. The oxide 530c2 is in contact with the insulator 550.

An In—Zn oxide can be used as the oxide 530c1, for example. As the oxide 530c2, it is possible to use a material similar to a material that can be used for the oxide 530c when the oxide 530c has a single-layer structure. As the oxide 530c2, a metal oxide with n:Ga:Zn=1:3:4 [atomic ratio], Ga:Zn=2:1 [atomic ratio], or Ga:Zn=2:5 [atomic ratio] can be used, for example.

When the oxide 530c has a two-layer structure of the oxide 530c1 and the oxide 530c2, the on-state current of the transistor can be increased as compared with the case where the oxide 530c has a single-layer structure. Thus, a transistor can be used as a power MOS transistor, for example. Note that the oxide 530c included in the transistor having the structure illustrated in FIG. 21A and FIG. 21B can also have a two-layer structure of the oxide 530c1 and the oxide 530c2.

The transistor having the structure illustrated in FIG. 24A and FIG. 24B can be used as the transistor 300 illustrated in FIG. 19 or FIG. 20, for example. Moreover, as described above, the transistor 300 can be used as the transistor Tr12 or the like of the memory cell array CA included in the arithmetic circuit MAC1 or the like described in the above embodiment, for example. Note that the transistor illustrated in FIG. 24A and FIG. 24B can be used as a transistor other than the transistor 300, which is included in the semiconductor apparatus of one embodiment of the present invention, such as the transistor 500.

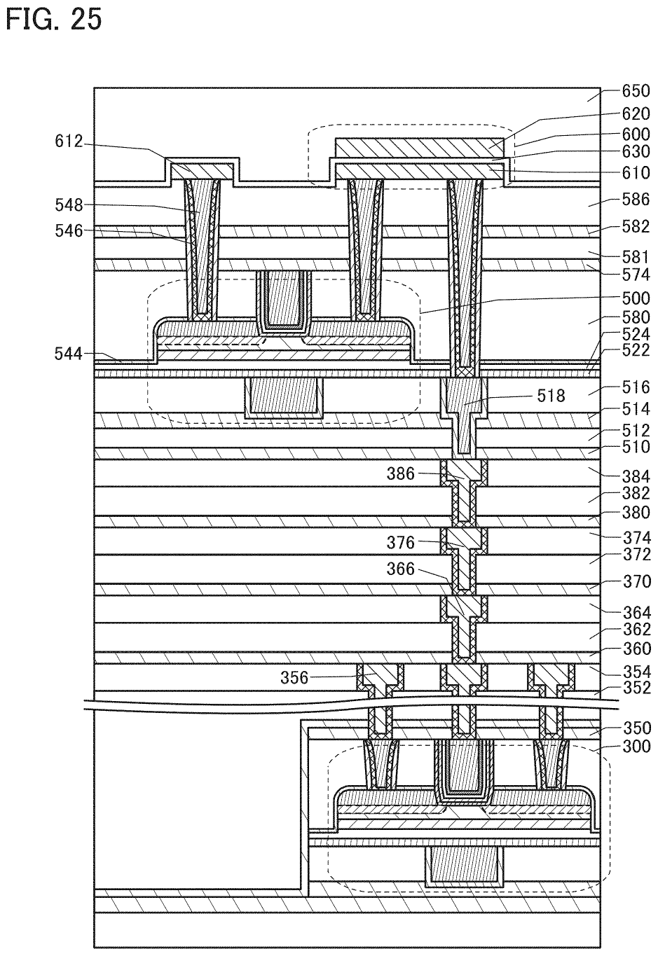

FIG. 25 is a cross-sectional view showing a structure example of a semiconductor apparatus in which the transistor 500 has the structure of the transistor illustrated in FIG. 21A and the transistor 300 has the structure of the transistor illustrated in FIG. 24A. Note that as in FIG. 23, the insulator 552 is provided on the side surface of the conductor 546. As illustrated in FIG. 25, in the semiconductor apparatus of one embodiment of the present invention, the transistor 300 and the transistor 500 can have different structures while both the transistor 300 and the transistor 500 can be OS transistors.

Next, a capacitor that can be used for the semiconductor apparatus illustrated in FIG. 19 or FIG. 20 will be described.

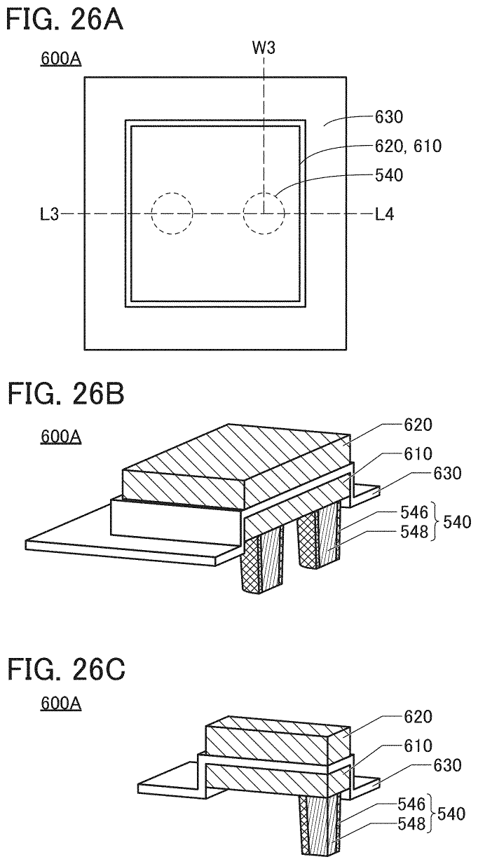

FIG. 26A to FIG. 26C illustrate a capacitive element 600A as an example of the capacitive element 600 that can be used in the semiconductor apparatus illustrated in FIG. 19. FIG. 26A is a top view of the capacitive element 600A, FIG. 26B is a perspective view illustrating a cross section of the capacitive element 600A along the dashed-dotted line L3-L4, and FIG. 26C is a perspective view illustrating a cross section of the capacitive element 600A along the dashed-dotted line W3-L4.

The conductor 610 functions as one of a pair of electrodes of the capacitive element 600A, and the conductor 620 functions as the other of the pair of electrodes of the capacitive element 600A. The insulator 630 functions as a dielectric sandwiched between the pair of electrodes.

The insulator 630 can be provided to have a single-layer structure or a stacked-layer structure using, for example, silicon oxide, silicon oxynitride, silicon nitride oxide, silicon nitride, aluminum oxide, aluminum oxynitride, aluminum nitride oxide, aluminum nitride, hafnium oxide, hafnium oxynitride, hafnium nitride oxide, hafnium nitride, or zirconium oxide.

For example, for the insulator 630, a stacked-layer structure using a material with high dielectric strength such as silicon oxynitride and a high-k material may be employed. When the insulator 630 includes an insulator that is a high-k material, the capacitive element 600A can ensure sufficient capacitance. Furthermore, when the insulator 630 includes an insulator with high dielectric strength, the dielectric strength of the capacitive element 600A increases and electrostatic breakdown of the capacitive element 600A can be inhibited.

Examples of the insulator that is a high-k material include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Alternatively, for example, a single layer or stacked layers of an insulator containing a high-k material, such as aluminum oxide, hafnium oxide, tantalum oxide, zirconium oxide, lead zirconate titanate (PZT), strontium titanate (SrTiO₃), or (Ba,Sr)TiO₃ (BST), may be used as the insulator 630. In the case where the insulator 630 has a stacked-layer structure, a three-layer structure with zirconium oxide, aluminum oxide, and zirconium oxide in this order, or a four-layer structure with zirconium oxide, aluminum oxide, zirconium oxide, and aluminum oxide in this order is employed, for example. For the insulator 630, a compound containing hafnium and zirconium may be used, for example. When the semiconductor apparatus is miniaturized and highly integrated, a dielectric used for a gate insulator and a capacitor becomes thin, which might cause a problem of leak current of a transistor and a capacitive element, for example. When a high-k material is used for an insulator functioning as the dielectric used for the gate insulator and the capacitive element, a gate potential during operation of the transistor can be lowered and the capacitance of the capacitive element can be ensured while the physical thickness is kept.

The bottom portion of the conductor 610 in the capacitive element 600 is electrically connected to the conductor 546 and the conductor 548. The conductor 546 and the conductor 548 function as plugs or wirings for connection to another circuit element. In FIG. 26, the conductor 546 and the conductor 548 are collectively denoted as a conductor 540.

For clarification of the drawing, the insulator 586 in which the conductor 546 and the conductor 548 are embedded and the insulator 650 that covers the conductor 620 and the insulator 630 are omitted in FIG. 26.

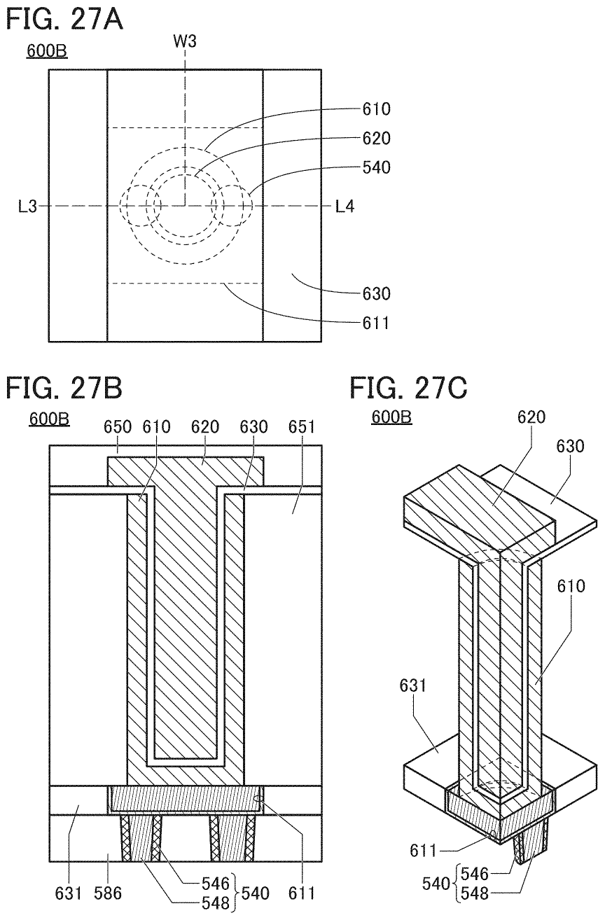

Although the capacitive element 600 illustrated in FIG. 19, FIG. 20, FIG. 23, FIG. 25, and FIG. 26 is a planar capacitive element, the shape of the capacitive element is not limited thereto. For example, the capacitive element 600 may be a cylindrical capacitive element 600B illustrated in FIG. 27A to FIG. 27C.

FIG. 27A is a top view of the capacitive element 600B, FIG. 27B is a cross-sectional view of the capacitive element 600B along the dashed-dotted line L3-L4, and FIG. 27C is a perspective view illustrating a cross section of the capacitive element 600B along the dashed-dotted line W3-L4.

As illustrated in FIG. 27B, the capacitive element 600B includes an insulator 631 over the insulator 586 in which the conductor 540 is embedded, an insulator 651 having an opening portion, the conductor 610 functioning as one of a pair of electrodes, and the conductor 620 functioning as the other of the pair of electrodes.

For clarification of the drawing, the insulator 586, the insulator 650, and the insulator 651 are omitted in FIG. 27C.

For the insulator 631, a material similar to that for the insulator 586 can be used, for example.

A conductor 611 is embedded in the insulator 631 to be electrically connected to the conductor 540. For the conductor 611, a material similar to those for the conductor 330 and the conductor 518 can be used, for example.

For the insulator 651, a material similar to that for the insulator 586 can be used, for example.

The insulator 651 has an opening portion as described above, and the opening portion overlaps with the conductor 611.

The conductor 610 is formed on the bottom portion and the side surface of the opening portion. In other words, the conductor 620 has a region in contact with the conductor 611.

In order to form the conductor 610, first, an opening portion is formed in the insulator 651 by an etching method or the like. Then, the conductor 610 is deposited by a sputtering method, an ALD method, or the like. After that, the conductor 610 deposited over the insulator 651 is removed by a CMP (Chemichal Mechanical Polishing) method or the like while the conductor 610 deposited in the opening portion is left.

The insulator 630 is positioned over the insulator 651 and over the formation surface of the conductor 610. Note that the insulator 630 functions as a dielectric sandwiched between the pair of electrodes in the capacitive element 600B.

The conductor 620 is formed over the insulator 630 so as to fill the opening portion of the insulator 651.

The insulator 650 is formed to cover the insulator 630 and the conductor 620.

The capacitance value of the cylindrical capacitive element 600B illustrated in FIG. 27A to FIG. 27C can be higher than that of the planar capacitive element 600A. Thus, when the capacitive element 600B is used as the capacitor C1, the capacitor C2, and the like described in the above embodiment, for example, a voltage between the terminals of the capacitive element can be maintained for long time.

The structure examples described in this embodiment can be combined with each other as appropriate. This embodiment can be combined with any of the other embodiments and the like in this specification as appropriate.

### Embodiment 6

In this embodiment, the composition of a CAC-OS (Cloud-Aligned Composite Oxide Semiconductor) and a CAAC-OS (c-axis Aligned Crystalline Oxide Semiconductor), which are metal oxides that can be used in the OS transistor described in the above embodiment, will be described.

### <Composition of Metal Oxide>

A CAC-OS or a CAC-metal oxide has a conducting function in a part of the material and has an insulating function in a part of the material, and has a function of a semiconductor as the whole material. Note that in the case where the CAC-OS or the CAC-metal oxide is used in an active layer of a transistor, the conducting function is a function of allowing electrons (or holes) serving as carriers to flow, and the insulating function is a function of not allowing electrons serving as carriers to flow. By the complementary action of the conducting function and the insulating function, the CAC-OS or the CAC-metal oxide can have a switching function (On/Off function). In the CAC-OS or the CAC-metal oxide, separation of the functions can maximize each function.

In addition, the CAC-OS or the CAC-metal oxide includes conductive regions and insulating regions. The conductive regions have the above-described conducting function, and the insulating regions have the above-described insulating function. In some cases, the conductive regions and the insulating regions in the material are separated at the nanoparticle level. In some cases, the conductive regions and the insulating regions are unevenly distributed in the material. The conductive regions are observed to be coupled in a cloud-like manner with their boundaries blurred, in some cases.

Furthermore, in the CAC-OS or the CAC-metal oxide, the conductive regions and the insulating regions each have a size of greater than or equal to 0.5 nm and less than or equal to 10 nm, preferably greater than or equal to 0.5 nm and less than or equal to 3 nm and are dispersed in the material, in some cases.

The CAC-OS or the CAC-metal oxide is formed of components having different bandgaps. For example, the CAC-OS or the CAC-metal oxide is formed of a component having a wide gap due to the insulating region and a component having a narrow gap due to the conductive region. When carriers flow in such a structure, carriers mainly flow in the component having a narrow gap. The component having a narrow gap complements the component having a wide gap, and carriers also flow in the component having a wide gap in conjunction with the component having a narrow gap. Therefore, in the case where the above-described CAC-OS or CAC-metal oxide is used in a channel formation region of a transistor, high current drive capability in the on state of the transistor, that is, high on-state current and high field-effect mobility, can be obtained.

In other words, the CAC-OS or the CAC-metal oxide can also be called a matrix composite or a metal matrix composite.

### <Structure of Metal Oxide>

An oxide semiconductor is classified into a single crystal oxide semiconductor and a non-single crystal oxide semiconductor. Examples of a non-single crystal oxide semiconductor include a CAAC-OS, a polycrystalline oxide semiconductor, an nc-OS (nanocrystalline oxide semiconductor), an amorphous-like oxide semiconductor (a-like OS), and an amorphous oxide semiconductor.

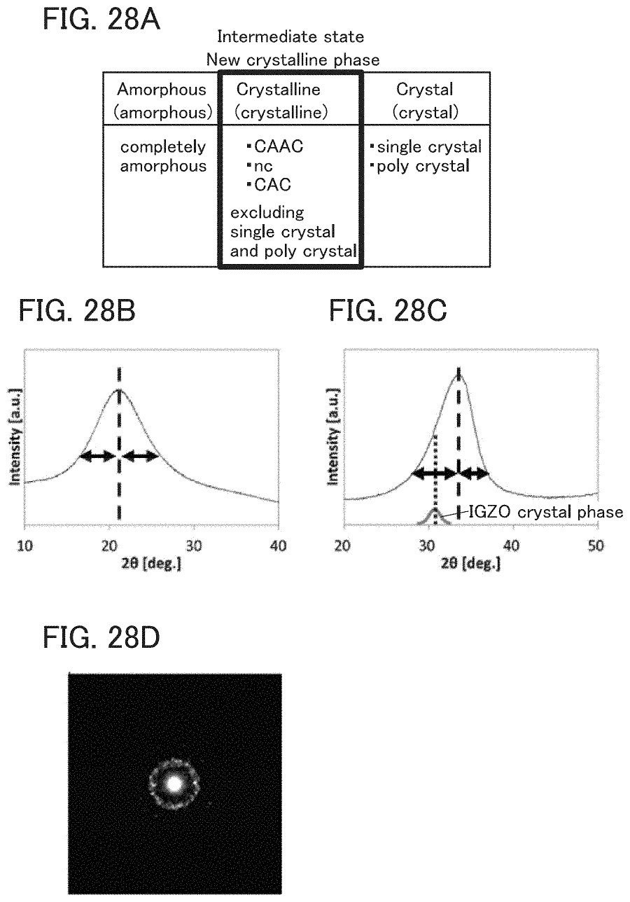

Oxide semiconductors might be classified in a manner different from the above-described one when classified in terms of the crystal structure. Here, the classification of the crystal structures of an oxide semiconductor is explained with FIG. 28A. FIG. 28A is a diagram showing the classification of crystal structures of an oxide semiconductor, typically IGZO (a metal oxide containing In, Ga, and Zn).

As shown in FIG. 28A, IGZO is roughly classified into Amorphous, Crystalline, and Crystal. Amorphous includes completely amorphous. Crystalline includes CAAC (c-axis aligned crystalline), nc (nanocrystalline), and CAC (Cloud-Aligned Composite). Note that Crystalline excludes single crystal, poly crystal, and completely amorphous (excluding single crystal and poly crystal). Crystal includes single crystal and poly crystal.

Note that the structures in the thick frame in FIG. 28A are in an intermediate state between Amorphous and Crystal, and belong to a new crystalline phase. This structure is positioned in a boundary region between Amorphous and Crystal. In other words, these structures can be rephrased as structures completely different from Amorphous, which is energetically unstable, and Crystal.

A crystal structure of a film or a substrate can be analyzed with X-ray diffraction (XRD) images. Here, XRD spectra of quartz glass and IGZO, which has a crystal structure classified into Crystalline (also referred to as Crystalline IGZO), are shown in FIG. 28B and FIG. 28C. FIG. 28B shows an XRD spectrum of quartz glass and FIG. 28C shows an XRD spectrum of Crystalline IGZO. Note that Crystalline IGZO shown in FIG. 28C has a composition in the neighborhood of In:Ga:Zn=4:2:3 [atomic ratio]. Furthermore, Crystalline IGZO shown in FIG. 28C has a thickness of 500 nm.

As indicated by arrows in FIG. 28B, the XRD spectrum of the quartz glass shows a substantially bilaterally symmetrical peak. In contrast, as indicated by arrows in FIG. 28C, the XRD spectrum of Crystalline IGZO shows a bilaterally asymmetrical peak. The bilaterally asymmetrical peak of the XRD spectrum clearly shows the existence of a crystal. In other words, the structure cannot be regarded as Amorphous unless it has a bilaterally symmetrical peak in the XRD spectrum. Note that in FIG. 28C, a crystal phase (IGZO crystal phase) is explicitly denoted at 20=31° or in the neighborhood thereof. The bilaterally asymmetrical peak of the XRD spectrum is probably derived from such a crystal phase (a fine crystal).

Specifically, in the XRD spectrum of Crystalline IGZO shown in FIG. 28C, there is a peak at 20=34° or in the neighborhood thereof. The microcrystal has a peak at 20=31° or in the neighborhood thereof. When an oxide semiconductor film is evaluated using an X-ray diffraction pattern, the spectrum becomes wide in the lower degree side than the peak at 20=34° or in the neighborhood thereof as shown in FIG. 28C. This indicates that the oxide semiconductor film includes a microcrystal attributed to a peak at 20=31° or in the neighborhood thereof.

A crystal structure of a film can also be evaluated with a diffraction pattern obtained by a nanobeam electron diffraction (NBED) method (such a pattern is also referred to as a nanobeam electron diffraction pattern). A diffraction pattern of the IGZO film deposited with a substrate temperature set at room temperature is shown in FIG. 28D. Note that the IGZO film shown FIG. 28D is deposited by a sputtering method using an oxide target with In:Ga:Zn=1:1:1 [atomic ratio]. In the nanobeam electron diffraction method, electron diffraction was performed with a probe diameter of 1 nm.

As shown in FIG. 28D, not a halo pattern but a spot-like pattern is observed in the diffraction pattern of the IGZO film deposited at room temperature. Thus, it is presumed that the IGZO film deposited at room temperature is in an intermediate state, which is neither a crystal state nor an amorphous state, and it cannot be concluded that the IGZO film is in an amorphous state.

The CAAC-OS has c-axis alignment, a plurality of nanocrystals are connected in the a-b plane direction, and its crystal structure has distortion. Note that distortion refers to a portion where the direction of a lattice arrangement changes between a region with a uniform lattice arrangement and another region with a uniform lattice arrangement in a region where the plurality of nanocrystals are connected.

The nanocrystal is basically a hexagon but is not always a regular hexagon and is a non-regular hexagon in some cases. Furthermore, a pentagonal lattice arrangement, a heptagonal lattice arrangement, and the like are included in the distortion in some cases. Note that a clear crystal grain boundary (also referred to as grain boundary) cannot be observed even in the vicinity of distortion in the CAAC-OS. That is, formation of a crystal grain boundary is inhibited by the distortion of a lattice arrangement. This is probably because the CAAC-OS can tolerate distortion owing to a low density of oxygen atom arrangement in an a-b plane direction, a change in interatomic bond distance by replacement of a metal element, and the like.

Note that a crystal structure in which a clear crystal grain boundary (grain boundary) is observed is what is called polycrystal. It is highly probable that the crystal grain boundary becomes a recombination center and traps carriers and thus decreases the on-state current and field-effect mobility of a transistor. Thus, the CAAC-OS in which no clear crystal grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a crystal grain boundary as compared with an In oxide.

Furthermore, the CAAC-OS tends to have a layered crystal structure (also referred to as a layered structure) in which a layer containing indium and oxygen (hereinafter, In layer) and a layer containing the element M, zinc, and oxygen (hereinafter, (M, Zn) layer) are stacked. Note that indium and the element M can be replaced with each other, and when the element M of the (M, Zn) layer is replaced by indium, the layer can also be referred to as an (In, M, Zn) layer. Furthermore, when indium of the In layer is replaced by the element M, the layer can also be referred to as an (In, M) layer.

The CAAC-OS is an oxide semiconductor with high crystallinity. By contrast, in the CAAC-OS, it can be said that a reduction in electron mobility due to the crystal grain boundary is less likely to occur because a clear crystal grain boundary cannot be observed. Moreover, since the crystallinity of an oxide semiconductor might be decreased by entry of impurities, formation of defects, or the like, the CAAC-OS can be regarded as an oxide semiconductor that has small amounts of impurities and defects (oxygen vacancies or the like). Thus, an oxide semiconductor including a CAAC-OS is physically stable. Therefore, the oxide semiconductor including a CAAC-OS is resistant to heat and has high reliability. In addition, the CAAC-OS is stable with respect to high temperature in the manufacturing process (what is called thermal budget). Accordingly, the use of the CAAC-OS for the OS transistor can extend a degree of freedom of the manufacturing process.

The nc-OS has a periodic atomic arrangement in a microscopic region (for example, a region with a size greater than or equal to 1 nm and less than or equal to 10 nm, in particular, a region with a size greater than or equal to 1 nm and less than or equal to 3 nm). In addition, no regularity of crystal orientation is observed between different nanocrystals in the nc-OS. Thus, the orientation is not observed in the whole film. Accordingly, in some cases, the nc-OS cannot be distinguished from an a-like OS or an amorphous oxide semiconductor depending on an analysis method.

The a-like OS is an oxide semiconductor that has a structure between those of the nc-OS and the amorphous oxide semiconductor. The a-like OS has a void or a low-density region. That is, the a-like OS has low crystallinity as compared with the nc-OS and the CAAC-OS.

An oxide semiconductor has various structures with different properties. Two or more kinds among the amorphous oxide semiconductor, the polycrystalline oxide semiconductor, the a-like OS, the nc-OS, and the CAAC-OS may be included in an oxide semiconductor of one embodiment of the present invention.

### <Transistor Including Oxide Semiconductor>

Next, the case where the above oxide semiconductor is used for a transistor will be described.

When the above oxide semiconductor is used for a transistor, a transistor with high field-effect mobility can be achieved. In addition, a transistor with high reliability can be achieved.

An oxide semiconductor with a low carrier concentration is preferably used for a transistor. In the case where the carrier concentration of an oxide semiconductor film is lowered, the impurity concentration in the oxide semiconductor film is lowered to lower the density of defect states. In this specification and the like, a state with a low impurity concentration and a low density of defect states is sometimes referred to as a highly purified intrinsic or substantially highly purified intrinsic state, or is sometimes referred to as an intrinsic or substantially intrinsic state.

In addition, a highly purified intrinsic or substantially highly purified intrinsic oxide semiconductor film has a low density of defect states and accordingly has a low density of trap states in some cases.

Furthermore, charges trapped by the trap states in the oxide semiconductor take a long time to disappear and may behave like fixed charges. Thus, a transistor whose channel formation region is formed in an oxide semiconductor with a high density of trap states has unstable electrical characteristics in some cases.

Thus, in order to stabilize electrical characteristics of the transistor, reducing the impurity concentration in the oxide semiconductor is effective. Furthermore, in order to reduce the impurity concentration in the oxide semiconductor, it is preferred that the impurity concentration in an adjacent film be also reduced. Examples of impurities include hydrogen, nitrogen, an alkali metal, an alkaline earth metal, iron, nickel, and silicon.

### <Impurity>

Here, the influence of each impurity in the oxide semiconductor will be described.

When silicon or carbon, which is one of the Group 14 elements, is contained in the oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration obtained by secondary ion mass spectrometry (SIMS)) are set lower than or equal to 2×10¹⁸ atoms/cm³, preferably lower than or equal to 2×10¹⁷ atoms/cm³.

Furthermore, when the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Accordingly, it is preferred to reduce the concentration of an alkali metal or an alkaline earth metal in the oxide semiconductor. Specifically, the concentration of an alkali metal or an alkaline earth metal in the oxide semiconductor obtained by SIMS is set lower than or equal to 1×10¹⁸ atoms/cm³, preferably lower than or equal to 2×10¹⁶ atoms/cm³.

Furthermore, when containing nitrogen, the oxide semiconductor easily becomes n-type by generation of electrons serving as carriers and an increase in carrier concentration. As a result, a transistor using an oxide semiconductor containing nitrogen as a semiconductor is likely to have normally-on characteristics. For this reason, nitrogen in the oxide semiconductor is preferably reduced as much as possible; the nitrogen concentration in the oxide semiconductor obtained by SIMS is set, for example, lower than 5×10¹⁹ atoms/cm³, preferably lower than or equal to 5×10¹⁸ atoms/cm³, more preferably lower than or equal to 1×10¹⁸ atoms/cm³, and still more preferably lower than or equal to 5×10¹⁷ atoms/cm³.

Furthermore, hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, in some cases, bonding of part of hydrogen to oxygen bonded to a metal atom causes generation of an electron serving as a carrier. Thus, a transistor using an oxide semiconductor containing hydrogen is likely to have normally-on characteristics. Accordingly, hydrogen in the oxide semiconductor is preferably reduced as much as possible. Specifically, the hydrogen concentration in the oxide semiconductor obtained by SIMS is lower than 1×10²⁰ atoms/cm³, preferably lower than 1×10¹⁹ atoms/cm³, more preferably lower than 5×10¹⁸ atoms/cm³, and still more preferably lower than 1×10¹⁸ atoms/cm³.

When an oxide semiconductor with sufficiently reduced impurities is used for a channel formation region of a transistor, stable electrical characteristics can be given.

The structure examples described in this embodiment can be combined with each other as appropriate. This embodiment can be combined with any of the other embodiments and the like in this specification as appropriate.

Embodiments (or an example) in this specification are described with reference to the drawings. Note that the embodiments (or the example) can be implemented in many different modes, and it will be readily appreciated by those skilled in the art that modes and details can be changed in various ways without departing from the spirit and scope thereof. Therefore, the present invention should not be interpreted as being limited to the description in the embodiments (or the example). Note that in the structures of the invention in the embodiments (or the example), the same portions or portions having similar functions are denoted by the same reference numerals in different drawings, and repetitive description thereof is omitted in some cases. In perspective views and the like, some components might not be illustrated for clarity of the drawings.

In the drawings in this specification, the size, the layer thickness, or the region is exaggerated for clarity in some cases. Therefore, they are not limited to the scale. Note that the drawings schematically show ideal examples, and embodiments of the present invention are not limited to shapes or values shown in the drawings. For example, variation in signal, voltage, or current due to noise or variation in signal, voltage, or current due to difference in timing can be included.

In this specification and the like, when a plurality of components are denoted by the same reference numerals, and in particular need to be distinguished from each other, an identification numeral such as “_1”, “[n]”, or “[m,n]” is sometimes added to the reference numerals.

In this specification and the like, “electrically connected” includes the case where components are directly connected to each other and the case where components are connected through an “object having any electric function”. Here, there is no particular limitation on the “object having any electric function” as long as electric signals can be transmitted and received between components that are connected through the object. Thus, even when the expression “electrically connected” is used, there is a case where no physical connection is made and a wiring just extends in an actual circuit.

In this specification and the like, a “resistor” is, for example, a circuit element or a wiring having a resistance value. Therefore, in this specification and the like, a “resistor” includes a wiring having a resistance value, a transistor in which current flows between a source and a drain, a diode, a coil, and the like. Thus, the term “resistor” can be replaced with the terms “resistance”, “load”, “a region having a resistance”, and the like; inversely, the terms “resistance”, “load”, and a “region having a resistance” can be replaced with the term “resistor” and the like. The resistance value can be, for example, preferably greater than or equal to 1 mQ and less than or equal to 10Ω, further preferably greater than or equal to 5 mQ and less than or equal to 5Ω, still further preferably greater than or equal to 10 mQ and less than or equal to 1Ω. As another example, the resistance value may be greater than or equal to 1Ω and less than or equal to 1×10⁹Ω.

In this specification and the like, a “capacitor” is, for example, a circuit element having an electrostatic capacitance value, a region of a wiring having an electrostatic capacitance value, parasitic capacitance, or gate capacitance of a transistor. Therefore, in this specification and the like, a “capacitor” includes not only a circuit element that has a pair of electrodes and a dielectric between the electrodes, but also parasitic capacitance generated between wirings, gate capacitance generated between a gate and one of a source and a drain of a transistor, and the like. The terms “capacitor”, “parasitic capacitance”, “gate capacitance”, and the like can be replaced with the term “capacitance” or the like; inversely, the term “capacitance” can be replaced with the terms “capacitor”, “parasitic capacitance”, “gate capacitance”, and the like. The term “pair of electrodes” of “capacitor” can be replaced with “pair of conductors”, “pair of conductive regions”, “pair of regions”, and the like. Note that the electrostatic capacitance value can be greater than or equal to 0.05 fF and less than or equal to 10 pF, for example. Alternatively, the electrostatic capacitance value may be greater than or equal to 1 pF and less than or equal to 10 μF, for example.

In this specification and the like, a node can be rephrased as a terminal, a wiring, an electrode, a conductive layer, a conductor, an impurity region, or the like depending on the circuit structure, the device structure, or the like. Furthermore, a terminal, a wiring, or the like can be rephrased as a node.

In this specification and the like, “voltage” and “potential” can be replaced with each other as appropriate. “Voltage” refers to a potential difference from a reference potential, and when the reference potential is a ground potential, for example, “voltage” can be rephrased as “potential”. The ground potential does not necessarily mean 0 V. Note that potentials are relative, and the potential supplied to a wiring or the like is changed depending on the reference potential, in some cases.

Ordinal numbers such as “first”, “second”, and “third” in this specification and the like are used in order to avoid confusion among components. Thus, the ordinal numbers do not limit the number of components. In addition, the ordinal numbers do not limit the order of components. In this specification and the like, for example, a “first” component in one embodiment can be referred to as a “second” component in other embodiments or claims. Furthermore, in this specification and the like, for example, a “first” component in one embodiment can be omitted in other embodiments or claims.

In this specification and the like, terms for describing arrangement, such as “over” and “under”, are used for convenience for describing the positional relation between components with reference to drawings in some cases. The positional relation between components is changed as appropriate in accordance with a direction in which the components are described. Thus, terms are not limited to those described in this specification and the like and can be rephrased as appropriate according to circumstances. For example, the expression “an insulator positioned over (on) a top surface of a conductor” can be rephrased as the expression “an insulator positioned on a bottom surface of a conductor” when the direction of a drawing showing these components is rotated by 180°.

Furthermore, the term “over” or “under” does not necessarily mean that a component is placed directly above or directly below and in direct contact with another component. For example, the expression “electrode B over insulating layer A” does not necessarily mean that the electrode B is formed on and in direct contact with the insulating layer A and does not exclude the case where another component is provided between the insulating layer A and the electrode B.

In this specification and the like, the terms “film”, “layer”, and the like can be interchanged with each other according to circumstances. For example, the term “conductive layer” can be changed into the term “conductive film” in some cases. Moreover, the term “insulating film” can be changed into the term “insulating layer” in some cases. Alternatively, the term “film”, “layer”, or the like is not used and can be interchanged with another term depending on the case or according to circumstances. For example, the term “conductive layer” or “conductive film” can be changed into the term “conductor” in some cases. Furthermore, for example, the term “insulating layer” or “insulating film” can be changed into the term “insulator” in some cases.

In this specification and the like, the term “electrode”, “wiring”, “terminal”, or the like does not functionally limit a component. For example, an “electrode” is used as part of a “wiring” in some cases, and vice versa. Furthermore, the term “electrode” or “wiring” can also mean the case where a plurality of “electrodes” or “wirings” are formed in an integrated manner. For example, a “terminal” is used as part of a “wiring” or an “electrode” in some cases, and vice versa. Furthermore, the term “terminal” can also mean the case where a plurality of “electrodes”, “wirings”, “terminals”, or the like are formed in an integrated manner, for example. Therefore, for example, an “electrode” can be part of a “wiring” or a “terminal”, and a “terminal” can be part of a “wiring” or an “electrode”. Moreover, the term “electrode”, “wiring”, “terminal”, or the like is sometimes replaced with the term “region”, for example.

In this specification and the like, the terms “wiring”, “signal line”, “power source line”, and the like can be interchanged with each other depending on the case or according to circumstances. For example, the term “wiring” can be changed into the term “signal line” in some cases. Also, for example, the term “wiring” can be changed into the term “power source line” in some cases. Inversely, the term “signal line”, “power source line”, or the like can be changed into the term “wiring” in some cases. The term “power source line” or the like can be changed into the term “signal line” or the like in some cases. Inversely, the term “signal line” or the like can be changed into the term “power source line” or the like in some cases. The term “potential” that is applied to a wiring can be changed into the term “signal” or the like depending on the case or according to circumstances. Inversely, the term “signal” or the like can be changed into the term “potential” in some cases.

In a neural network, the connection strength between synapses can be changed when existing data is given to the neural network. The processing for determining a connection strength by providing a neural network with existing data in such a manner is called “learning” in some cases.

In this specification and the like, a metal oxide is an oxide of metal in a broad sense. Metal oxides are classified into an oxide insulator, an oxide conductor (including a transparent oxide conductor), an oxide semiconductor (also simply referred to as an OS), and the like. For example, in the case where a metal oxide is used in an active layer of a transistor, the metal oxide is referred to as an oxide semiconductor in some cases. That is, when a metal oxide forms and obtains a channel formation region of a transistor that has at least one of an amplifying function, a rectifying function, and a switching function, the metal oxide can be referred to as a metal oxide semiconductor or shortly as an OS. Moreover, when an OS FET or an OS transistor is described, it can also be referred to as a transistor including a metal oxide or an oxide semiconductor.

Furthermore, in this specification and the like, a metal oxide containing nitrogen is also collectively referred to as a metal oxide in some cases. A metal oxide containing nitrogen may be referred to as a metal oxynitride.

### Example

This example shows an example in which a machine performed good or bad determination on SEM images by the inspection method described in Embodiment 1.

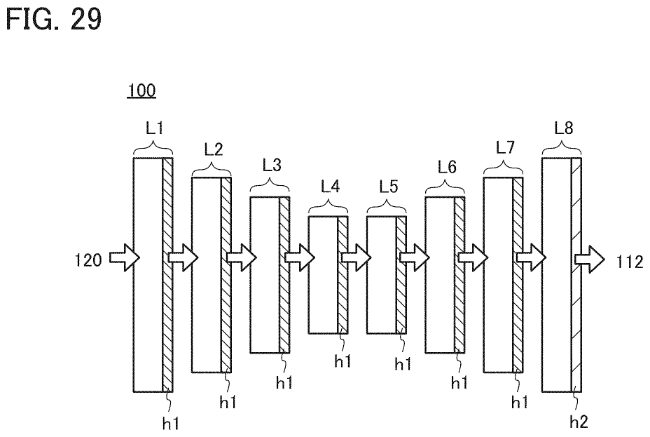

FIG. 29 illustrates the structure of the generator 100 used in this example.

The generator 100 of this example is a Convolutional Autoencoder and includes a layer L1 to a layer L8. The layer L1 to the layer L4 are convolutional layers and collectively function as an encoder. The layer L5 to the layer L8 are deconvolutional layers and collectively function as a decoder. Each of the layers L1 to L7 includes a layer h1 in its output portion and the layer L8 includes a layer h2 in its output portion. The layer h1 performs Batch Normalization on data on which convolution (or deconvolution) has been performed, and applies a Leaky relu function to the data. The layer h2 applies a sigmoid function to data on which deconvolution has been performed. The image 120 is input to the layer L1 and the image 112 is output from the layer L8.

Table 1 lists the parameters of the layers included in the generator 100. In Table 1, channel (i) represents the number of input channels, channel (o) represents the number of output channels, kernel represents the size of a filter (also referred to as kernel), stride represents the value of a stride, and pad represents the value of padding.

TABLE 1

| layer | channel (i) | channel (o) | kernel | stride | pad |
|---|---|---|---|---|---|
| L1 | 1 | 16 | 4 × 4 | 2 | 1 |
| L2 | 16 | 32 | 4 × 4 | 2 | 1 |
| L3 | 32 | 64 | 3 × 3 | 1 | 1 |
| L4 | 64 | 128 | 3 × 3 | 1 | 0 |
| L5 | 128 | 64 | 3 × 3 | 1 | 0 |
| L6 | 64 | 32 | 3 × 3 | 1 | 1 |
| L7 | 32 | 16 | 4 × 4 | 2 | 1 |
| L8 | 16 | 1 | 4 × 4 | 2 | 1 |

Learning of the generator 100 was performed by the method described in Embodiment 1. As the teacher data 101, 1024 SEM images of wiring shapes of semiconductor devices were used. The batch size was 128, the resolution of each image was 224×224 pix, and the learning was performed until the mean square error between the image 112 and the image 120 became a constant value.

Next, using the generator 100 that has performed the learning, good or bad determination was performed on 128 SEM images by the method described in Embodiment 1.

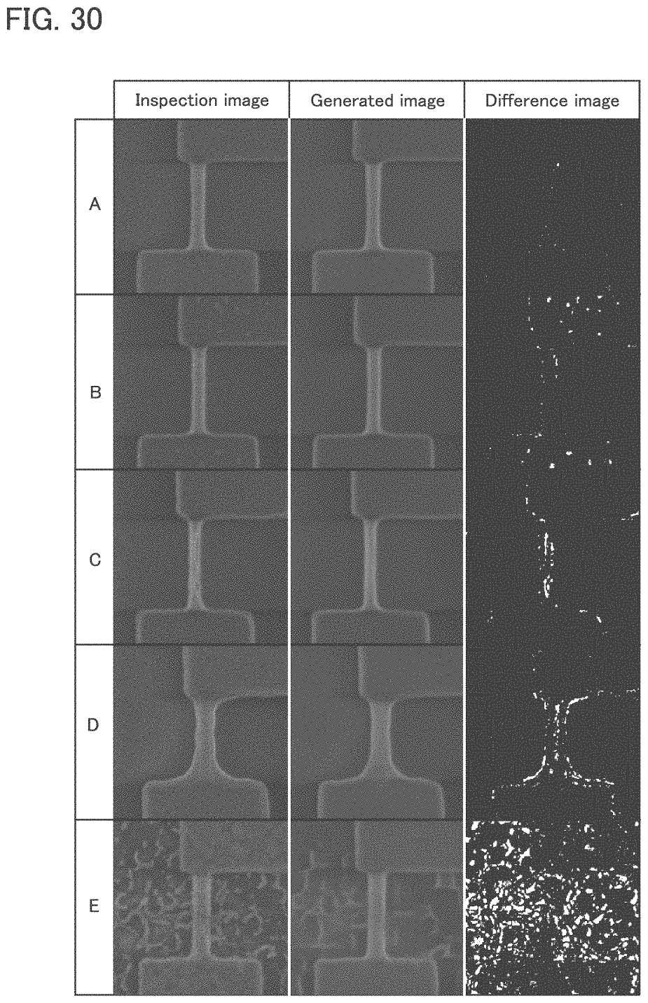

FIG. 30 shows an inspection image (corresponding to the inspection image 110 in FIG. 5A), an image generated by the generator 100 (corresponding to the image 112 in FIG. 5A), and a difference image of the two images (corresponding to the image 116 in FIG. 5C).

The inspection image shown in A in FIG. 30 is an image of a non-defective item. There is a small difference between the inspection image and the generated image, and the difference image includes a small number of portions displayed in white.

In the inspection image shown in B in FIG. 30, foreign substances that are probably etching residues are observed over a wiring. It is found from the difference image that portions corresponding to the foreign substances are displayed in white.

In the inspection image shown in C in FIG. 30, a cavity is observed in part of a center portion of a wiring. It is found from the difference image that a portion corresponding to the cavity is displayed in white.

In the inspection image shown in D in FIG. 30, it is observed that a center wiring is broader than that of the non-defective item. It is found from the difference image that a portion corresponding to the broad wiring is displayed in white.

In the inspection image shown in E in FIG. 30, an abnormal pattern is observed around a wiring (a portion corresponding to a base). It is found from the difference image that a portion corresponding to the abnormal pattern is displayed in white.

As described above, it was found from the results shown in FIG. 30 that the abnormal portion included in the inspection image can be extracted by obtaining the difference between the inspection image and the generated image.

Next, outlier detection was performed on the obtained difference images and the machine performed good or bad determination. For the outlier detection, a OneClassSVM method was employed. The determination results are listed in the following table.

TABLE 2

| | | Determination by | |
|---|---|---|---|
| | | machine | |
| | | Good | Bad |
| Determination by | Good | 46 | 18 |
| human | Bad | 6 | 58 |

The accuracy of the determination results was (46+58)/128=0.81.

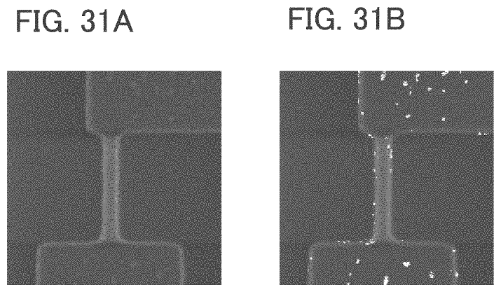

FIG. 31A is the inspection image shown in B in FIG. 30. FIG. 31B is obtained by combining the inspection image shown in B in FIG. 30 and the difference image shown in B in FIG. 30. Arranging the two images in such a manner makes it easier for a user to find the abnormal portions.

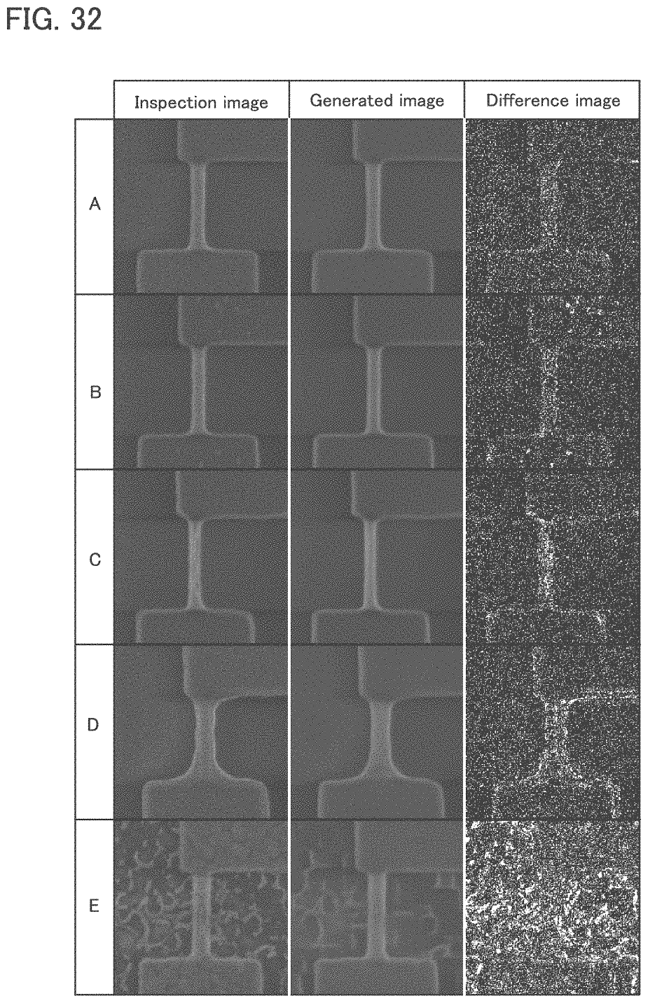

Next, FIG. 32 shows a comparative example in which difference images are obtained without performing Step S25 (smoothing processing) shown in FIG. 4 and FIG. 5B. The inspection images and the generated images shown in FIG. 32 are the same as those in FIG. 30.

In each of the entire difference images in FIG. 32, a large number of white pixels exist; thus, it is found difficult to identify the location of an abnormal portion.

As on the difference images in FIG. 30, the machine also performed good or bad determination on the difference images in FIG. 32. The determination results are listed in the following table.

TABLE 3

| | | Determination by | |
|---|---|---|---|
| | | machine | |
| | | Good | Bad |
| Determination by | Good | 25 | 39 |
| human | Bad | 26 | 38 |

The accuracy of the determination results was (25+38)/128=0.49.

It was found from the above results that the accuracy of the good or bad determination was improved by performing the smoothing processing before the difference between the inspection image and the generated image is obtained.

This example can be combined with the other embodiments in this specification as appropriate.

### REFERENCE NUMERALS

10: electron microscope, 11: electron gun, 12: condenser lens, 13: objective lens, 14: scanning coil, 15: detector, 16: stage, 17: electron beam, 18: sample, 19: signal electron, 20: PC, 21: input-output device, 30: server, 31: CPU, 32: AI chip, 33: main memory device, 34: auxiliary memory device, 35: bus, 40: calculator, 50: computed tomography device, 51: gantry, 52: cradle, 61: opening portion, 62: inspection object, 71: X-ray tube, 72: detector, 80: image processing device, 100: generator, 101: teacher data, 101a: teacher data, 101b: teacher data, 101c: teacher data, 102: data, 103: learning result, 103a: learning result, 103b: learning result, 103c: learning result, 110: inspection image, 111: abnormal portion, 112: image, 113: image, 114: image, 115: image, 116: image, 117: image, 120: image, 121: region, 122: region, 130: classifier, 131: image data, 132: label, 133: learning result, 134: data, 200: neural network, 210: nuclear magnetic resonance device, 211: gantry, 212: cradle, 221: opening portion, 222: object, 231: coil, 300: transistor, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 350: insulator, 352: insulator, 354: insulator, 356: conductor, 360: insulator, 362: insulator, 364: insulator, 366: conductor, 370: insulator, 372: insulator, 374: insulator, 376: conductor, 380: insulator, 382: insulator, 384: insulator, 386: conductor, 402: insulator, 404: insulator, 500: transistor, 503: conductor, 503a: conductor, 503b: conductor, 510: insulator, 512: insulator, 514: insulator, 516: insulator, 518: conductor, 520: insulator, 522: insulator, 524: insulator, 530: oxide, 530a: oxide, 530b: oxide, 530c: oxide, 530c1: oxide, 530c2: oxide, 540: conductor, 540a: conductor, 540b: conductor, 542a: conductor, 542b: conductor, 543a: region, 543b: region, 544: insulator, 546: conductor, 548: conductor, 550: insulator, 552: insulator, 560: conductor, 560a: conductor, 560b: conductor, 574: insulator, 580: insulator, 581: insulator, 582: insulator, 586: insulator, 600: capacitive element, 600A: capacitive element, 600B: capacitive element, 610: conductor, 611: conductor, 612: conductor, 620: conductor, 630: insulator, 631: insulator, 650: insulator, 651: insulator, 1400: memory device, 1411: peripheral circuit, 1420: row circuit, 1430: column circuit, 1440: output circuit, 1460: control logic circuit, 1470: memory cell array, 1471: memory cell, 1472: memory cell, 1473: memory cell, 1474: memory cell, 1475: memory cell, 1476: memory cell, 1477: memory cell, 1478: memory cell

1. An inspection device comprising:
an electron microscope configured to generate a signal corresponding to a surface shape of a sample;
an image processing device configured to generate a first image corresponding to the signal; and
a calculator comprising a circuit in which a neural network is formed,
wherein the calculator is configured to obtain a second image on the basis of the first image by using the neural network,
wherein the calculator is configured to obtain a third image by performing smoothing processing on the first image,
wherein the calculator is configured to obtain a fourth image by performing smoothing processing on the second image, and
wherein the calculator is configured to obtain a fifth image by obtaining a difference between the third image and the fourth image.

2. (canceled)

3. The inspection device according to claim 1,
wherein the third image is expressed by a first pixel value,
wherein the fourth image is expressed by a second pixel value,
wherein the fifth image is expressed by a third pixel value which is a difference between the first pixel value and the second pixel value,
wherein the calculator is configured to obtain a fourth pixel value on the basis of the third pixel value,
wherein the fourth pixel value is a first value when the third pixel value is greater than or equal to a threshold, and
wherein the fourth pixel value is a second value when the third pixel value is less than the threshold.

4. The inspection device according to claim 3,
wherein the calculator is configured to perform outlier detection on a sixth image expressed by the fourth pixel value to classify the sixth image as abnormal data or normal data.

5. The inspection device according to claim 4,
wherein the calculator further comprises an input/output device,
wherein the calculator is configured to calculate a degree of abnormality of the sixth image by performing the outlier detection,
wherein the calculator is configured to obtain the sixth images corresponding to a plurality of first images and calculate the degrees of abnormality of the obtained sixth images, and
wherein the input/output device is configured to display the first images corresponding to the sixth images in order of the degree of abnormality.

6. The inspection device according to claim 5,
wherein the input/output device is configured to display a seventh image obtained by combining the first image and the sixth image.

7. The inspection device according to claim 1,
wherein when the first image comprises an abnormal portion, the second image obtained by the calculator on the basis of the first image does not comprise the abnormal portion.

8. The inspection device according to claim 1,
wherein the circuit in which the neural network is formed comprises a transistor using a metal oxide in a channel formation region.

9.-16. (canceled)
